(19) United States
(12) Patent Application Publication
(10) Pub. No.: US 2024/0292731 A1
(43) Pub. Date: Aug. 29, 2024

(54) ORGANOMETALLIC COMPOUND AND APPLICATION THEREOF

(71) Applicant: GUANGDONG AGLAIA OPTOELECTRONIC MATERIALS CO., LTD., Foshan, Guangdong (CN)

(72) Inventors: Liangliang YAN, Foshan (CN); Lei DAI, Foshan (CN); Lifei CAI, Foshan (CN)

(73) Assignee: GUANGDONG AGLAIA OPTOELECTRONIC MATERIALS CO., LTD., Foshan, Guangdong (CN)

(21) Appl. No.: 18/289,437

(22) PCT Filed: Feb. 26, 2022
(86) PCT No.: PCT/CN2022/078116

§ 371 Date: Nov. 3, 2023

(30) Foreign Application Priority Data
May 6, 2021 (CN) 202110487685.7

(51) Int. Cl. H10K 85/30; C07F 15/00; C09K 11/06; H10K 50/12

(52) U.S. Cl. CPC H10K 85/342; C07F 15/0033; C09K 11/06; C09K 2211/1044; C09K 2211/185; H10K 50/12

(57) ABSTRACT

The present invention relates to an organometallic compound and application thereof. The organometallic compound has a general formula of Ir(La)(Lb)(Lc), where La is a structure represented by Formula (1). The compound provided by the present invention has the advantages of high optical and electrical stability, narrow emission half-peak width, high color saturation, high luminous efficiency, long device service life and the like, and can be used in organic electroluminescent devices. In particular, the compound has the potential for application in the AMOLED industry as a green light-emitting dopant.

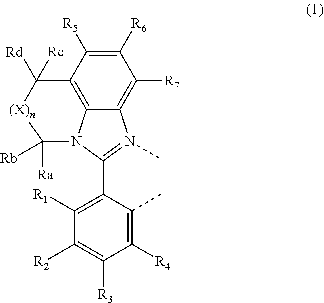

### TECHNICAL FIELD

The present invention relates to the technical field of organic electroluminescence, in particular to an organic light-emitting material applicable to organic electroluminescent devices, and specially relates to an organometallic compound and application thereof in an organic electroluminescent device.

### BACKGROUND

At present, as a new-generation display technology, an organic electroluminescent device (OLED) has attracted more and more attention in display and lighting technologies, thus having a wide application prospect. However, compared with market application requirements, properties, such as luminous efficiency, driving voltage and service life, of the OLED still need to be strengthened and improved.

In generally, the OLED includes various organic functional material films with different functions sandwiched between metal electrodes as a basic structure, which is similar to a sandwich structure. Under the driving of a current, holes and electrons are injected from a cathode and an anode, respectively. After moving to a certain distance, the holes and the electrons are compounded in a light-emitting layer, and then released in the form of light or heat to achieve luminescence of the OLED.

However, organic functional materials are core components of the OLED, and the thermal stability, photochemical stability, electrochemical stability, quantum yield, film forming stability, crystallinity, color saturation and the like of the materials are main factors affecting properties of the device.

Generally, the organic functional materials include fluorescent materials and phosphorescent materials. The fluorescent materials are usually organic small-molecule materials, which can only utilize 25% of a singlet state for luminescence, so that the luminous efficiency is relatively low. Meanwhile, due to an earth-spin orbit coupling effect caused by a heavy atom effect, the phosphorescent materials can utilize 25% of a singlet state and can also utilize 75% of the energy of triplet excitons, so that the luminous efficiency can be improved. However, compared with the fluorescent materials, the phosphorescent materials are developed later, and the thermal stability, service life, color saturation and the like of the materials need to be improved. Thus, the phosphorescent materials have become a challenging topic. Various organometallic compounds have been developed to serve as the phosphorescent materials. For example, an invention patent (CN1726606) discloses an arylbenzimidazole iridium compound. However, the luminous efficiency of the compound is far from enough to meet market demands. A non-patent document published by Wen et al. in 2004 (Chem. Mater. 2004, 16, 2480-2488) discloses a benzimidazole-aromatic ring metallic iridium complex, which has certain luminous efficiency. However, due to too large half-peak width and short device service life, especially short T95, of the material, market application demands are difficult to meet, and the material needs to be further improved. An invention patent document (CN102272261) discloses an iridium compound connected with aryl-substituted benzimidazole having steric hindrance on N. However, the color saturation, the emission spectrum half-peak width and device properties, especially the luminous efficiency and the device service life, of the compound need to be improved. An invention patent document (CN103396455) discloses a substituted benzimidazole iridium compound connected with alkyl on N. Similarly, the compound also has the problems of poor color saturation, too large emission spectrum half-peak width, low device efficiency, short device service life and the like, which need to be solved. An invention patent document (CN103254238) discloses an iridium compound connected with aryl-substituted benzimidazole-dibenzoheterocyclic ring having steric hindrance on N. However, the compound also has the problems of too large emission spectrum half-peak width, low device efficiency, short device service life and the like, which need to be solved. An invention patent document (CN102898477) discloses an iridium compound shown as

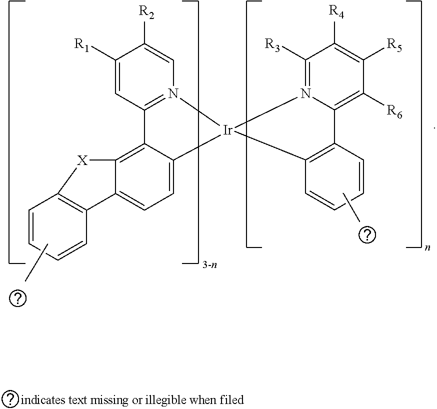

However, the compound also has the problems of too large emission spectrum half-peak width, low device efficiency, short device service life and the like, which need to be solved.

### SUMMARY

In order to overcome the above disadvantages, the present invention provides an organic electroluminescent device with high properties and an organometallic compound material capable of realizing the organic electroluminescent device.

An organometallic compound of the present invention has a general formula of Ir(La)(Lb)(Lc), where La is a structure represented by Formula (1). The iridium complex provided by the present invention has the advantages of high optical and electrical stability, narrow emission half-peak width, high color saturation, high luminous efficiency, long device service life and the like, and can be used in organic electroluminescent devices. In particular, the compound has the potential for application in the AMOLED industry as a green light-emitting phosphorescent material.

An organometallic compound has a general formula of Ir(La)(Lb)(Lc), where La is a structure represented by Formula (1):

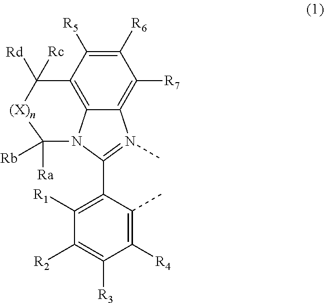

where dotted lines refer to positions connected to the metal Ir;
X is O, S, Se, CRpRq, SiRrRs or NRt;
n is an integer from 0 to 3, and when the n is equal to or greater than 2, multiple X groups are present at the same time and are the same or different;
Ra, Rb, Rc, Rd, Rp, Rq, Rr, Rs and Rt are independently selected from hydrogen, deuterium, halogen, substituted or unsubstituted C₁-C₁₀ alkyl, substituted or unsubstituted C₃-C₂₀ cycloalkyl, substituted or unsubstituted C₆-C₁₈ aryl, and substituted or unsubstituted C₂-C₁₇ heteroaryl;
R₁-R₇ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₇ are connected to each other to form an aliphatic ring structure or an aromatic ring structure;
the heteroalkyl and the heteroaryl at least contain one O, N or S heteroatom;
both Lb and Lc are a monoanionic bidentate ligand, the La, the Lb and the Lc are the same or at least one is different, and the different indicates different parent nuclear structures, a same parent nuclear structure with different substituents, or a same parent nuclear structure with different substituent positions;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

Optionally,
the X is CRpRq; the Ra, the Rb, the Rc, the Rd, the Rp and the Rq are independently selected from hydrogen, deuterium, halogen, substituted or unsubstituted C₁-C₁₀ alkyl, and substituted or unsubstituted C₃-C₂₀ cycloalkyl;
and the “substituted” refers to substitution with deuterium, F, Cl, Br, C₁-C₆ alkyl, and C₃-C₆ cycloalkyl, and the substitution ranges from a single substitution number to a maximum substitution number.

More optionally,
the R₄ and the R₇ are independently selected from hydrogen, the R₁-R₃ and the R₅-R₆ are independently selected from hydrogen, deuterium, halogen, hydroxyl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₆-C₁₈ aryl, and substituted or unsubstituted C₂-C₁₇ heteroaryl, or any two adjacent groups of the R₁-R₂ are connected to each other to form an aliphatic ring.

Further optionally,
the Ra, the Rb, the Rc, the Rd, the Rp and the Rq are independently selected from hydrogen, deuterium, and substituted or unsubstituted C₁-C₁₀ alkyl;
the R₄ and the R₇ are independently selected from hydrogen; the R₃, the R₅ and the R₆ are independently selected from hydrogen, deuterium, halogen, substituted or unsubstituted C₁-C₁₀ alkyl, substituted or unsubstituted C₃-C₂₀ cycloalkyl, and substituted or unsubstituted C₆-C₁₈ aryl; and the R₁ and the R₂ are selected from hydrogen, deuterium, halogen, hydroxyl, substituted or unsubstituted C₁-C₁₀ alkyl, substituted or unsubstituted C₁-C₁₀ heteroalkyl, substituted or unsubstituted C₆-C₁₈ aryl, and substituted or unsubstituted C₂-C₁₇ heteroaryl, or any two adjacent groups are connected to each other to form an aliphatic ring.

As a optional organometallic compound, the Lb is a structure represented by Formula (2):

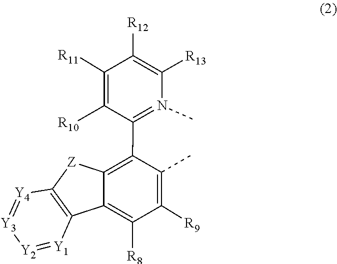

where dotted lines refer to positions connected to the metal Ir;
Y₁-Y₄ are independently selected from CR₀ or N;
Z is O, S, Se, CRpRq, SiRrRs or NRt;
R₀ and R₈-R₁₃ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₈-R₁₃ may be connected to each other to form an aliphatic ring structure or an aromatic ring structure;
the heteroalkyl and the heteroaryl at least contain one O, N or S heteroatom;
Rp, Rq, Rr, Rs and Rt are defined the same as above;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

Optionally,
the Y₁-Y₃ are independently selected from CR₀; the Y₄ is independently selected from CR₀ or N;
the Z is O;
the R₀ and the R₈-R₁₃ are independently selected from hydrogen, deuterium, halogen, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₆-C₁₈ aryl, and substituted or unsubstituted C₂-C₁₇ heteroaryl, or any two adjacent groups of the R₈-R₁₃ may be connected to each other to form an aliphatic ring structure or an aromatic ring structure;
and the “substituted” refers to substitution with deuterium, F, Cl, Br, C₁-C₆ alkyl, and C₃-C₆ cycloalkyl, and the substitution ranges from a single substitution number to a maximum substitution number.

Further optionally,
the R₀, the R₉ and the R₁₀ are independently selected from hydrogen, the R₁₁-R₁₃ are independently selected from hydrogen, deuterium, halogen, substituted or unsubstituted C₁-C₁₀ alkyl, substituted or unsubstituted C₁-C₁₀ heteroalkyl, and substituted or unsubstituted C₃-C₂₀ cycloalkyl, or any two adjacent groups of the R₈-R₁₃ may be connected to each other to form an aliphatic ring structure or an aromatic ring structure.

As a optional organometallic compound, the Lc is the same as the La or the Lb, and the La is different from the Lb.

As a optional organometallic compound, the Lc is a structure represented by Formula (3):

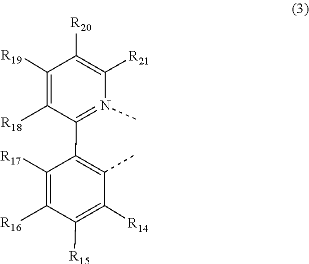

where dotted lines refer to positions connected to the metal Ir;
R₁₄-R₂₁ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁₄-R₂₁ may be connected to each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

Optionally, the R₁₄-R₂₁ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₆-C₁₈ aryl, and substituted or unsubstituted C₂-C₁₇ heteroaryl, or any two adjacent groups of the R₁₄-R₂₁ may be connected to each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, and C₃-C₆ cycloalkyl, and the substitution ranges from a single substitution number to a maximum substitution number.

Optionally, the R₁₇ and the R₁₈ are connected to each other to form a five-membered or six-membered aliphatic ring or aromatic ring structure.

As a optional organometallic compound, the La optionally has one of the following structural formulas, or is partially or completely deuterated or fluorinated correspondingly,

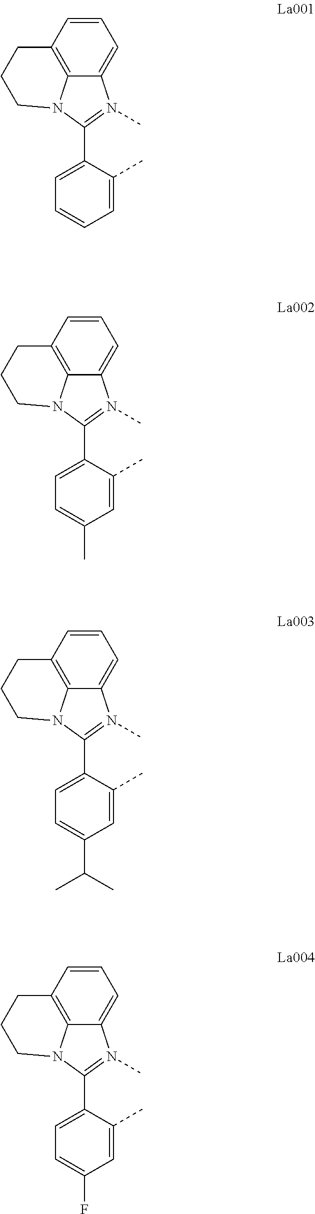

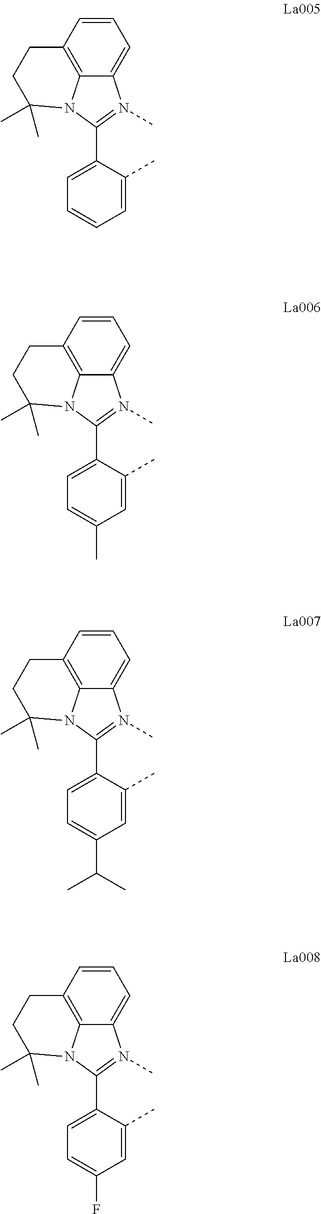

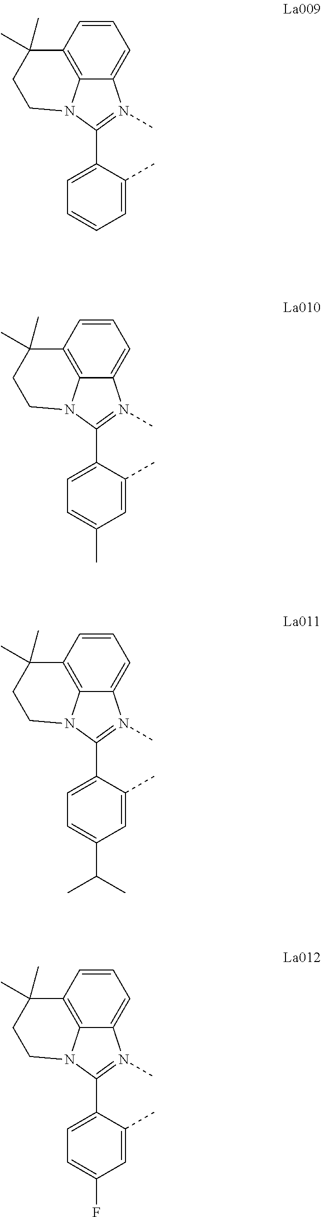

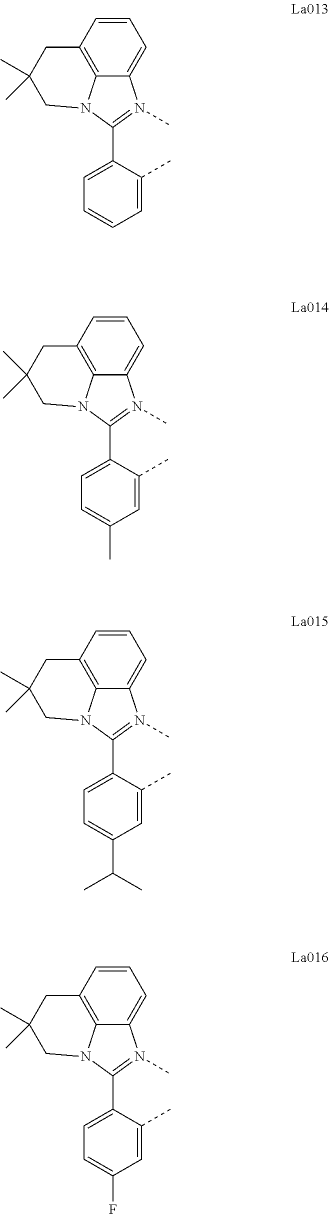

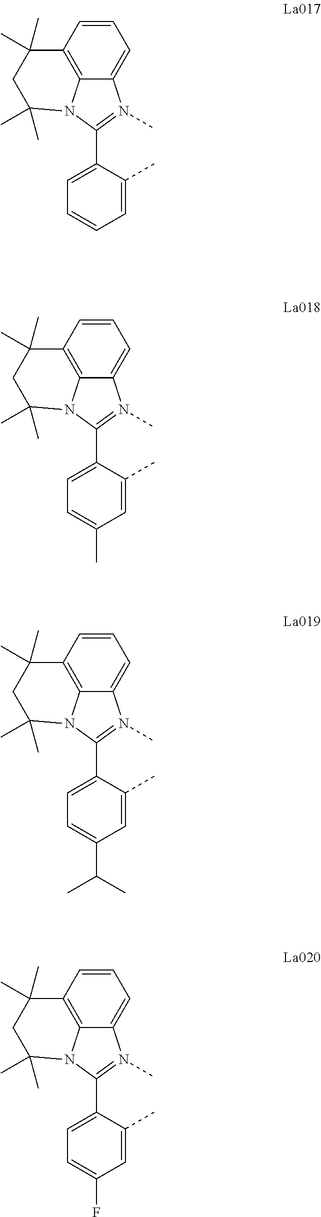

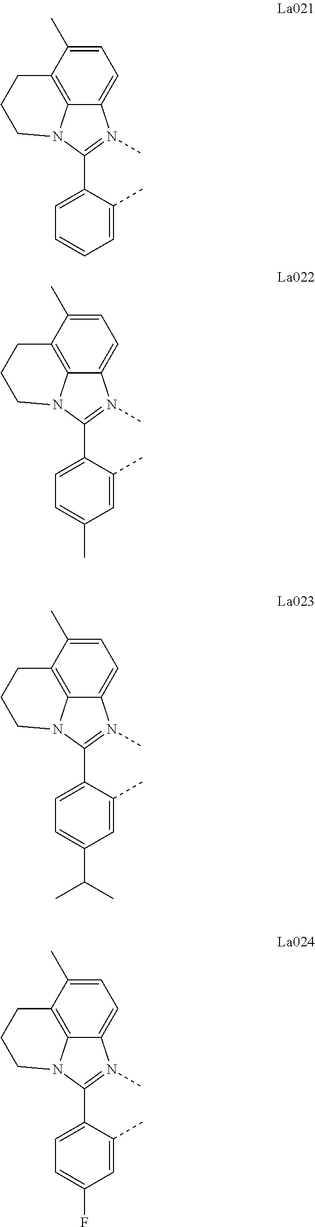

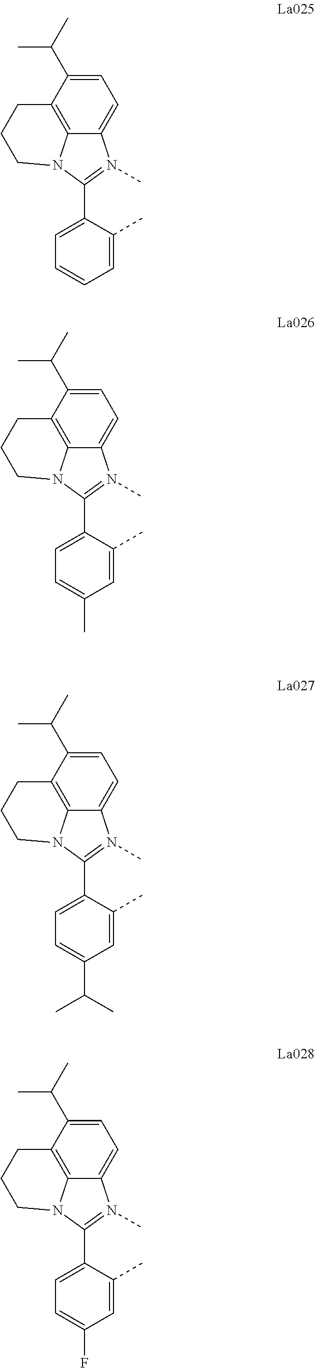

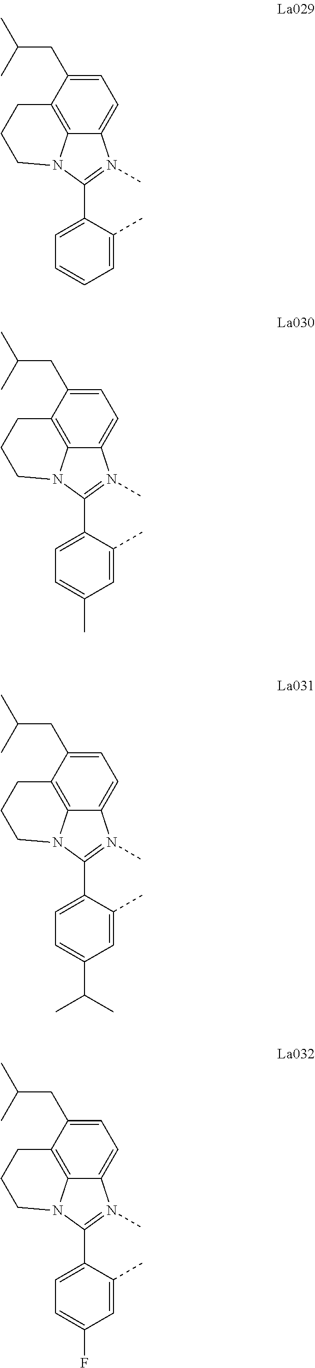

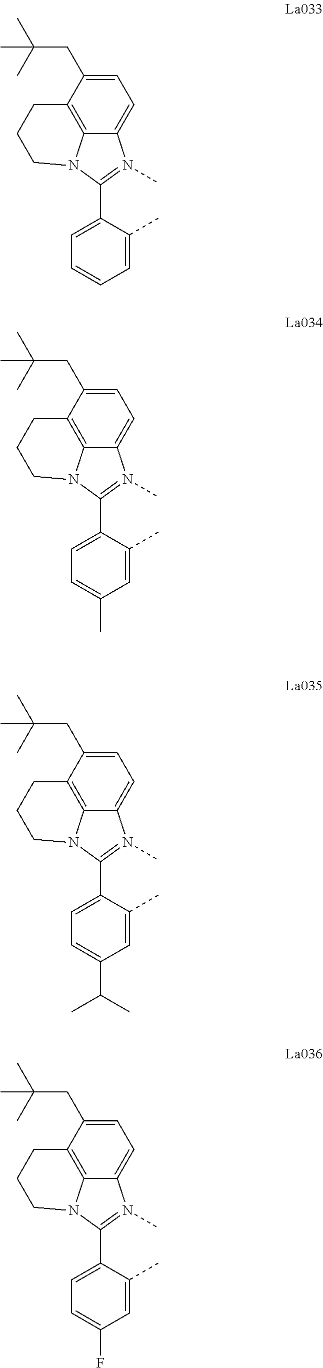

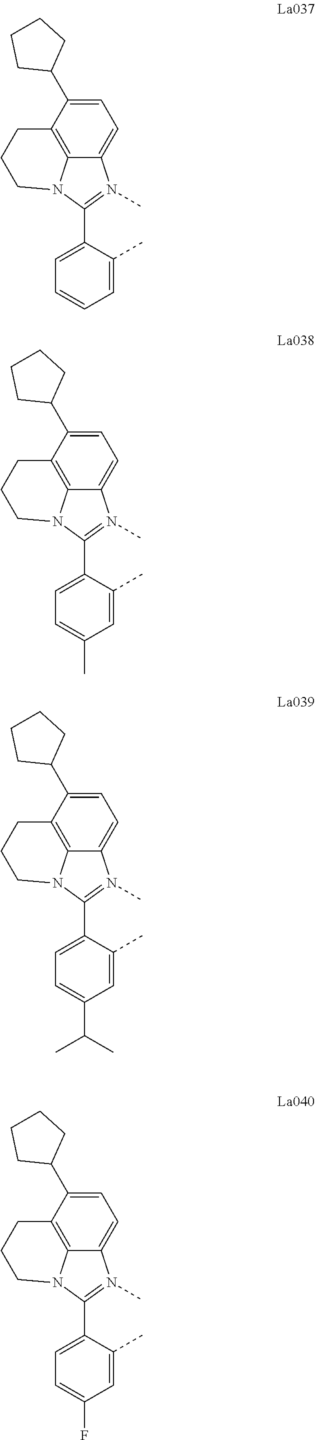

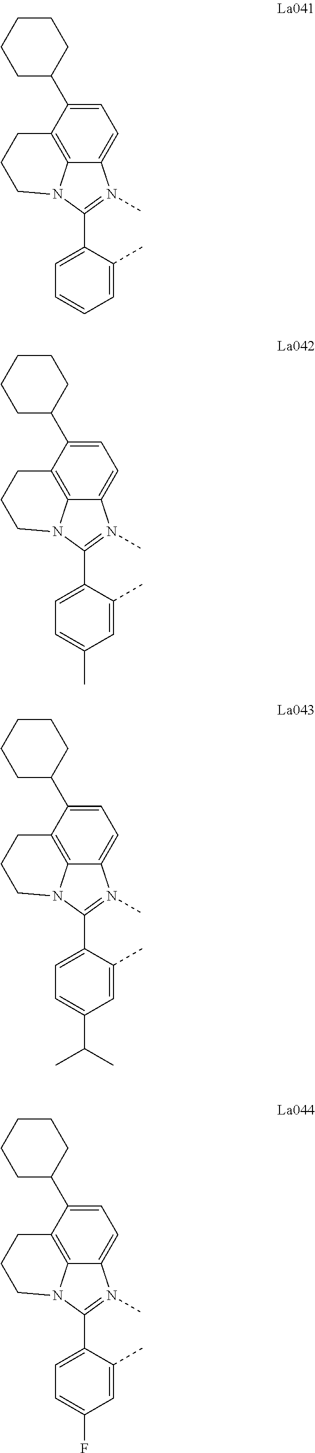

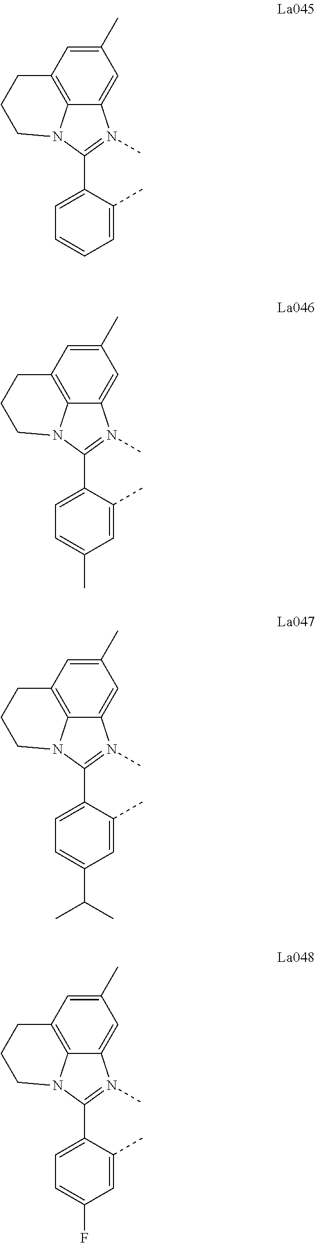

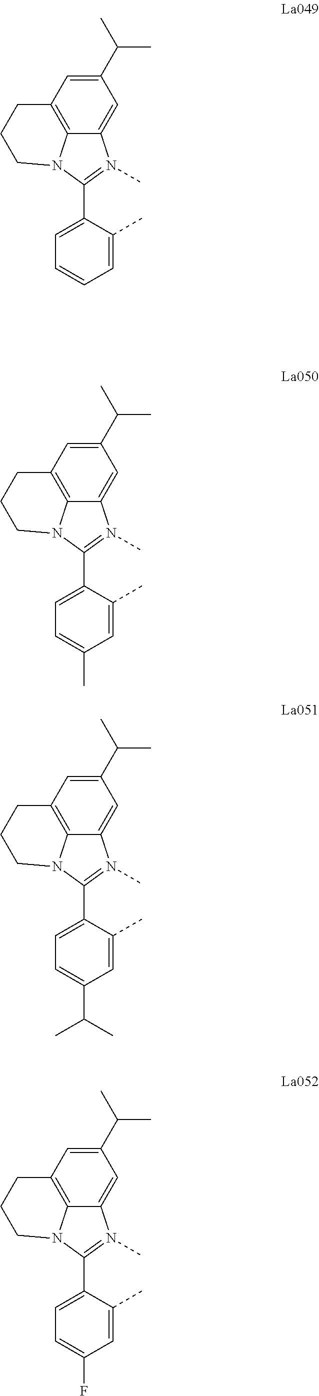

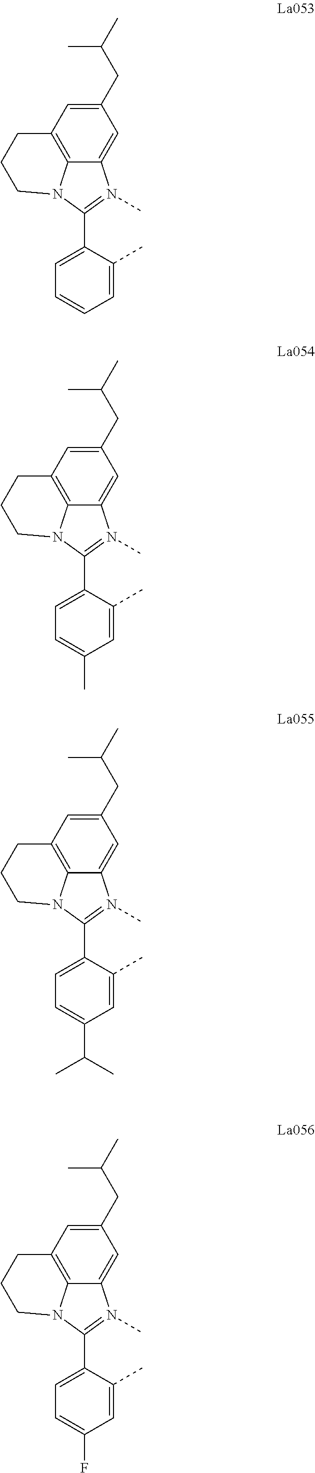

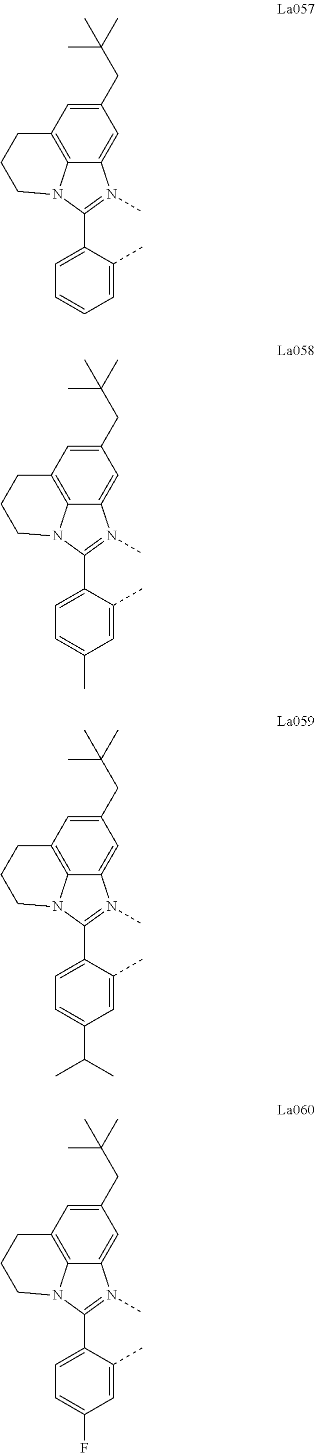

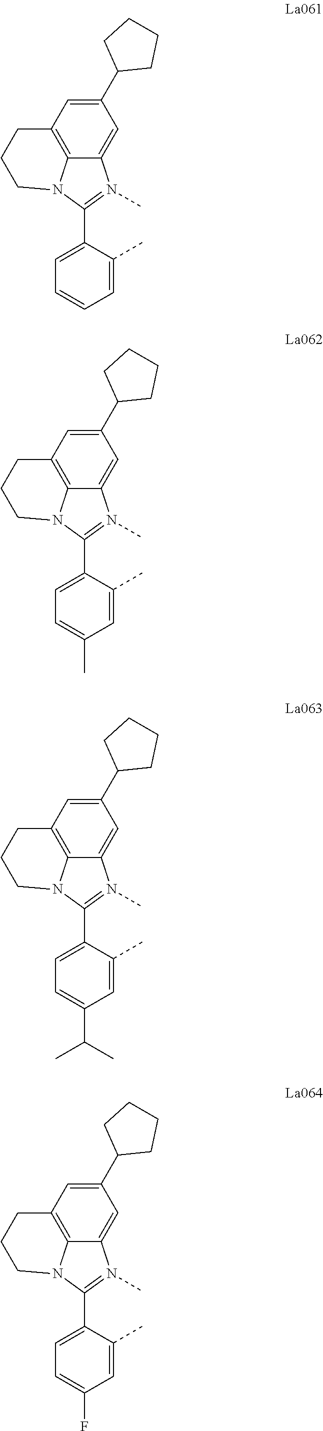

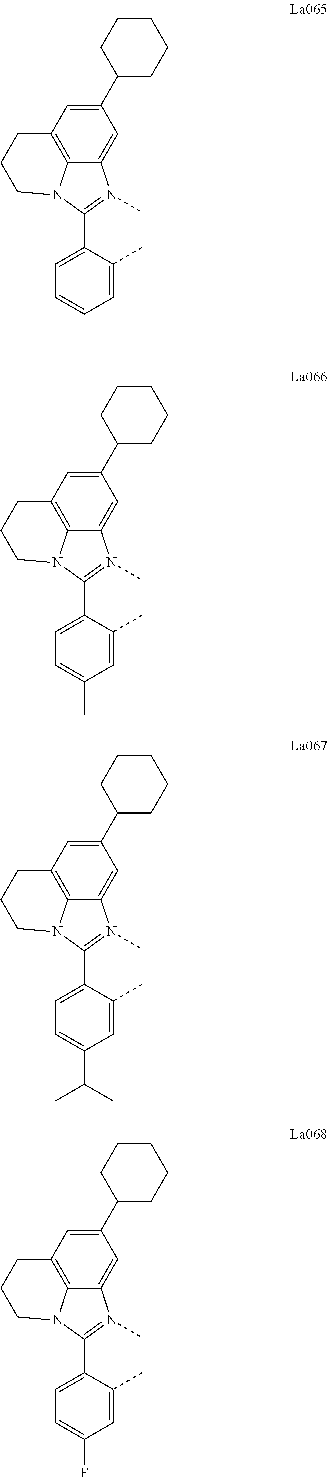

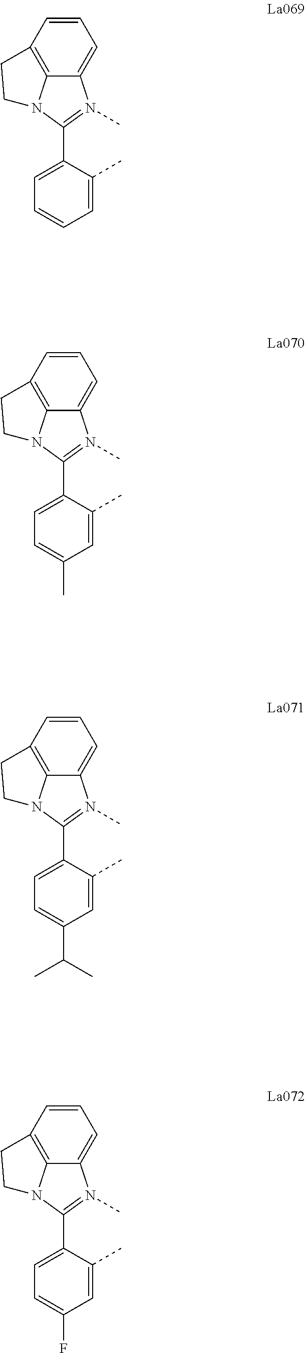

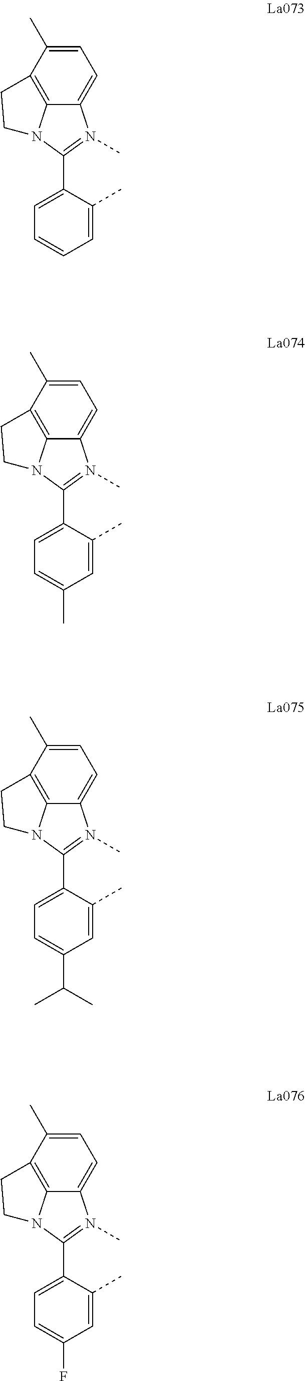

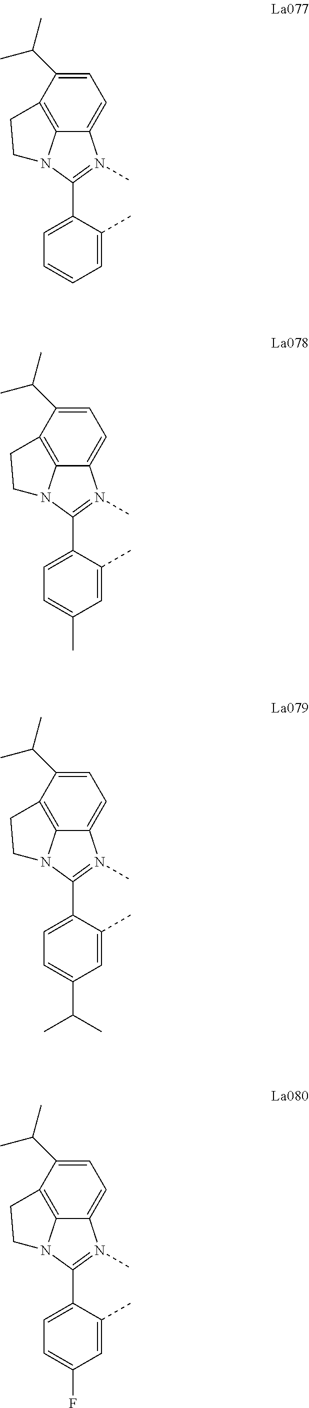

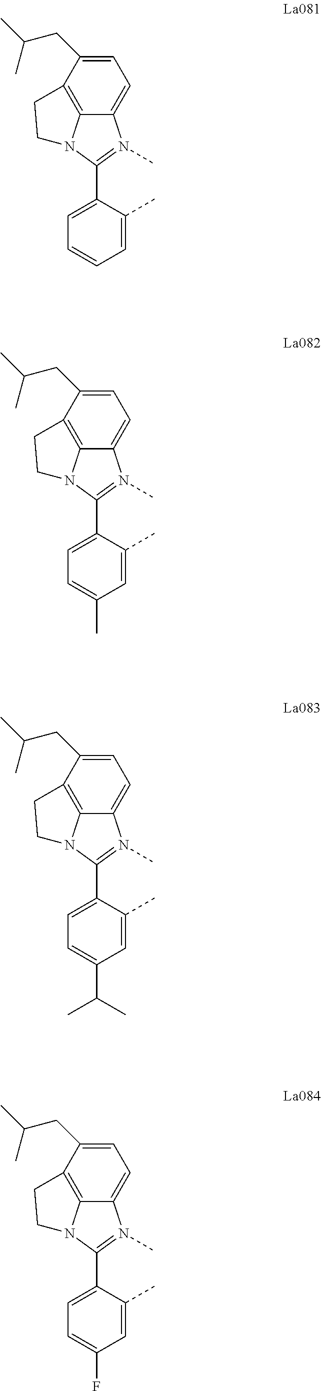

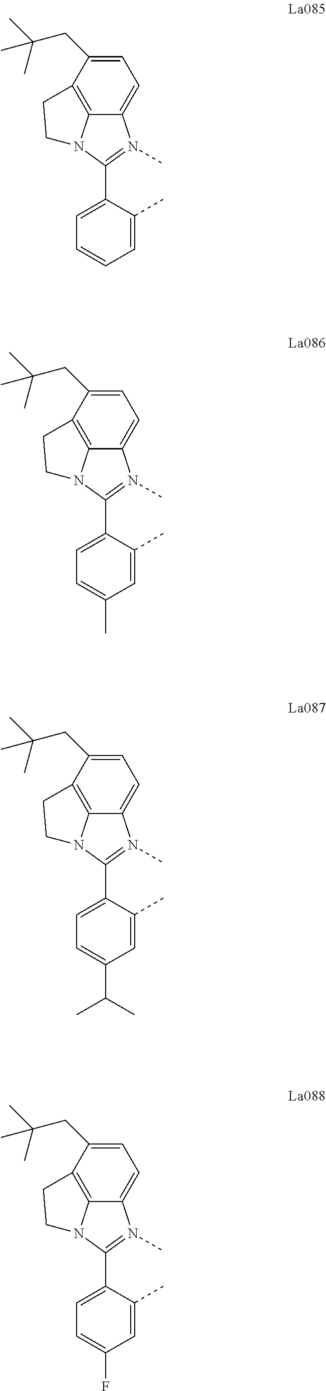

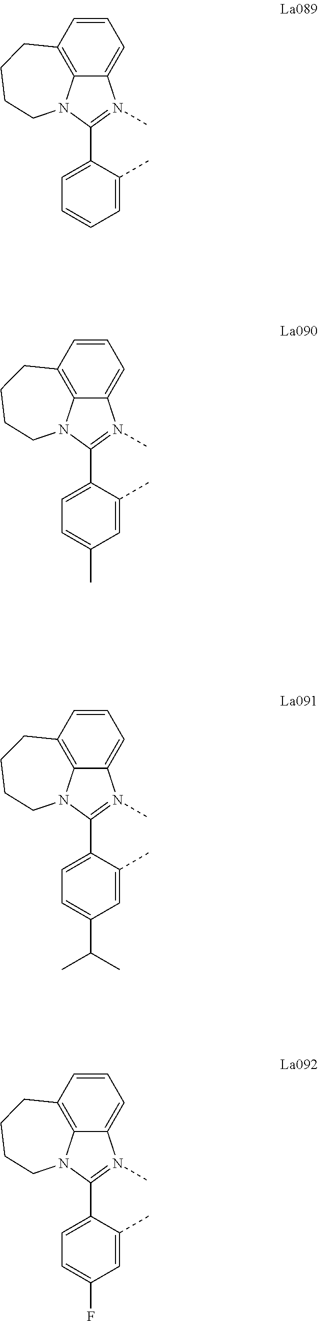

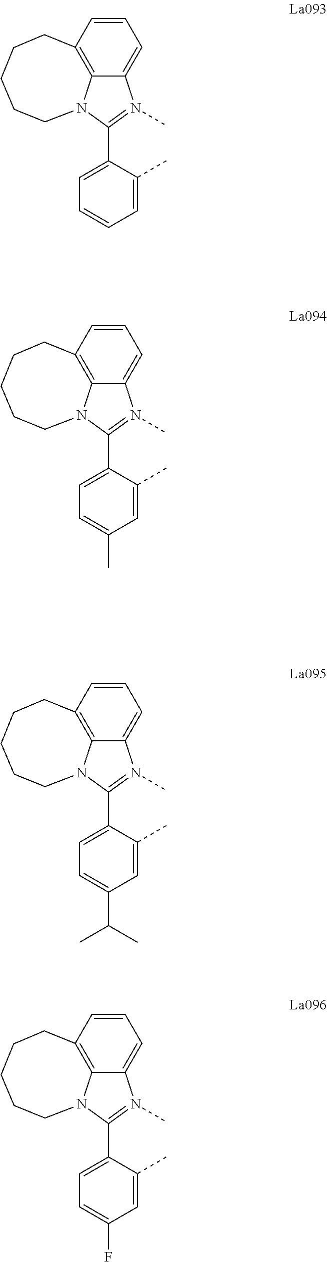

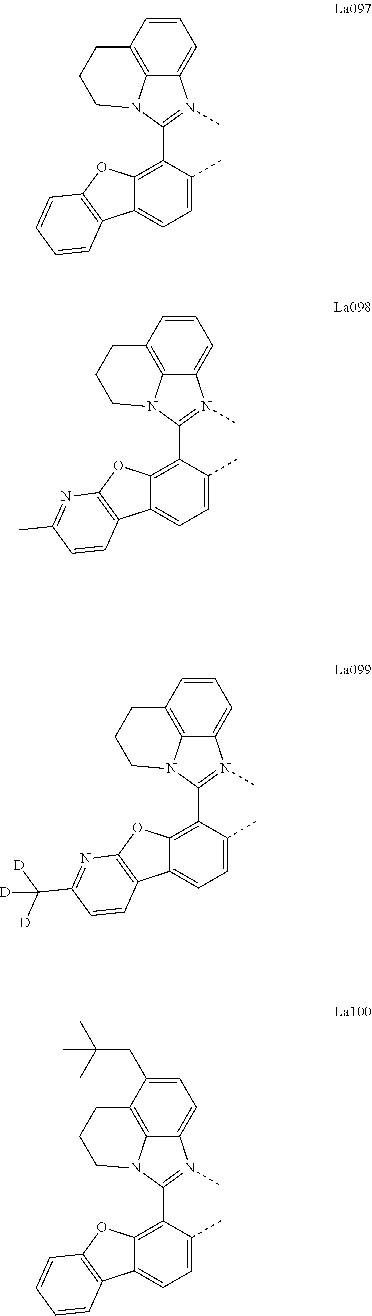

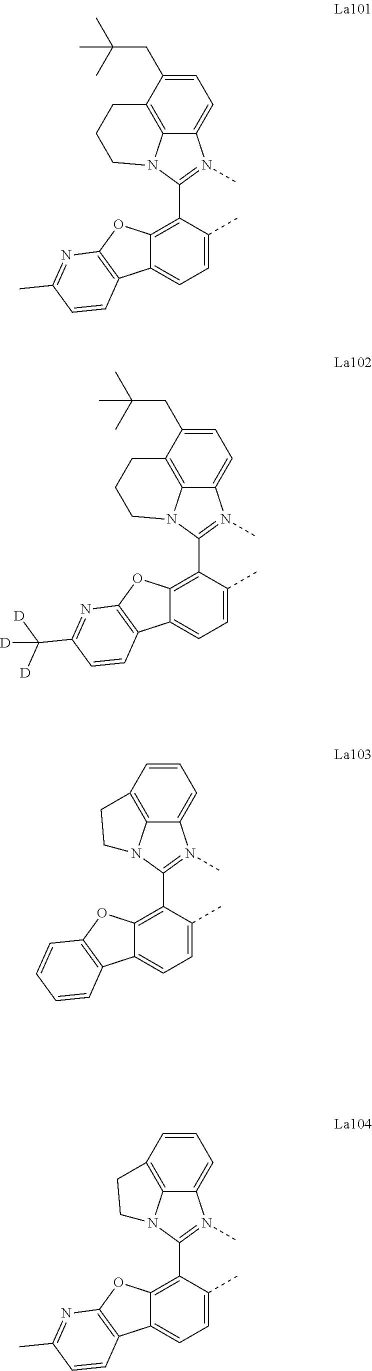

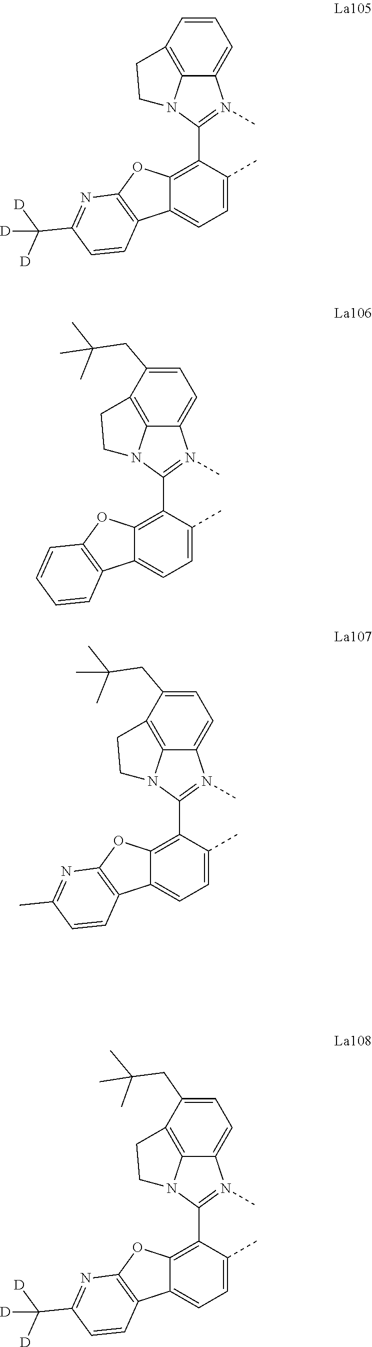

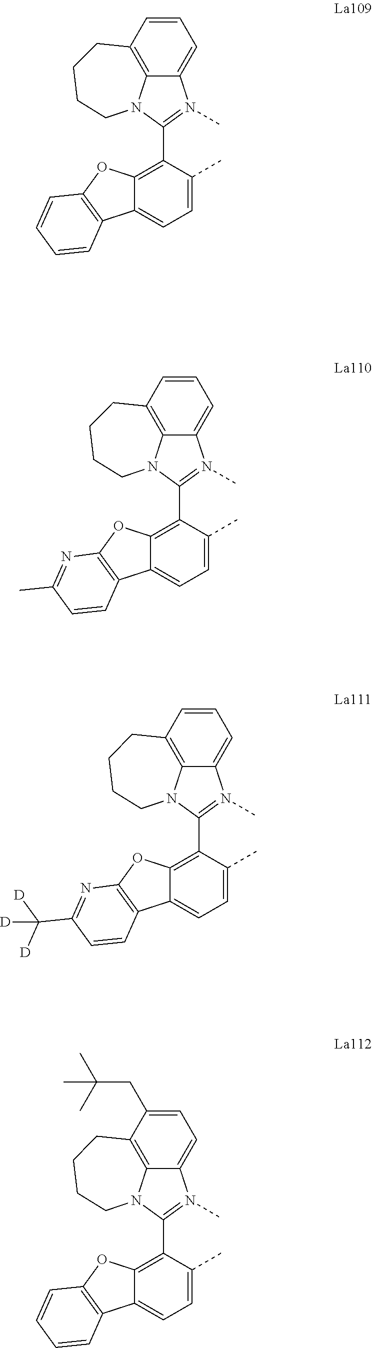

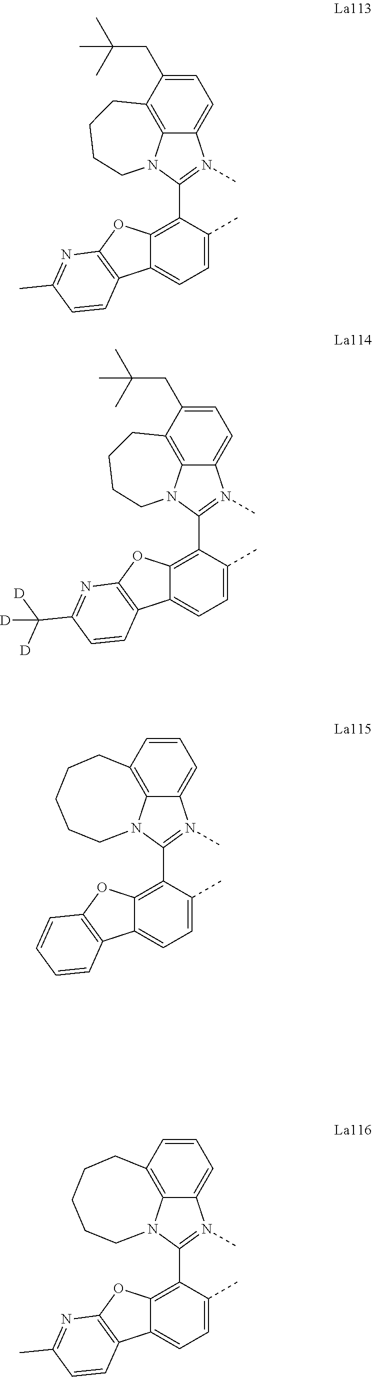

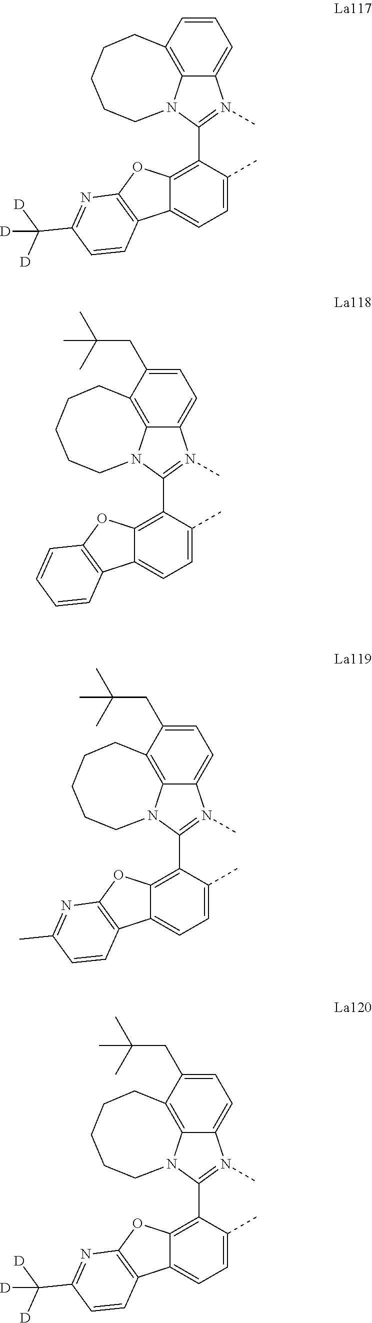

As a optional organometallic compound, the Lb optionally has one of the following structural formulas, or is partially or completely deuterated or fluorinated correspondingly,

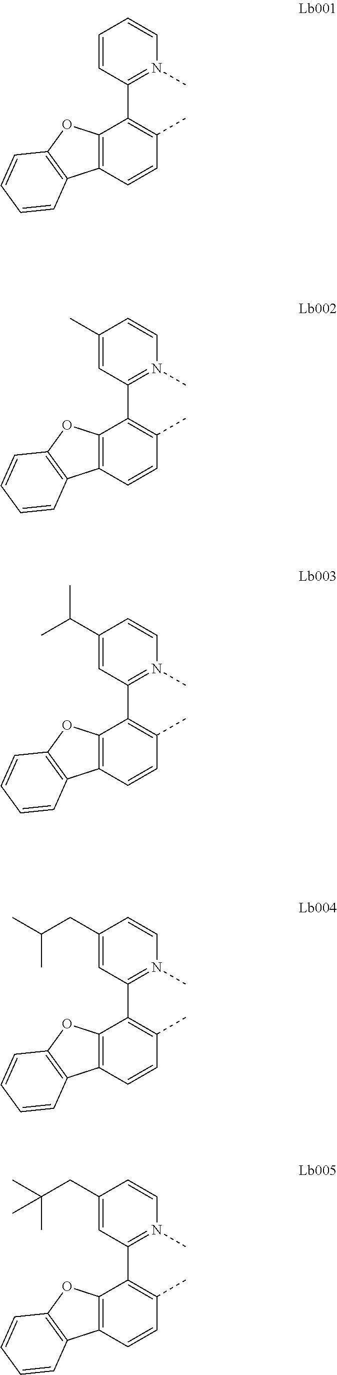

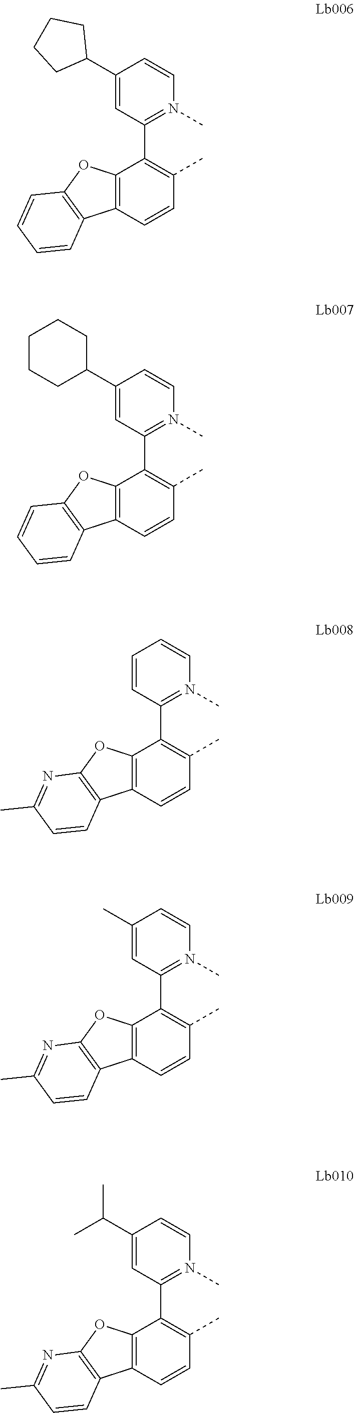

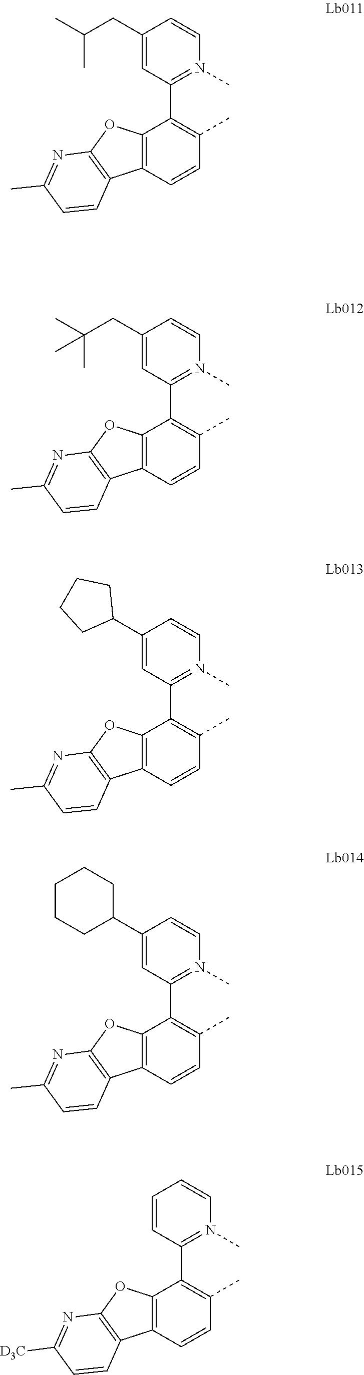

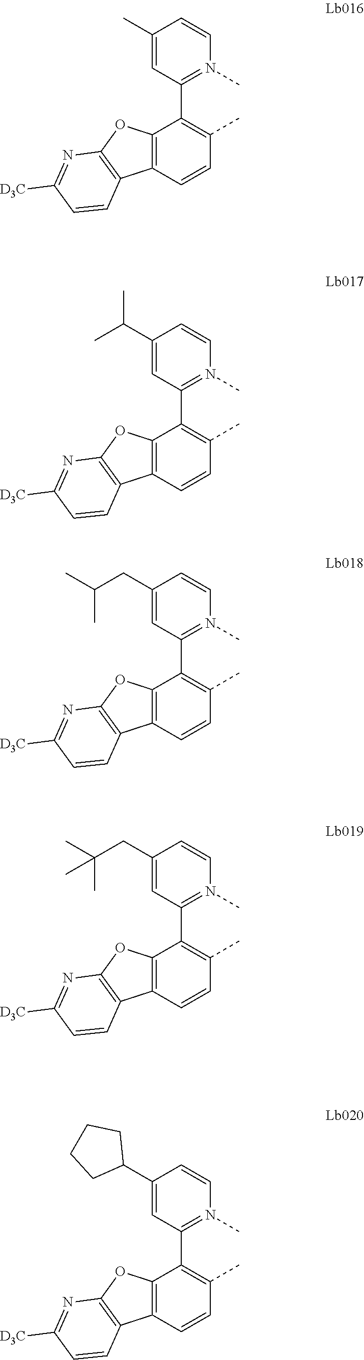

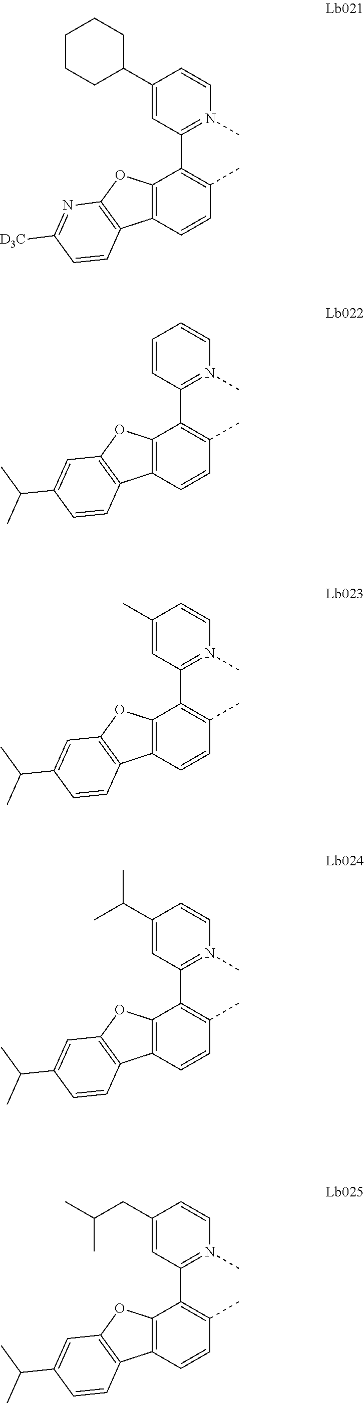

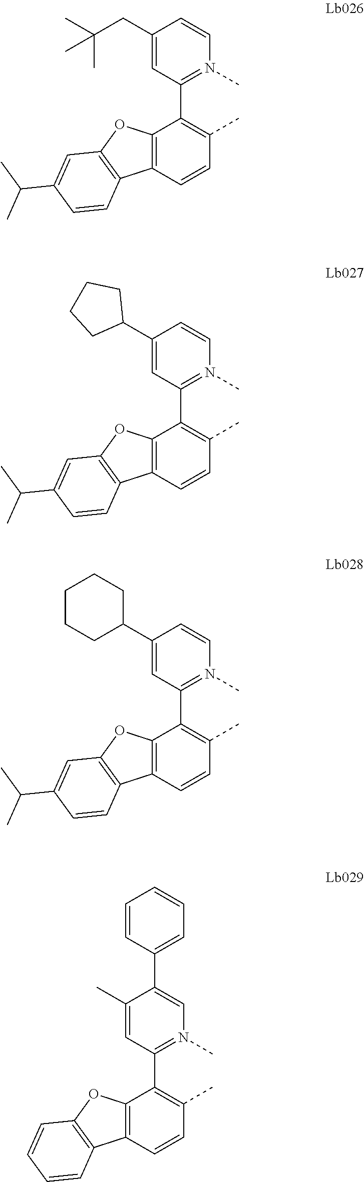

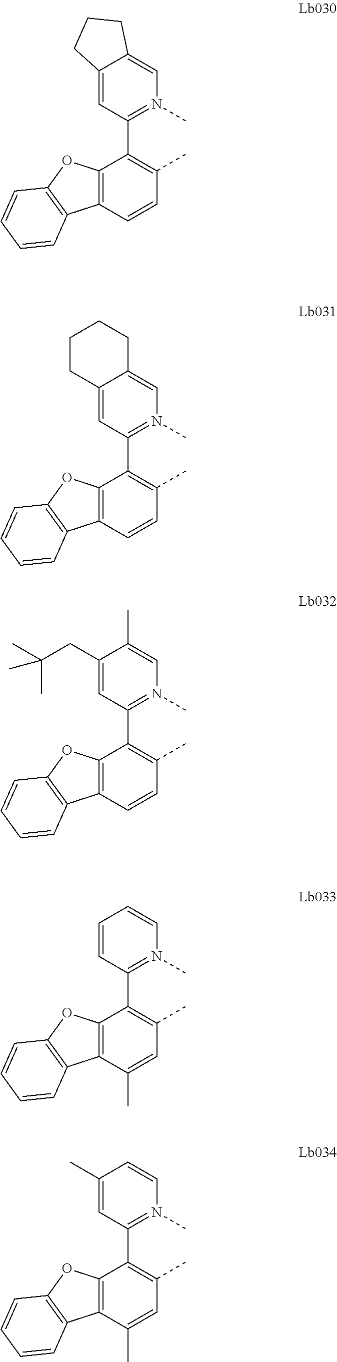

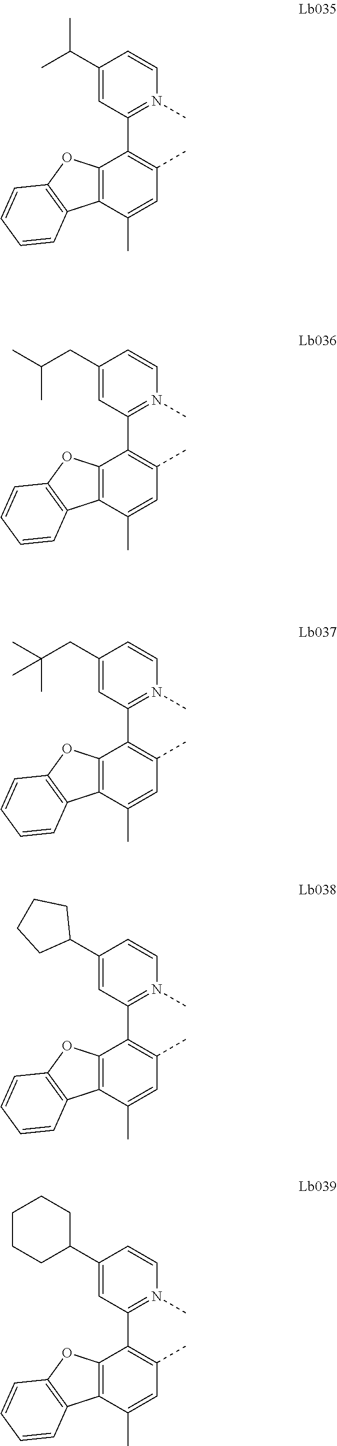

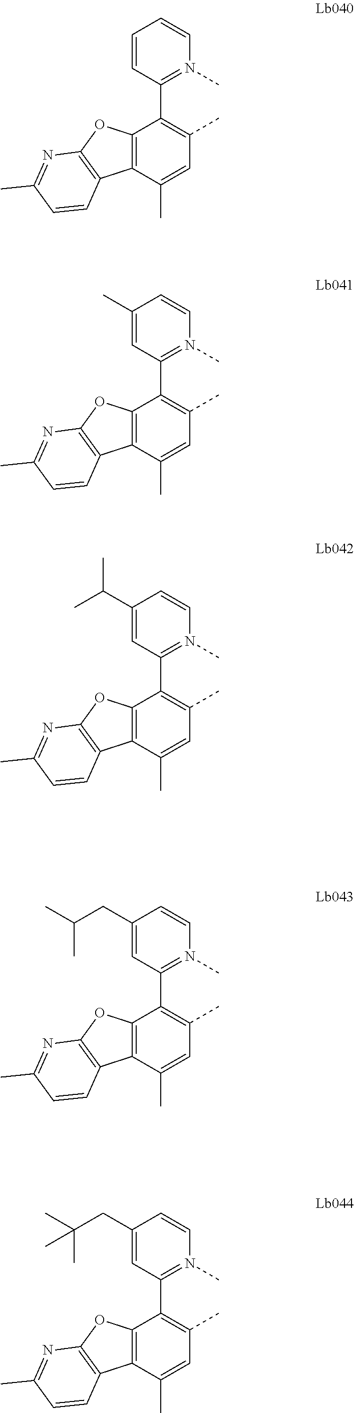

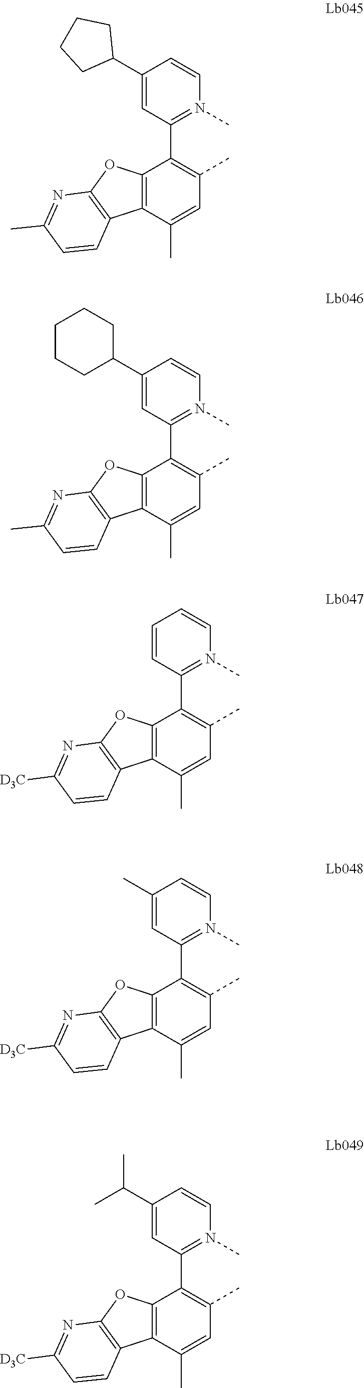

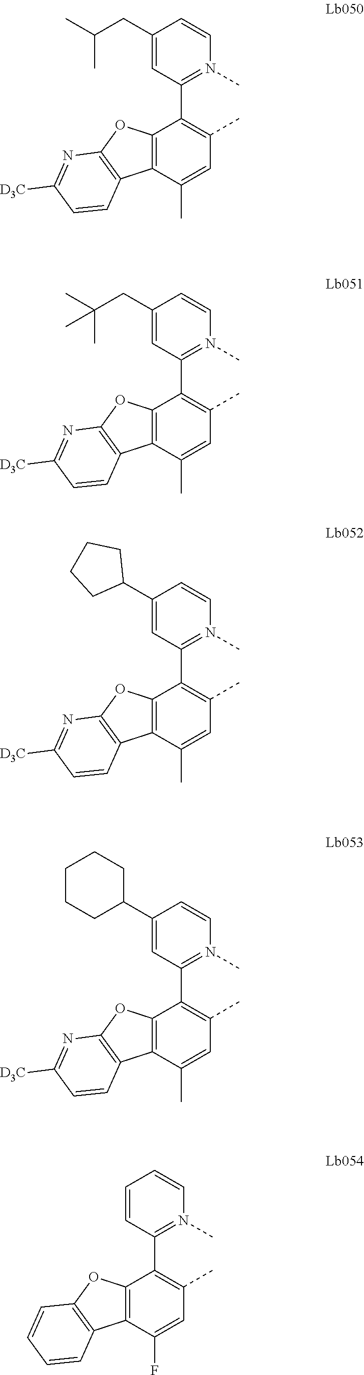

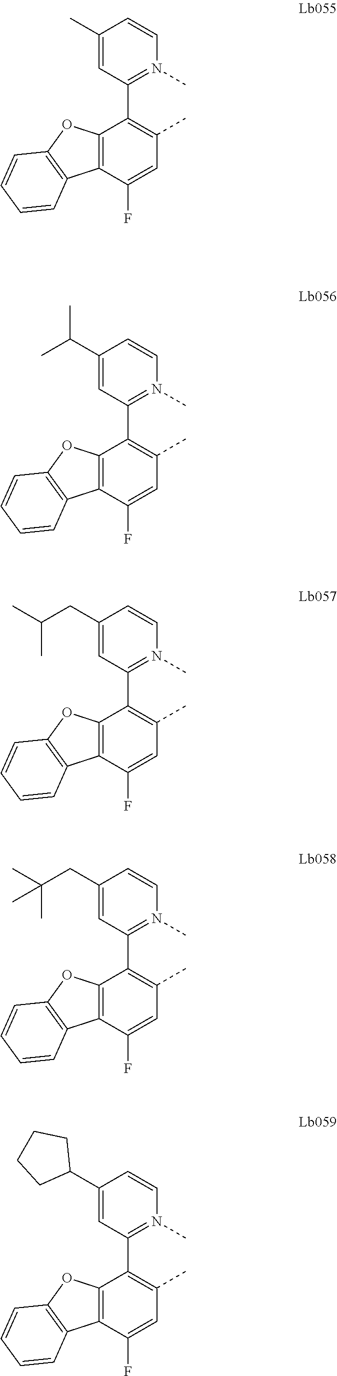

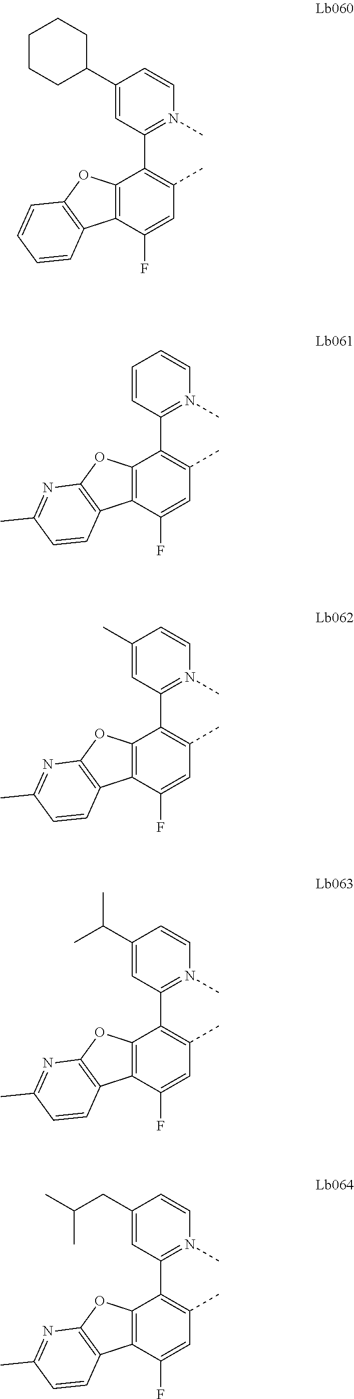

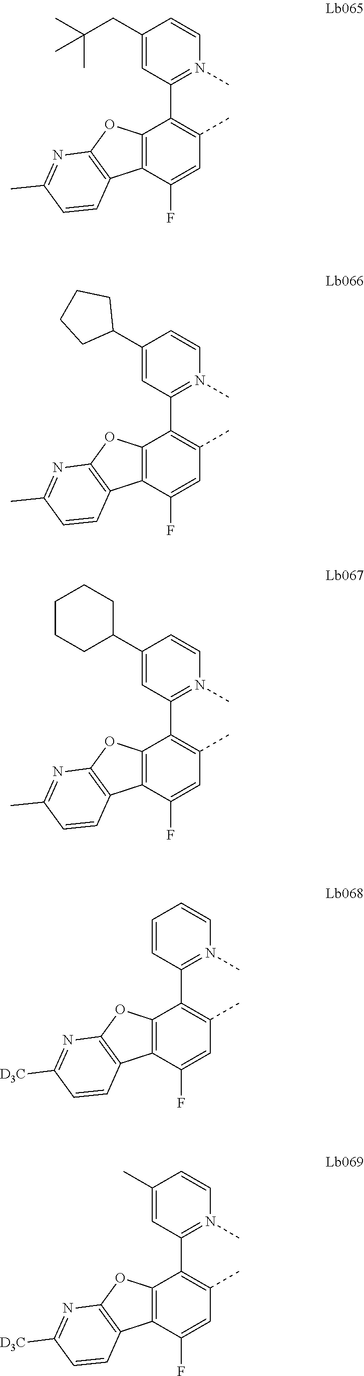

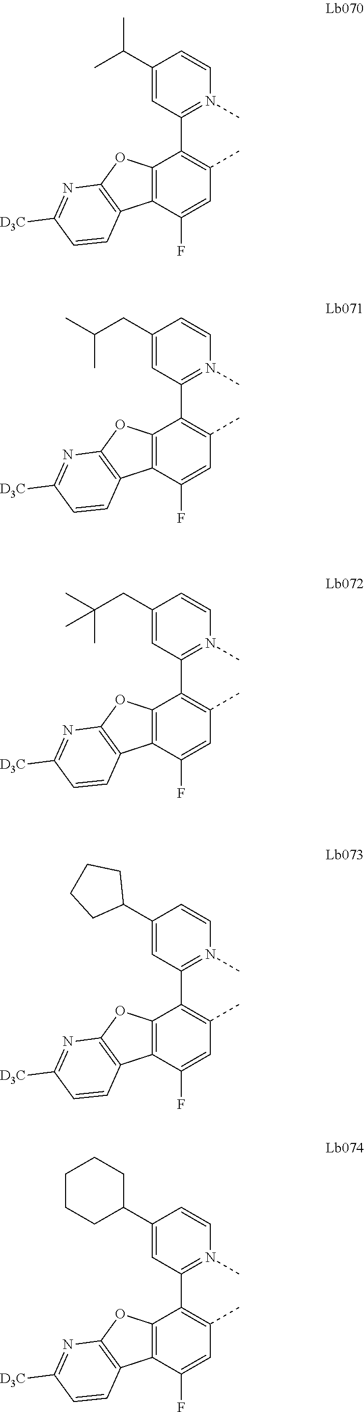

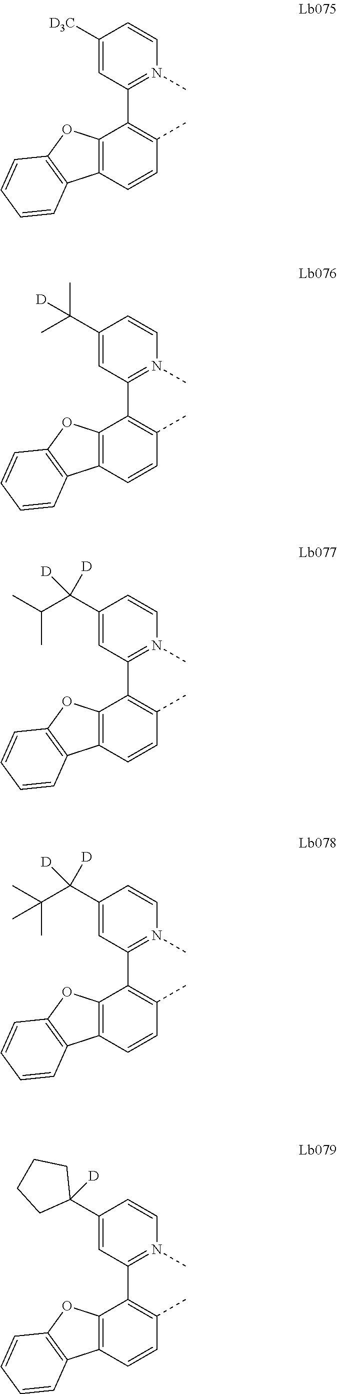

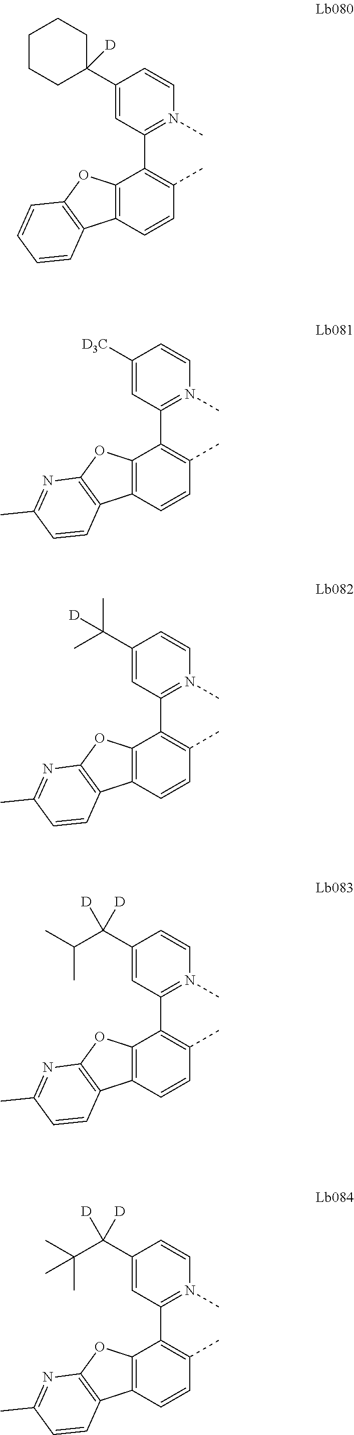

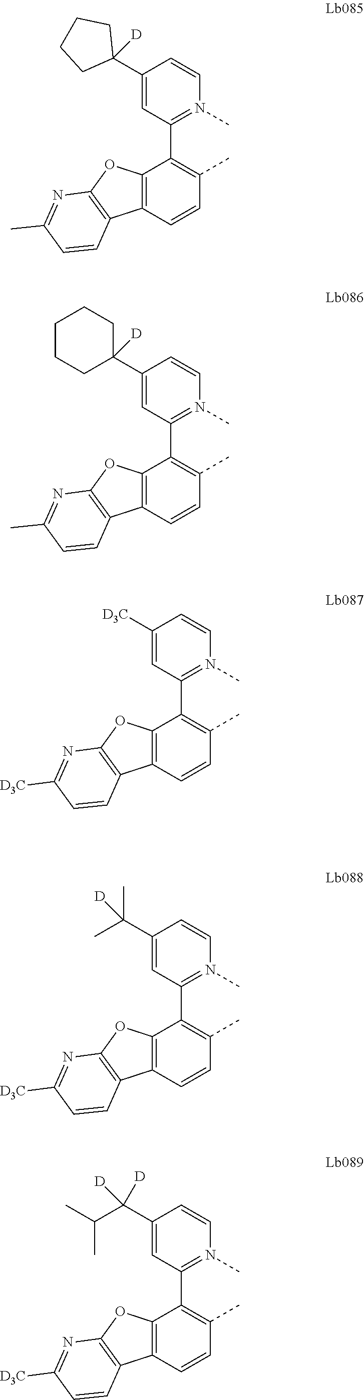

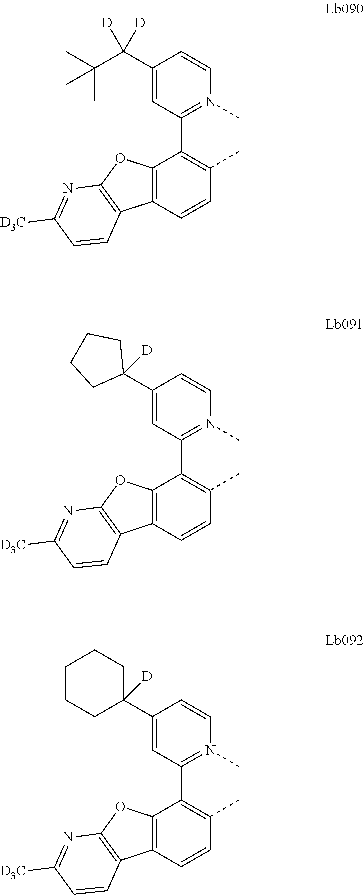

As a optional organometallic compound, the Lc optionally has one of the following structural formulas, or is partially or completely deuterated or fluorinated correspondingly.

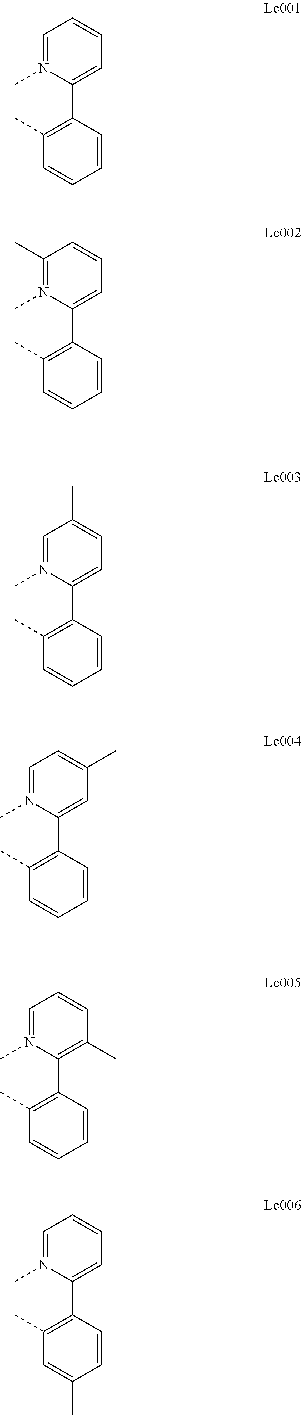

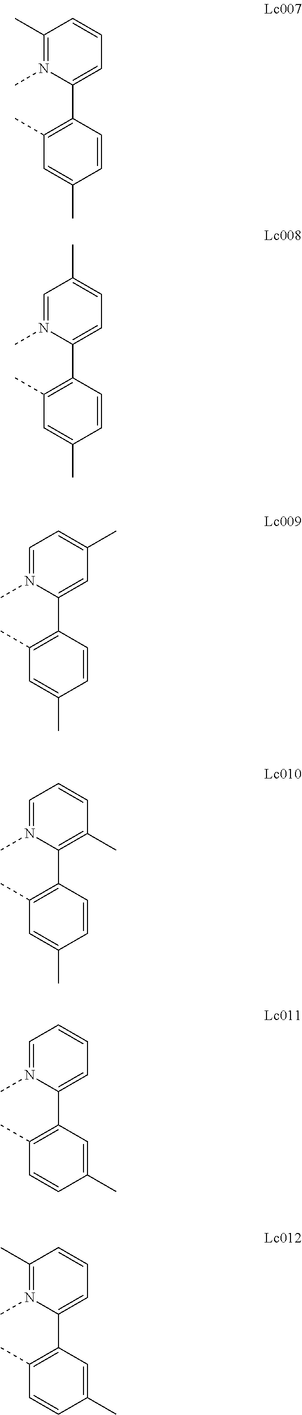

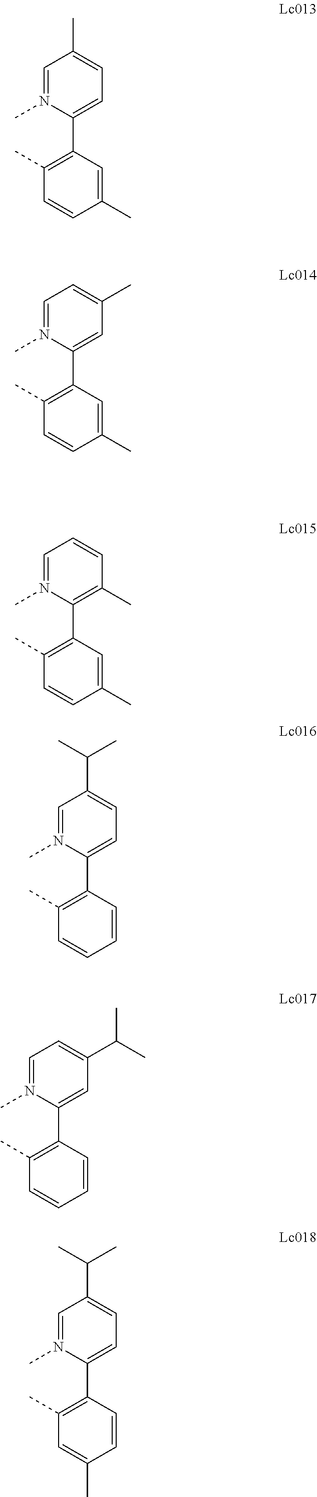

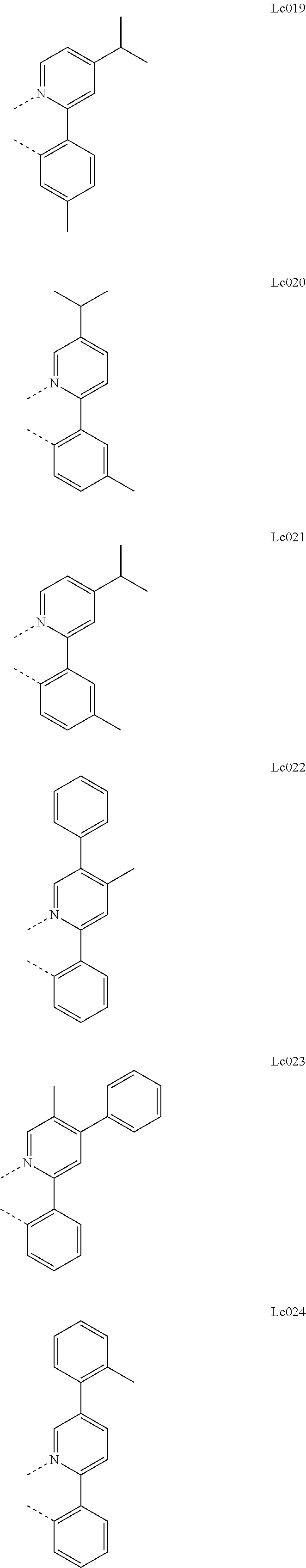

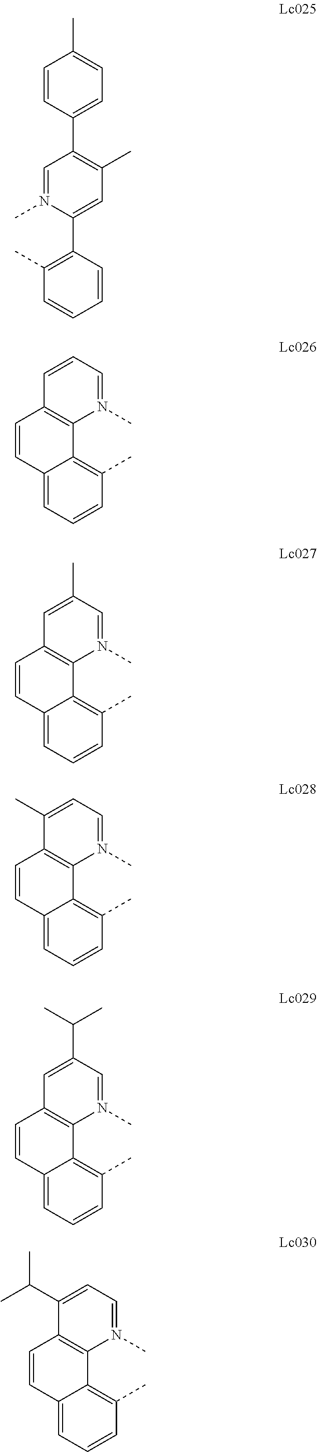

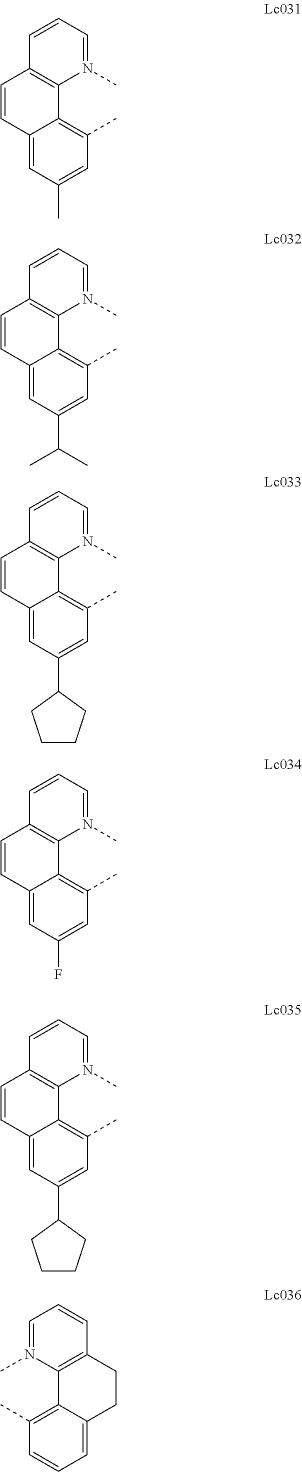

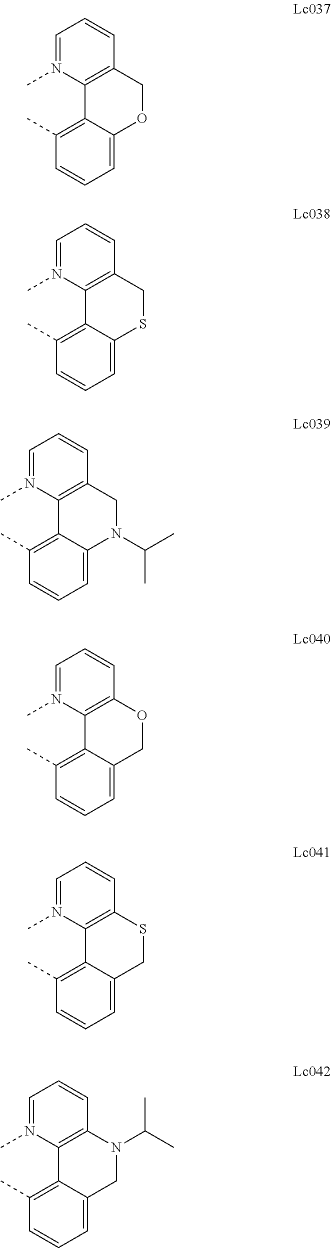

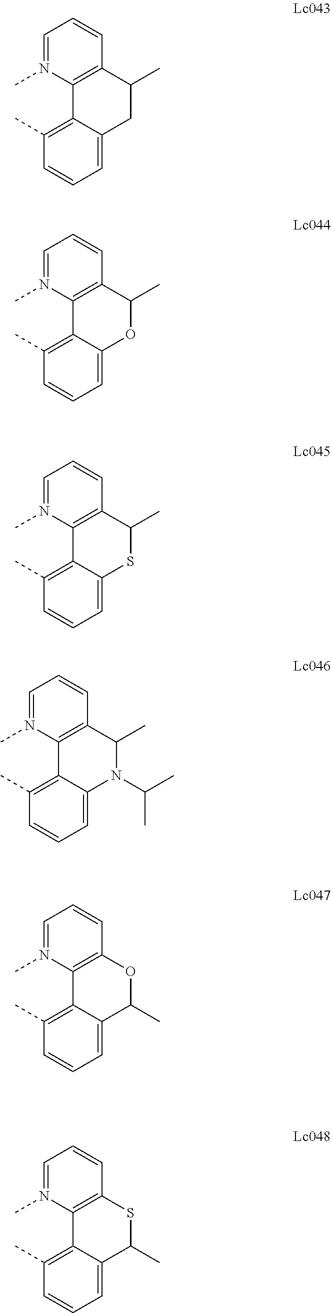

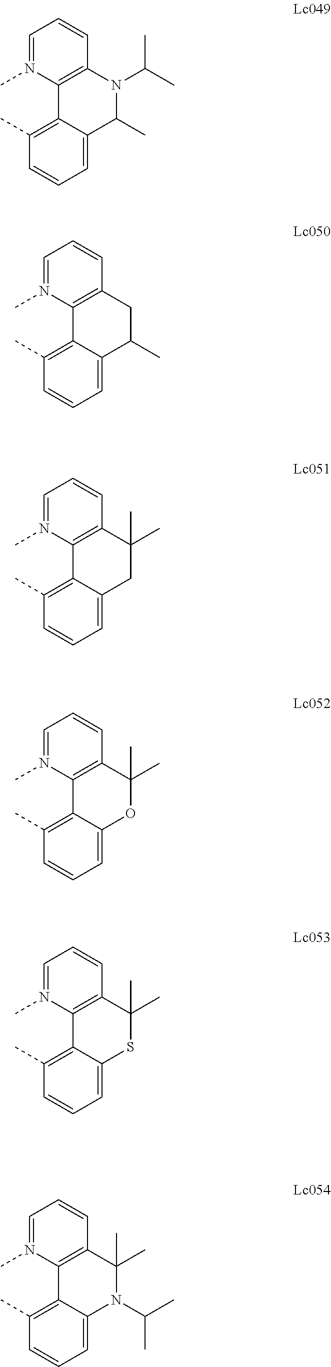

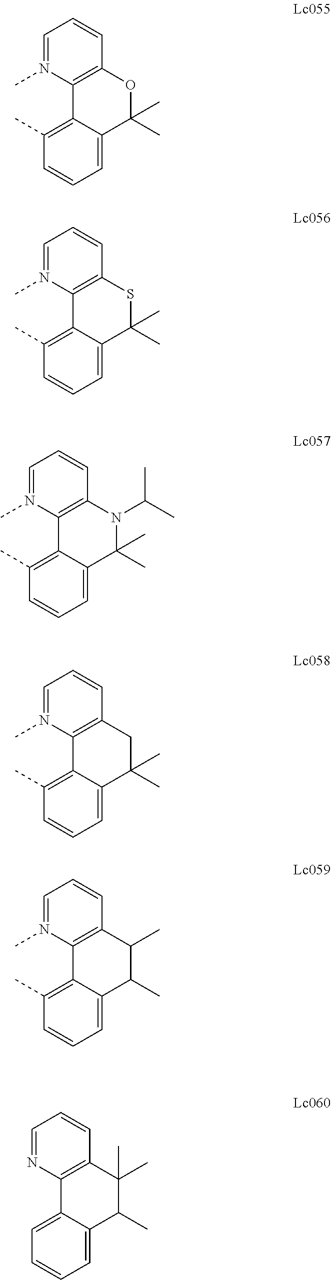

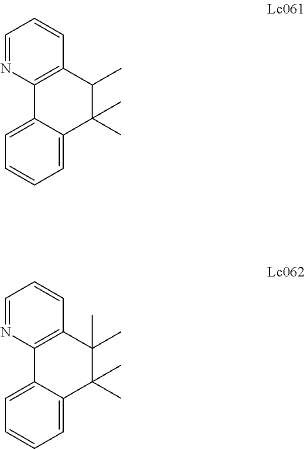 [SMILES: CC1c2cccnc2-c2ccccc2C1(C)C ; CC1(C)c2ccccc2-c2ncccc2C1(C)C]

One of objectives of the present invention is to provide an OLED phosphorescent material containing the compound.

One of objectives of the present invention is to provide an OLED containing the compound.

The material of the present invention has the advantages of high optical and electrical stability, narrow emission half-peak width, high color saturation, high luminous efficiency, long device service life and the like. As a phosphorescent material, the material of the present invention can convert a triplet state into light, thereby improving the luminous efficiency of organic electroluminescent devices and reducing energy consumption. In particular, the compound has the potential for application in the AMOLED industry as a green light-emitting dopant.

### BRIEF DESCRIPTION OF DRAWINGS

FIG. 1 shows the 1HNMR spectrum of a compound Ir(La001)(Lb012)₂ of the present invention in a deuterated chloroform solution.

FIG. 2 shows the ultraviolet absorption spectrum and emission spectrum of a compound Ir(La001)(Lb012)₂ of the present invention in a dichloromethane solution.

FIG. 3 shows the 1HNMR spectrum of a compound Ir(La001)₂(Lb012) of the present invention in a deuterated chloroform solution.

FIG. 4 shows the ultraviolet absorption spectrum and emission spectrum of a compound Ir(La001)₂(Lb012) of the present invention in a dichloromethane solution.

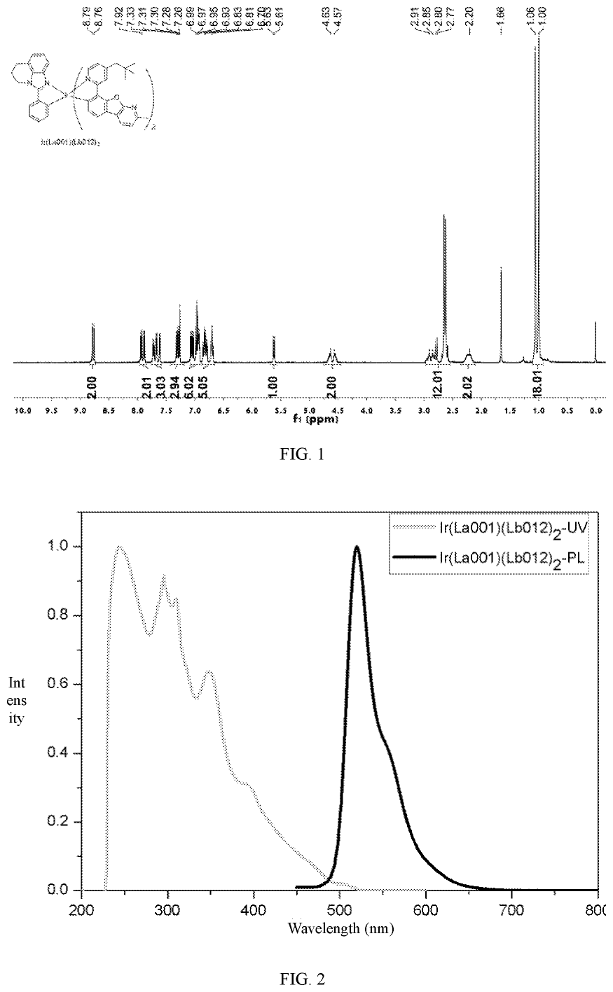

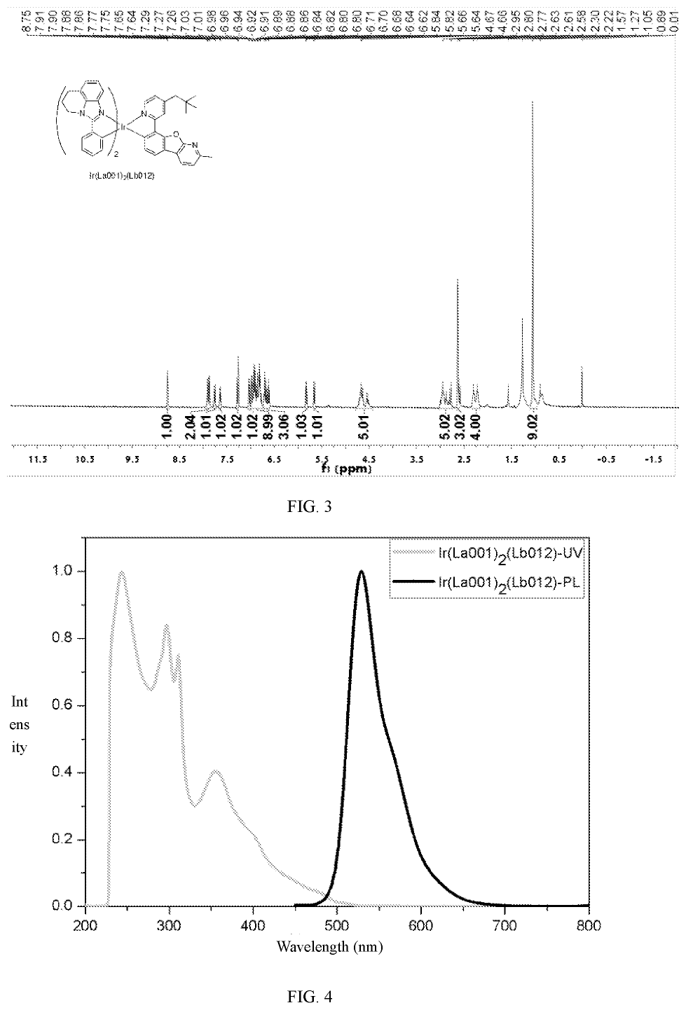

### DETAILED DESCRIPTION OF EMBODIMENTS

A compound of the present invention is an organometallic compound having a general formula of Ir(La)(Lb)(Lc), where La is a structure represented by Formula (1):

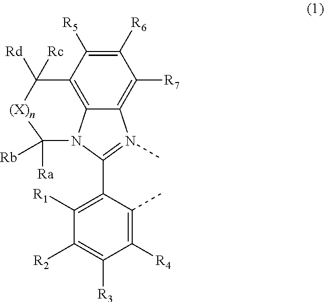

where dotted lines refer to positions connected to the metal Ir;
X is O, S, Se, CRpRq, SiRrRs or NRt;
n is an integer from 0 to 3, and when the n is equal to or greater than 2, multiple X groups are present at the same time and may be the same or different;
Ra, Rb, Rc, Rd, Rp, Rq, Rr, Rs and Rt are independently selected from hydrogen, deuterium, halogen, substituted or unsubstituted C₁-C₁₀ alkyl, substituted or unsubstituted C₃-C₂₀ cycloalkyl, substituted or unsubstituted C₆-C₁₈ aryl, and substituted or unsubstituted C₂-C₁₇ heteroaryl;
R₁-R₇ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₇ may be connected to each other to form an aliphatic ring structure or an aromatic ring structure;
the heteroalkyl and the heteroaryl at least contain one O, N or S heteroatom;
both Lb and Lc are a monoanionic bidentate ligand, the La, the Lb and the Lc may be the same or different, and the different indicates different parent nuclear structures, a same parent nuclear structure with different substituents, or a same parent nuclear structure with different substituent positions;
any two or three of the La, the Lb and the Lc may be connected to each other to form a polydentate ligand;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

In Formula (1), in a case of 2 or more substituents, the multiple substituents may be the same or different, respectively.

Examples of various groups of compounds represented by Formula (1) to Formula (3) are described below.

It is to be noted that in the specification, “Cₐ-C_{b}” in the term “substituted or unsubstituted Cₐ-C_{b} X group” refers to the number of carbons when the X group is unsubstituted, excluding the number of carbons of a substituent when the X group is substituted.

As a linear or branched alkyl, the C₁-C₁₀ alkyl specifically includes methyl, ethyl, propyl, isopropyl, n-butyl, isobutyl, sec-butyl, tert-butyl, n-pentyl and isomers thereof, n-hexyl and isomers thereof, n-heptyl and isomers thereof, n-octyl and isomers thereof, n-nonyl and isomers thereof, and n-decyl and isomers thereof, optionally includes methyl, ethyl, propyl, isopropyl, n-butyl, isobutyl, sec-butyl, and tert-butyl, and more optionally includes propyl, isopropyl, isobutyl, sec-butyl, and tert-butyl.

The C₃-C₂₀ cycloalkyl may include cyclopropyl, cyclobutyl, cyclopentyl, cyclohexyl, 1-adamantyl, 2-adamantyl, 1-norbornyl, and 2-norbornyl, and optionally includes cyclopentyl and cyclohexyl.

The C₂-C₁₀ alkenyl may include vinyl, propenyl, allyl, 1-butadienyl, 2-butadienyl, 1-hexatrienyl, 2-hexatrienyl, and 3-hexatrienyl, and optionally includes propenyl and allyl.

As a linear or branched alkyl or cycloalkyl consisting of atoms other than carbon and hydrogen, the C₁-C₁₀ heteroalkyl may include mercaptomethyl methyl, methoxymethyl, ethoxymethyl, tert-butoxyl methyl, N,N-dimethyl methyl, epoxy butyl, epoxy pentyl, and epoxy hexyl, and optionally includes methoxymethyl and epoxy pentyl.

Specific examples of the aryl include phenyl, naphthyl, anthracyl, phenanthryl, tetracenyl, pyrenyl, chrysenyl, benzo[c]phenanthryl,
benzo[g]chrysenyl, fluorenyl, benzofluorenyl, dibenzofluorenyl, biphenyl, triphenyl, tetraphenyl, and fluoranthracyl, and optionally include phenyl and naphthyl.

Specific examples of the heteroaryl may include pyrrolyl, pyrazinyl, pyridyl, pyrimidinyl, triazinyl, indolyl, isoindolyl, imidazolyl, furyl, benzofuryl, isobenzofuryl, dibenzofuryl, dibenzothienyl, azodibenzofuryl, azodibenzothienyl, diazodibenzofuryl, diazodibenzothienyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furzanyl, thienyl, benzothienyl, dihydroacridinyl, azocarbazolyl, diazocarbazolyl, and quinazolinyl, and optionally include pyridyl, pyrimidinyl, triazinyl, dibenzofuryl, dibenzothienyl, azodibenzofuryl, azodibenzothienyl, diazodibenzofuryl, diazodibenzothienyl, carbazolyl, azocarbazolyl, and diazocarbazolyl.

The following embodiments are merely described to facilitate the understanding of the technical invention, and should not be considered as specific limitations of the present invention.

All raw materials, solvents and the like involved in the synthesis of compounds in the present invention are purchased from Alfa, Acros, and other suppliers known to persons skilled in the art.

### Synthesis of a Ligand La001

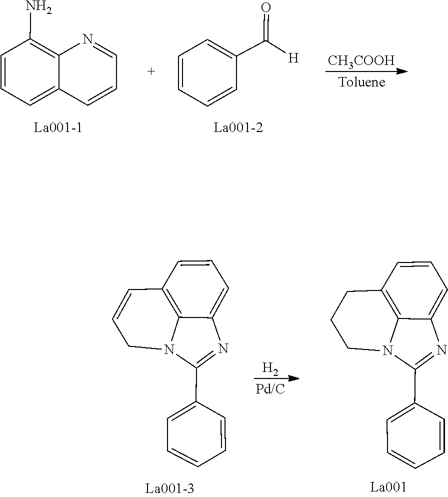

### Synthesis of a compound La001-3

A compound La001-1 (80.0 g, 0.55 mol, 1.0 eq), La001-2 (70.66 g, 0.66 mol, 1.20 eq), acetic acid (49.9 g, 0.83 mol, 1.5 eq) and toluene (400 ml) were added into a 1 L three-necked flask, vacuumization was performed for nitrogen replacement for 3 times, and stirring was performed at 110° C. for reflux for 18 hours under the protection of nitrogen. According to monitoring by thin-layer chromatography (TLC), the raw material La001-1 was completely reacted. Cooling was performed to room temperature, and 250 ml of deionized water was added for water washing and liquid separation. An organic phase on an upper layer was collected, concentrated to remove an organic solvent, spin-dried and separated by column chromatography (with an eluting agent including ethyl acetate and n-hexane at a ratio of 1:20), followed by drying to obtain 77.4 g of a grayish white solid compound La001-3 with a yield of 60.1%. The mass spectrum was: 233.28 (M+H).

### Synthesis of a Compound La001

The compound La001-3 (60.0 g, 0.25 mol, 1.0 eq), 10% Pd/C (3 g, 5% of the weight of the La001-3) and ethyl acetate (480 ml) were added into a 1 L one-necked flask, a hydrogen balloon was introduced after the flask was sealed, and stirring was performed to carry out a reaction at room temperature for 2.5 hours. According to monitoring by TLC, the raw material La001-3 was completely reacted. Cooling was performed to room temperature, and filtration was performed with diatomite. A filtrate was collected, concentrated to remove an organic solvent, spin-dried and separated by column chromatography (with an eluting agent including ethyl acetate and n-hexane at a ratio of 1:20), followed by drying to obtain a grayish white solid. Then, the solid was crystallized with dichloromethane (150 ml) and n-hexane (300 ml) to obtain 38.3 g of a compound La001 with a yield of 63.4%. The mass spectrum was: 235.3 (M+H).

### Synthesis of a Compound Ir(La001)(Lb002)₂

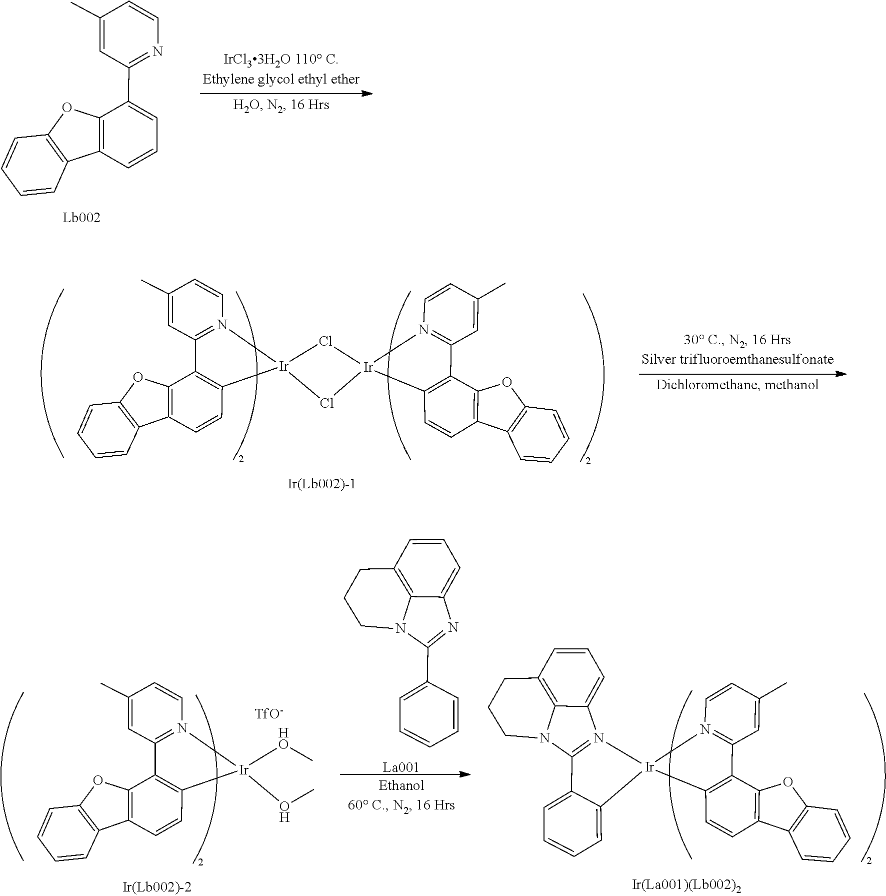

### Synthesis of a Compound Ir(Lb002)-1

A compound Lb002 (10.4 g, 40.1 mmol, 3.0 eq) and IrCl₃·3H₂O (4.5 g, 13.37 mmol, 1.0 eq) were added into a 1 L one-necked flask, ethylene glycol ethyl ether (100 ml) and deionized water (30 ml) were added, vacuumization was performed for replacement for 3 times, and a mixture was stirred at 110° C. for reflux for 16 hours under the protection of N₂. After cooling was performed to room temperature, filtration was performed. A filter reside was sequentially washed with methanol (50 ml*3) and n-hexane (50 ml*3), and a solid was collected and dried to obtain 7.98 g of a compound Ir(Lb002)-1 with a yield of 80.2%. The obtained compound was directly used in the next step without purification.

### Synthesis of a compound Ir(Lb002)-2

The dimer Ir (Lb002)-1 (7.98 g, 10.7 mmol, 1.0 eq) and dichloromethane (700 ml) were added into a 3 L three-necked flask and stirred for dissolution. Silver trifluoromethanesulfonate (5.51 g, 21.4 mmol, 2.0 eq) was dissolved in methanol (510 ml) and then added into the original reaction solution flask, vacuumization was performed for replacement for 3 times, and a mixture was stirred at room temperature for 16 hours under the protection of N₂. Then, a reaction solution was filtered with diatomite. A filter residue was rinsed with dichloromethane (100 ml), and a filtrate was spin-dried to obtain 7.57 g of a compound Ir(Lb002)-2 with a yield of 79.2%. The obtained compound was directly used in the next step without purification.

### Synthesis of a Compound Ir(La001)(Lb002)₂

The compound Ir(Lb002)-2 (6.5 g, 7.29 mmol, 1.0 eq) and the La001 (4.27 g, 18.22 mmol, 2.5 eq) were added into a 250 ml three-necked flask, ethanol (65 ml) was added, vacuumization was performed for replacement for 3 times, and stirring was performed for reflux for 16 hours under the protection of N₂. After cooling was performed to room temperature, filtration was performed. A solid was collected, dissolved in dichloromethane (150 ml) and filtered with silica gel. Then, a filter cake was rinsed with dichloromethane (50 ml), and a filtrate was spin-dried, recrystallized with tetrahydrofuran/methanol for 2 times (the ratio of the product to the tetrahydrofuran to the methanol was 1:7:10) and beaten with n-hexane (60 ml) for 1 time, followed by drying to obtain 3.10 g of a compound Ir(La001)(Lb002)₂ with a yield of 45.1%. 3.1 g of the crude product Ir(La001)(Lb002)₂ was sublimated and purified to obtain 1.84 g of sublimated and purified Ir(La001)(Lb002)₂ with a yield of 59.35%. The mass spectrum was: 943.09 (M+H). ¹H NMR (400 MHZ, CDCl₃) δ 8.61 (d, J=12.6 Hz, 2H), 7.98 (dd, J=18.2, 7.1 Hz, 2H), 7.84 (m, 3H), 7.77 (m, 2H), 7.69 (m, 2H), 7.60-7.18 (m, 11H), 7.05 (dd, J=16.6, 6.4 Hz, 2H), 3.99 (t, 2H), 2.97 (t, 2H), 2.42 (s, 6H), 2.26 (dt, 2H).

### Synthesis of a Compound Ir(La001)(Lb005)₂

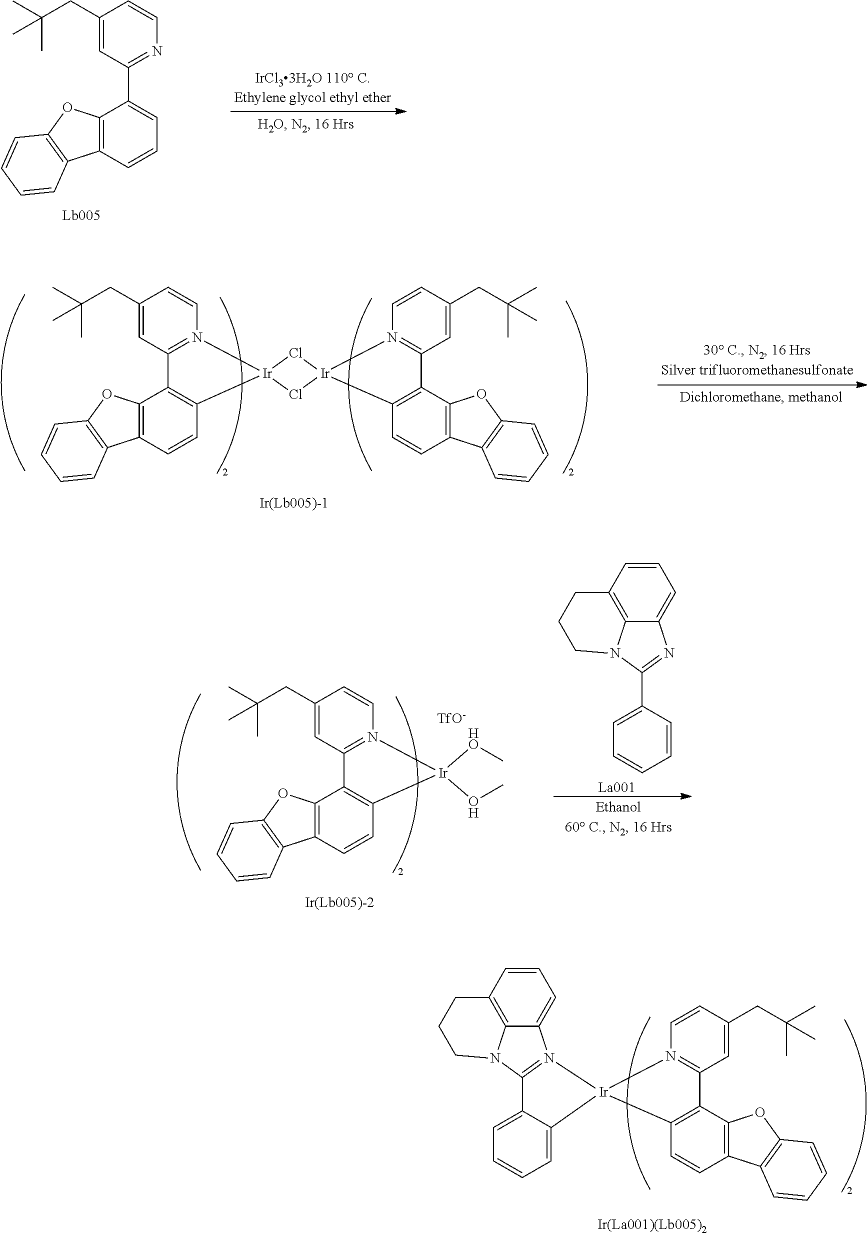

### Synthesis of a Compound Ir(Lb005)-1

With reference to synthesis and purification methods of the compound Ir(Lb002)-1, only the corresponding raw materials were required to be changed, and an obtained compound was directly used in the next step without purification.

### Synthesis of a Compound Ir(Lb005)-2

With reference to synthesis and purification methods of the compound Ir(Lb002)-2, only the corresponding raw materials were required to be changed, and an obtained compound was directly used in the next step without purification.

### Synthesis of a Compound Ir(La001)(Lb005)₂

With reference to synthesis and purification methods of the compound Ir(La001)(Lb002)₂, only the corresponding raw materials were required to be changed, and 4.32 g of a target compound Ir(La001)(Lb005)₂ with a yield of 51.8% was obtained. 4.32 g of the crude product Ir(La001)(Lb005)₂ was sublimated and purified to obtain 2.89 g of sublimated and purified Ir(La001)(Lb005)₂ with a yield of 66.89%. The mass spectrum was: 1055.43 (M+H). ¹H NMR (400 MHZ, CDCl₃) δ 8.65 (d, J=13.1 Hz, 2H), 7.88 (dd, J=17.2, 7.6 Hz, 2H), 7.84 (d, 2H), 7.77 (m, 2H), 7.69 (m, 3H), 7.60-7.47 (m, 4H), 7.46-7.36 (m, 4H), 7.31 (m, 2H), 7.22 (d, 2H), 7.05 (d, 2H), 3.99 (t, J=5.5 Hz, 2H), 3.21 (s, 4H), 2.97 (t, J=5.9 Hz, 2H), 2.31-2.21 (m, 2H), 0.85 (s, 18H).

### Synthesis of a Compound Ir(La001)(Lb012)₂

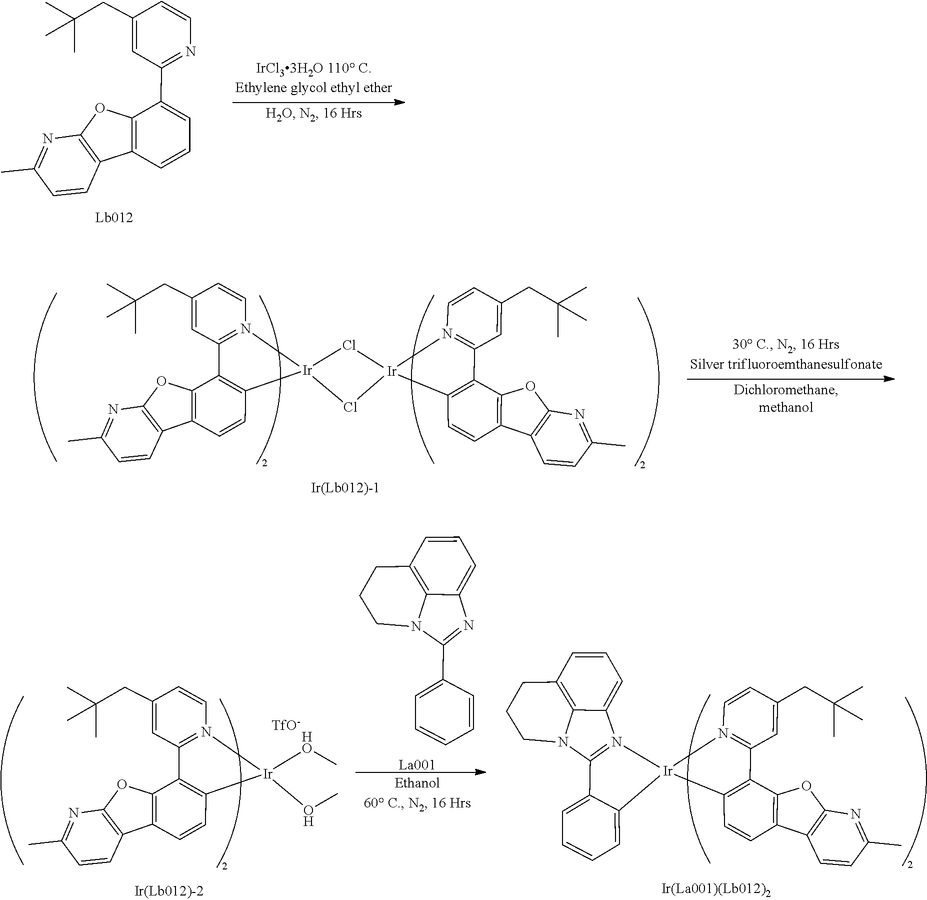

### Synthesis of a Compound Ir(Lb012)-1

With reference to synthesis and purification methods of the compound Ir(Lb002)-1, only the corresponding raw materials were required to be changed, and an obtained compound was directly used in the next step without purification.

### Synthesis of a Compound Ir(Lb012)-2

With reference to synthesis and purification methods of the compound Ir(Lb002)-2, only the corresponding raw materials were required to be changed, and an obtained compound was directly used in the next step without purification.

### Synthesis of a Compound Ir(La001)(Lb012)₂

With reference to synthesis and purification methods of the compound Ir(La001)(Lb002)₂, only the corresponding raw materials were required to be changed, and 4.14 g of a target compound Ir(La001)(Lb012)₂ with a yield of 48.9% was obtained. 4.14 g of the crude product Ir(La001)(Lb012)₂ was sublimated and purified to obtain 2.71 g of sublimated and purified Ir(La001)(Lb012)₂ with a yield of 65.45%. The mass spectrum was: 1085.33 (M+H). ¹H NMR (400 MHZ, CDCl₃) δ 8.78 (d, J=12.9 Hz, 2H), 7.91 (dd, J=19.3, 7.7 Hz, 2H), 7.77-7.58 (m, 3H), 7.43-7.19 (m, 3H), 7.00 (ddd, J=23.3, 14.6, 7.7 Hz, 6H), 6.77 (ddd, J=41.2, 15.7, 7.8 Hz, 5H), 5.62 (d, J=8.1 Hz, 1H), 4.60 (d, J=25.0 Hz, 2H), 2.83 (dd, J=36.7, 17.4 Hz, 12H), 2.20 (s, 2H), 1.03 (d, J=25.1 Hz, 18H).

### Synthesis of a Compound Ir(La001)₂(Lb012)

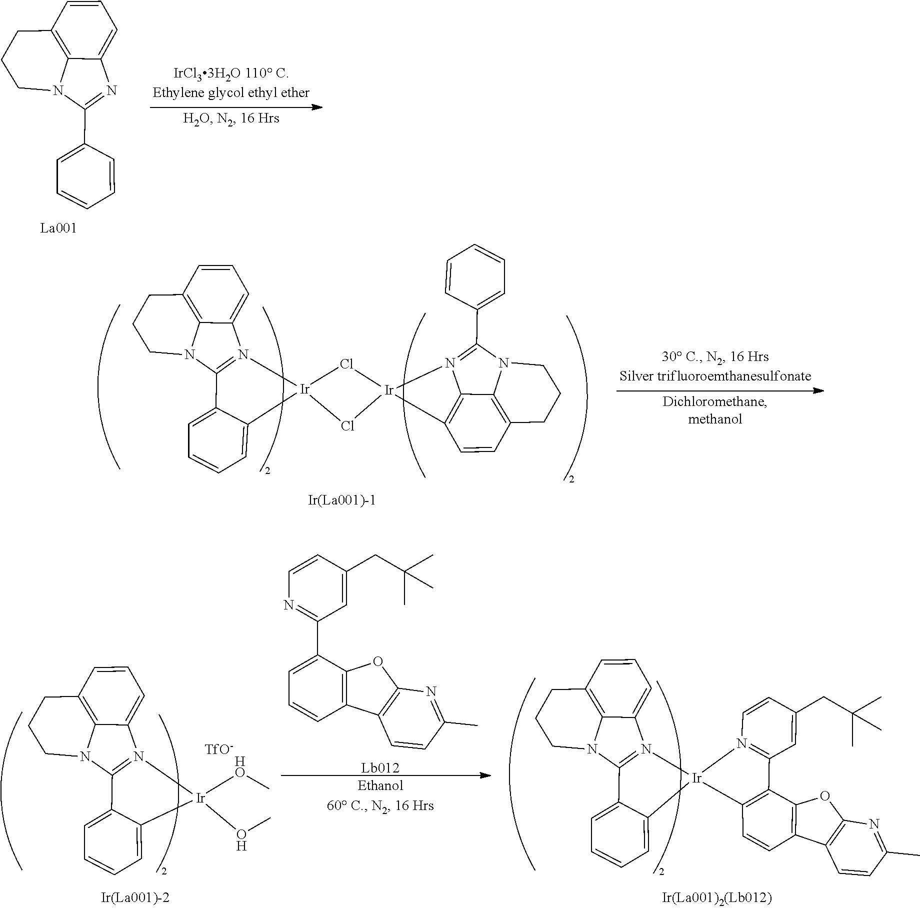

### Synthesis of a Compound Ir(La001)-1

With reference to synthesis and purification methods of the compound Ir(Lb002)-1, only the corresponding raw materials were required to be changed, and an obtained compound was directly used in the next step without purification.

### Synthesis of a Compound Ir(La001)-2

With reference to synthesis and purification methods of the compound Ir(Lb002)-2, only the corresponding raw materials were required to be changed, and an obtained compound was directly used in the next step without purification.

### Synthesis of a Compound Ir(La001)₂(Lb012)

With reference to synthesis and purification methods of the compound Ir(La001)(Lb002)₂, only the corresponding raw materials were required to be changed, and 3.36 g of a target compound Ir(La001)₂(Lb012) with a yield of 42.7% was obtained. 3.36 g of the crude product Ir(La001)₂(Lb012) was sublimated and purified to obtain 2.29 g of sublimated and purified Ir(La001)₂(Lb012) with a yield of 68.15%. The mass spectrum was: 989.21 (M+H). ¹H NMR (400 MHZ, CDCl₃) δ 8.75 (s, 1H), 7.89 (dd, J=13.2, 6.6 Hz, 2H), 7.76 (d, J=7.3 Hz, 1H), 7.64 (d, J=6.1 Hz, 1H), 7.28 (d, J=8.0 Hz, 1H), 7.02 (d, J=7.7 Hz, 1H), 6.99-6.74 (m, 9H), 6.72-6.60 (m, 3H), 5.83 (d, J=8.2 Hz, 1H), 5.65 (d, J=8.1 Hz, 1H), 4.78-4.42 (m, 5H), 2.85 (dd, J=51.3, 22.0 Hz, 5H), 2.62 (d, J=7.5 Hz, 3H), 2.26 (d, J=31.6 Hz, 4H), 1.05 (s, 9H).

### Synthesis of a Compound Ir(La001)(Lb012)(Lc003)

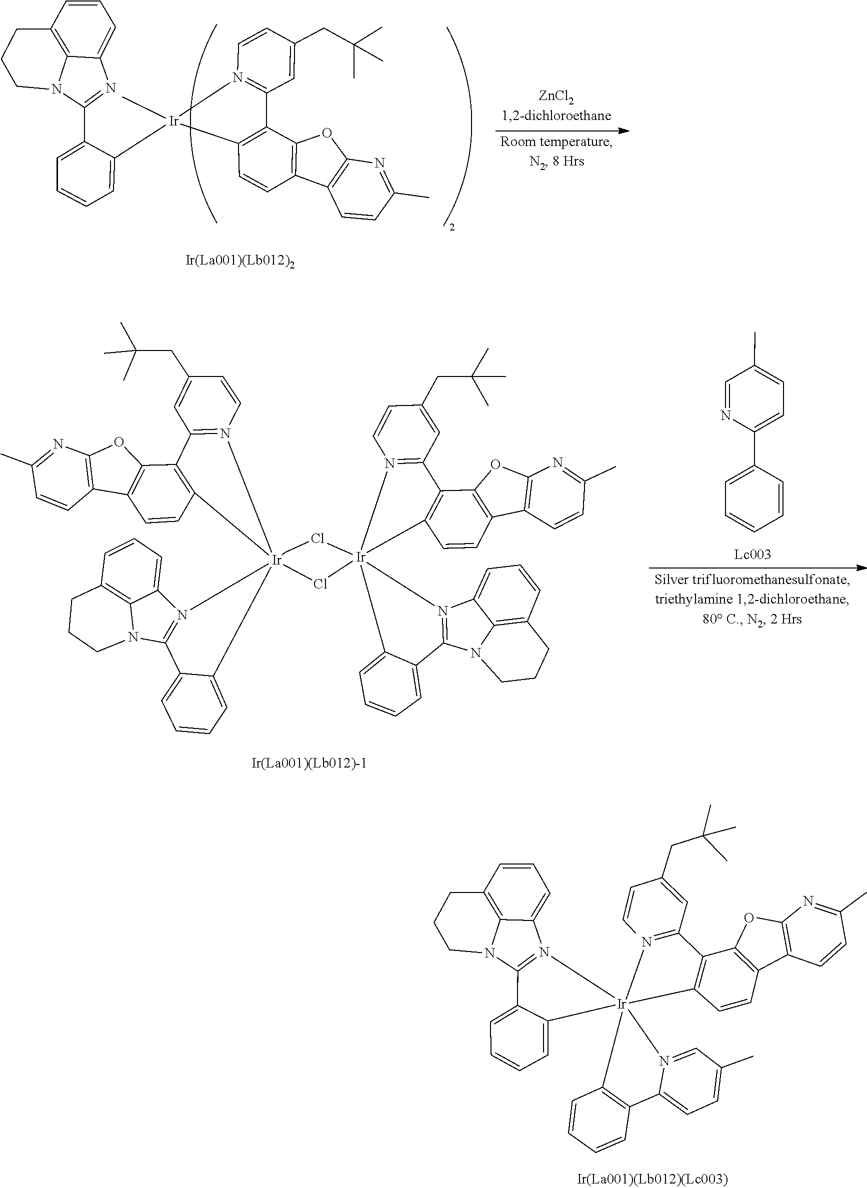

### Synthesis of a Compound Ir(La001)(Lb012)-1

The compound Ir(La001)(Lb012)₂ (5.42 g, 5.0 mmol, 1.0 eq) and zinc chloride (34.06 g, 249.9 mmol, 50 eq) were added into a 1 L one-necked flask, 1,2-dichloroethane (352 ml) was added, vacuumization was performed for replacement for 3 times, and stirring was performed to carry out a reflux reaction for 18 hours under the protection of N₂. According to point-plate monitoring by TLC, the raw material Ir(La001)(Lb012)₂ was basically completely reacted. After cooling was performed to room temperature, deionized water (150 ml) was added for washing for 3 times, and a filtrate was spin-dried to obtain 3.37 g of a compound Ir(La001)(Lb012)-1 with a yield of 85.3%. The obtained compound was directly used in the next step without purification.

### Synthesis of a Compound Ir(La001)(Lb012)(Lc003)

The dimer Ir(La001)(Lb012)-1 (3.37 g, 4.26 mmol, 1.0 eq), silver trifluoromethanesulfonate (3.29 g, 12.79 mmol, 3.0 eq), Lc003 (2.16 g, 12.79 mmol, 3.0 eq), triethylamine (4.31 g, 42.64 mmol, 10 eq) and 1,2-dichloroethane (240 ml) were added into a 500 ml three-necked flask, vacuumization was performed for replacement for 3 times, and a mixture was heated and stirred to carry out a reflux reaction for 3 hours under the protection of N₂. According to point-plate monitoring by TLC, the dimer Ir(La001)(Lb012)-1 was completely consumed. Cooling was performed to room temperature. Then, a reaction solution was filtered with diatomite, a filter residue was rinsed with dichloromethane (100 ml), and a filtrate was spin-dried to obtain a crude product. The crude product was separated by column chromatography (with an eluting agent including dichloromethane and n-hexane at a ratio of 1:10), and a resulting product was recrystallized with tetrahydrofuran/methanol for 2 times (the ratio of the product to the tetrahydrofuran to the methanol was 1:5:5) and beaten with n-hexane (40 ml) for 1 time, followed by drying to obtain 1.32 g of a compound Ir(La001)(Lb012)(Lc003) with a yield of 33.6%. 1.32 g of the crude product Ir(La001)(Lb012)(Lc003) was sublimated and purified to obtain 0.87 g of sublimated and purified Ir(La001)(Lb012)(Lc003) with a yield of 65.9%. The mass spectrum was: 924.13 (M+H). ¹H NMR (400 MHZ, CDCl₃) δ 8.72 (s, 1H), 8.32 (d, J=23.0 Hz, 2H), 8.16 (m, 2H), 7.84 (m, 2H), 7.80-7.66 (m, 3H), 7.58 (m, 2H), 7.54-7.39 (m, 5H), 7.25 (d, J=35.0 Hz, 2H), 7.03 (d, J=20.0 Hz, 2H), 3.99 (t, 2H), 3.22 (s, 2H), 2.98 (t, 2H), 2.68 (s, 3H), 2.32 (s, 3H), 2.26 (dt, 2H), 0.96 (s, 9H).

### Synthesis of a Compound Ir(La001)(Lb012)(Lc008)

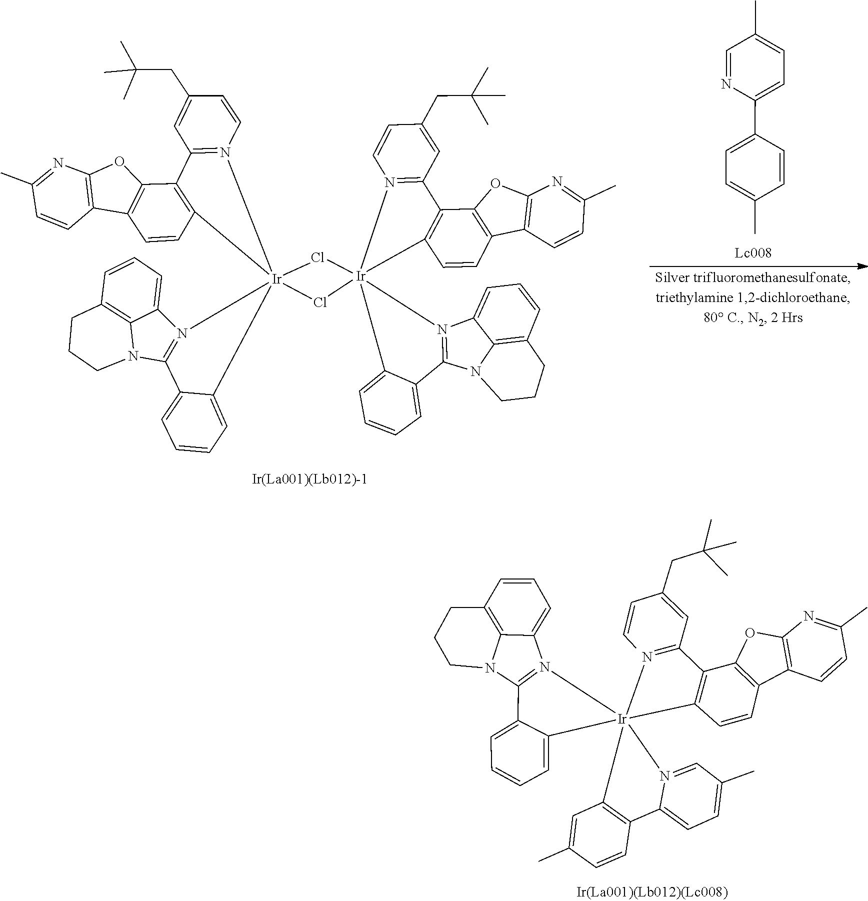

### Synthesis of a Compound Ir(La001)(Lb012)(Lc008)

With reference to synthesis and purification methods of the compound Ir(La001)(Lb012)(Lc003), only the corresponding raw materials were required to be changed, and 1.47 g of a target compound Ir(La001)(Lb012)(Lc008) with a yield of 30.81% was obtained. 1.47 g of the crude product Ir(La001)(Lb012)(Lc008) was sublimated and purified to obtain 1.01 g of sublimated and purified Ir(La001)(Lb012)(Lc008) with a yield of 68.70%. The mass spectrum was: 938.16 (M+H). ¹H NMR (400 MHZ, CDCl₃) δ 8.67(d, J=34.3 Hz, 2H), 8.30 (m, 2H), 8.11 (m, 2H), 7.84 (d, 2H), 7.80-7.67 (m, 3H), 7.62-7.38 (m, 4H), 7.33-7.17 (m, 3H), 7.03 (d, J=20.0 Hz, 2H), 3.89 (t, 2H), 3.21 (s, 2H), 2.99 (t, 2H), 2.68 (s, 3H), 2.31 (d, J=5.0 Hz, 6H), 2.26 (dt, 2H), 0.97 (s, 9H).

### Synthesis of a Compound Ir(La001)(Lb012)(Lc026)

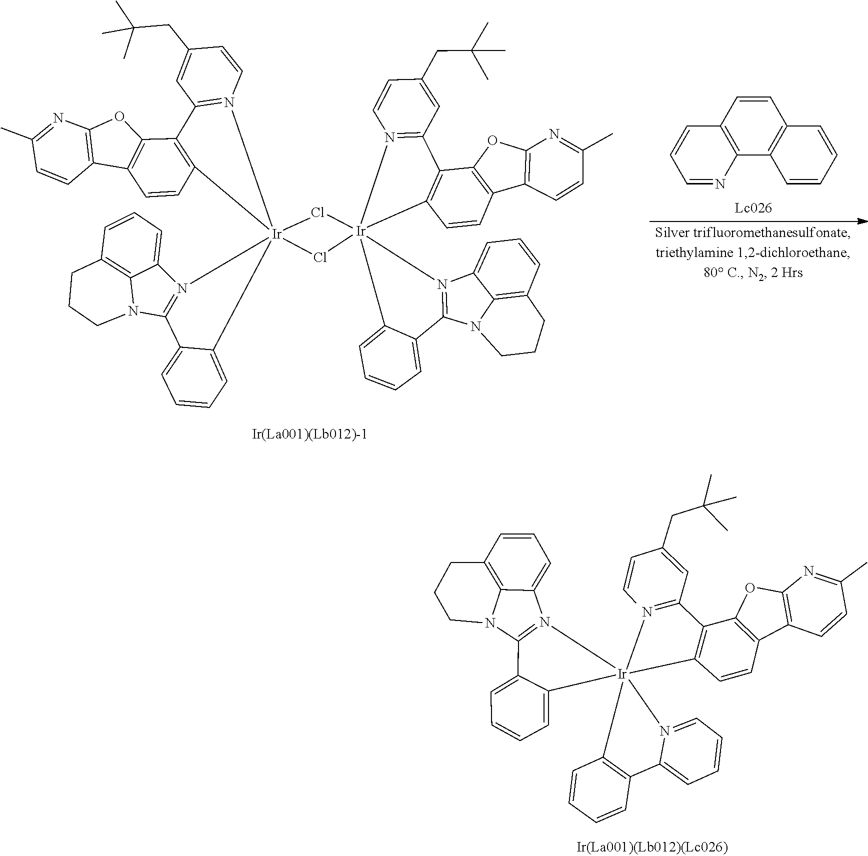

With reference to synthesis and purification methods of the compound Ir(La001)(Lb012)(Lc003), only the corresponding raw materials were required to be changed, and 1.55 g of a target compound Ir(La001)(Lb012)(Lc026) with a yield of 36.32% was obtained. 1.55 g of the crude product Ir(La001)(Lb012)(Lc026) was sublimated and purified to obtain 1.1 g of sublimated and purified Ir(La001)(Lb012)(Lc026) with a yield of 70.96%. The mass spectrum was: 934.13 (M+H). ¹H NMR (400 MHZ, CDCl₃) δ 8.90 (s, 1H), 8.49 (d, J=5.0 Hz, 2H), 8.10 (m, 2H), 7.88-7.73 (m, 4H), 7.69 (m, 2H), 7.62-7.35 (m, 7H), 7.22 (d, 2H), 7.03 (d, J=20.0 Hz, 2H), 3.95 (t, 2H), 3.25 (s, 2H), 2.97 (t, 2H), 2.68 (s, 3H), 2.28 (dt, 2H), 0.90 (s, 9H).

### Synthesis of a Compound Ir(La001)(Lb012)(Lc062)

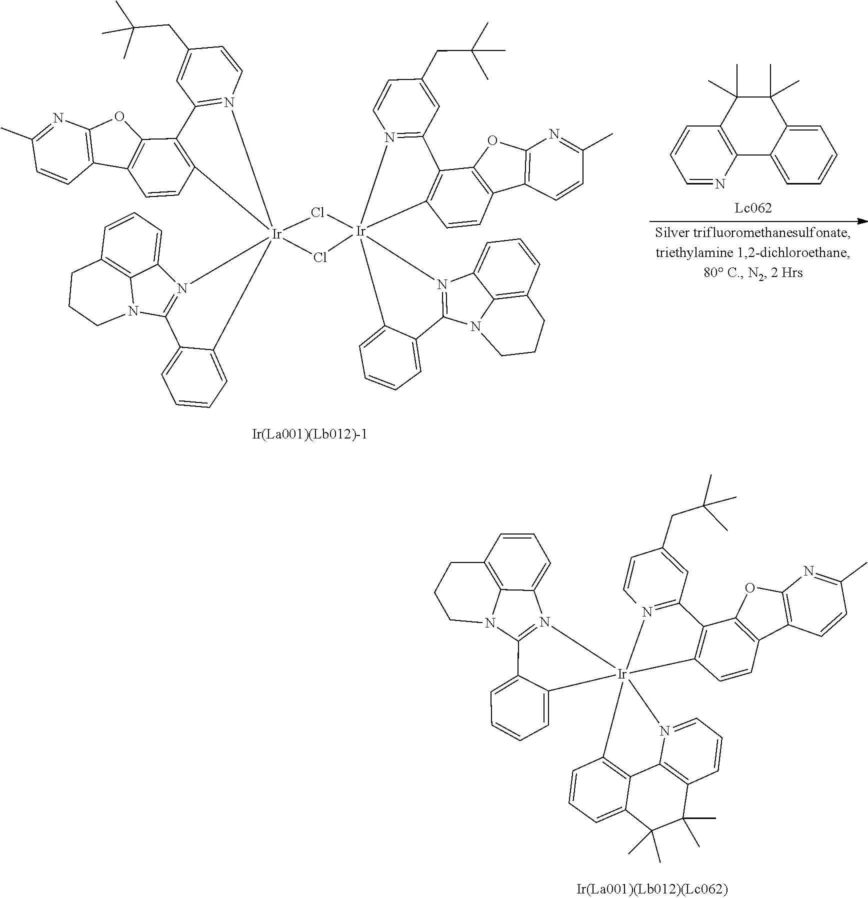

With reference to synthesis and purification methods of the compound Ir(La001)(Lb012)(Lc003), only the corresponding raw materials were required to be changed, and 1.27 g of a target compound Ir(La001)(Lb012)(Lc062) with a yield of 29.8% was obtained. 1.27 g of the crude product Ir(La001)(Lb012)(Lc062) was sublimated and purified to obtain 0.83 g of sublimated and purified Ir(La001)(Lb012)(Lc062) with a yield of 65.35%. The mass spectrum was: 992.25 (M+H). ¹H NMR (400 MHZ, CDCl₃) δ 8.72 (d, J=17.1 Hz, 2H), 8.35 (m, 2H), 7.81 (d, J=35.0 Hz, 2H), 7.69 (m, 2H), 7.64-7.38 (m, 5H), 7.38-7.17 (m, 3H), 7.03 (d, J=20.0 Hz, 2H), 6.67 (m, 2H), 3.94 (t, 2H), 3.23 (s, 2H), 2.97 (t, 2H), 2.66 (s, 3H), 2.24 (dt, 2H), 1.35 (s, 12H), 0.88 (s, 9H).

### Synthesis of a Compound Ir(La001)(Lb001)(Lb012)

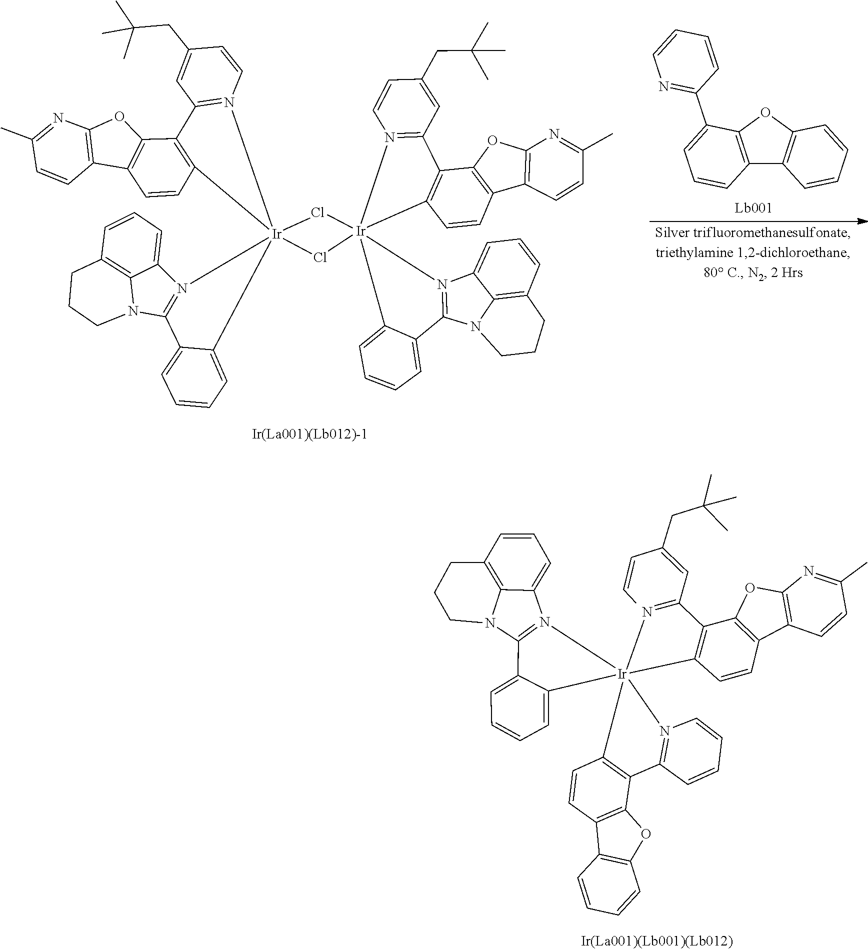

With reference to synthesis and purification methods of the compound Ir(La001)(Lb012)(Lc003), only the corresponding raw materials were required to be changed, and 1.21 g of a target compound Ir(La001)(Lb001)(Lb012) with a yield of 32.3% was obtained. 1.21 g of the crude product Ir(La001)(Lb001)(Lb012) was sublimated and purified to obtain 0.87 g of sublimated and purified Ir(La001)(Lb001)(Lb012) with a yield of 71.90%. The mass spectrum was: 1000.19 (M+H). ¹H NMR (400 MHZ, CDCl₃) δ 8.67 (d, J=28.0 Hz, 2H), 8.37 (m, 2H), 7.98 (m, 2H), 7.84 (m, 2H), 7.77 (d, 1H), 7.69 (m, 2H), 7.44 (ddd, J=55.0, 40.0, 27.5 Hz, 8H), 7.26-7.10 (m, 2H), 7.03 (d, J=20.0 Hz, 2H), 6.90 (s, 1H), 3.99 (t, 2H), 3.21 (s, 2H), 2.97 (t, 2H), 2.68 (s, 3H), 2.26 (dt, 2H), 0.85 (s, 9H).

### Synthesis of a Ligand La033

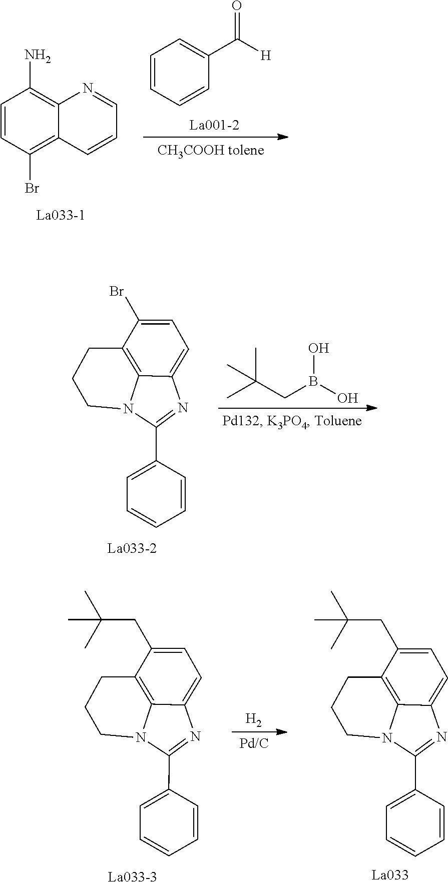

### Synthesis of a Compound La033-2

With reference to synthesis and purification methods of the compound La001-3, only the corresponding raw materials were required to be changed. The mass spectrum was: 312.1 (M+H).

### Synthesis of a Compound La033-3

The compound La033-2 (15 g, 48.2 mmol, 1.0 eq), isobutaneboronic acid (6.71 g, mmol, 57.85 1.2 eq), bis(di-tert-butyl(4-dimethylaminophenyl)phosphine)dichloropalladium (II) (0.68 g, 0.96 mmol, 0.02 eq), K₃PO₄ (20.46 g, 96.41 mmol, 2.0 eq) and toluene (150 ml) were sequentially added into a 500 ml three-necked flask, vacuumization was performed for nitrogen replacement for 3 times, and the above compounds were heated to about 70° C. in an oil bath and stirred for 16 hours. According to monitoring of a sample by TLC, the raw material La033-2 was basically completely reacted. Cooling was performed to room temperature, and deionized water was added for water washing for 3 times (100 ml/time). Then, liquid separation was performed, and an organic phase was concentrated under reduced pressure to obtain a solid. The crude product was separated by column chromatography (with a mixture of ethyl acetate (EA) and n-hexane (Hex) at a ratio of 1:20), and a resulting product was dried to obtain 9.59 g of a white-like solid compound La033-3 with a yield of 65.8%. The mass spectrum was: 303.4 (M+H).

### Synthesis of a Compound La033

With reference to synthesis and purification methods of the compound La001, only the corresponding raw materials were required to be changed. The mass spectrum was: 305.4 (M+H).

### Synthesis of a Compound Ir(La001)(La033)(Lb012)

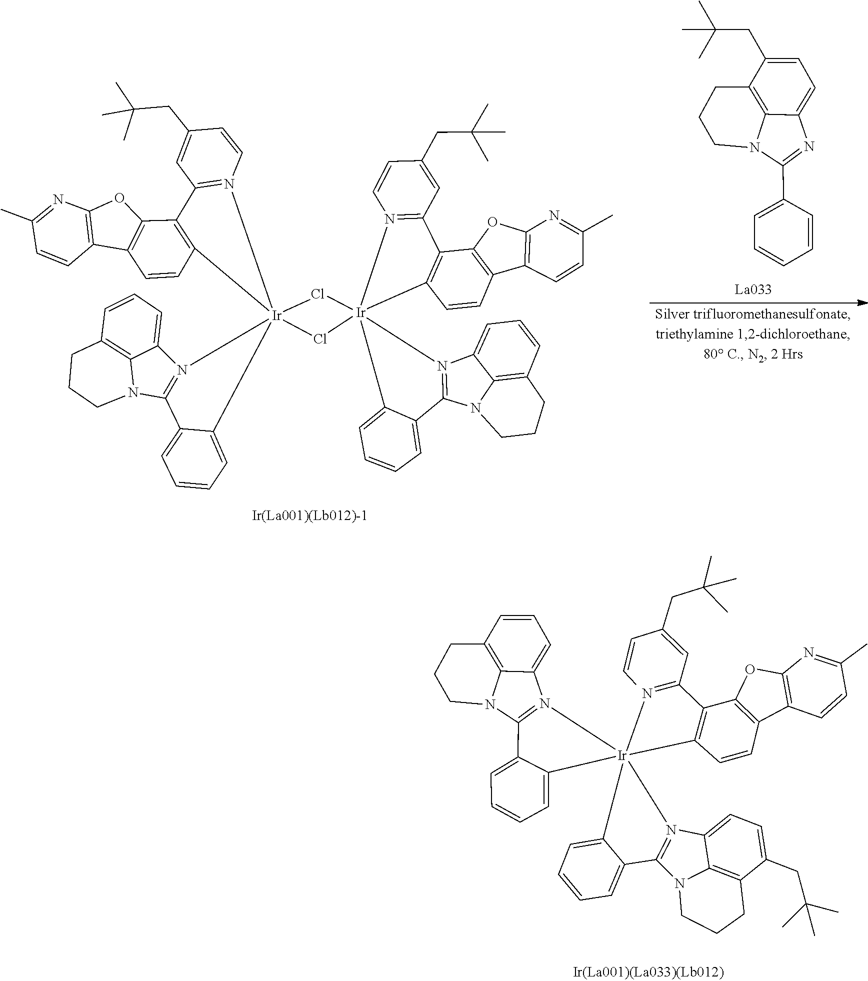

With reference to synthesis and purification methods of the compound Ir(La001)(Lb012)(Lc003), only the corresponding raw materials were required to be changed, and 1.42 g of a target compound Ir(La001)(La033)(Lb012) with a yield of 34.71% was obtained. 1.42 g of the crude product Ir(La001)(La033)(Lb012) was sublimated and purified to obtain 0.97 g of sublimated and purified Ir(La001)(La033)(Lb012) with a yield of 68.3%. The mass spectrum was: 1059.3 (M+H). ¹H NMR (400 MHZ, CDCl₃) δ 8.64 (d, J=10.1 Hz, 2H), 7.86-7.65 (m, 4H), 7.62-7.37 (m, 7H), 7.22 (m, 4H), 7.11-6.96 (m, 3H), 3.95 (t, 4H), 3.21 (s, 2H), 2.98 (t, 4H), 2.67 (d, J=15.0 Hz, 5H), 2.26 (dt, 4H), 0.96 (s, 18H).

### Synthesis of a Ligand La005

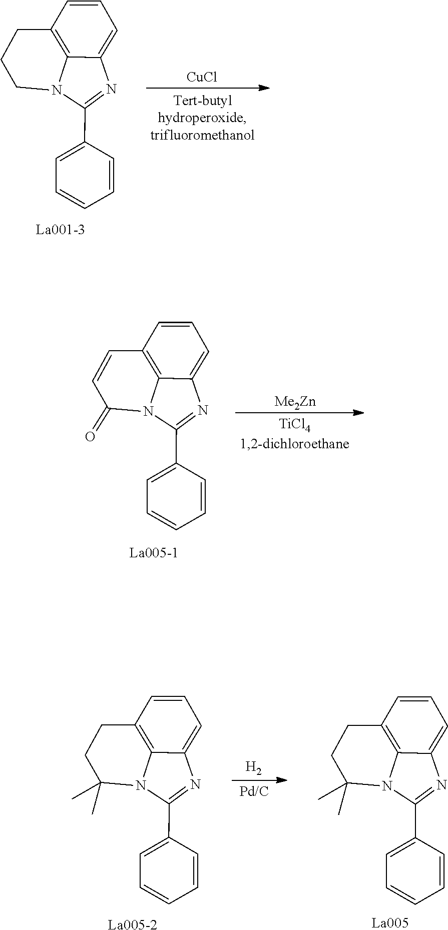

### Synthesis of a Compound La005-1

The compound La001-3 (20 g, 86.1 mmol, 1.0 eq), cuprous chloride (0.85 g, 8.61 mmol, 0.1 eq), tert-butyl hydroperoxide (15.52 g, 172.2 mmol, 2.0 eq) and trifluoroethanol (200 ml) were sequentially added into a 1 L three-necked flask, vacuumization was performed for nitrogen replacement for 3 times, and the above compounds were heated to about 50° C. in an oil bath and stirred for 6 hours. According to monitoring of a sample by TLC, the raw material La001-3 was basically completely reacted. Cooling was performed to room temperature, and deionized water was added for water washing for 3 times (100 ml/time). Then, liquid separation was performed, and an organic phase was concentrated under reduced pressure to obtain a solid. The crude product was separated by column chromatography (with a mixture of EA and Hex at a ratio of 1:10), and a resulting product was dried to obtain 11.45 g of a white-like solid compound La005-1 with a yield of 54.0%. The mass spectrum was: 247.2 (M+H).

### Synthesis of a Compound La005-2

The compound La005-1 (8 g, 32.49 mmol, 1.0 eq), dimethyl zinc (9.3 g, 97.46 mmol, 3.0 eq) and trifluoroethanol (200 ml) were sequentially added into a 1 L three-necked flask, vacuumization was performed for nitrogen replacement for 3 times, and the reaction system was cooled to −30° C. Titanium tetrachloride (18.49 g, 97.46 mmol, 3.0 eq) was slowly added dropwise, and after the dropping was completed, the above compounds were stirred at room temperature for 2 hours. According to monitoring of a sample by TLC, the raw material La005-1 was basically completely reacted. Deionized water (100 ml) was slowly added for quenching, and ethyl acetate (250 ml) was added. Then, stirring was performed for extraction and liquid separation, and an organic phase was concentrated under reduced pressure to obtain a solid. The crude product was separated by column chromatography (with a mixture of EA and Hex at a ratio of 1:20), and a resulting product was dried to obtain 6.82 g of a white-like solid compound La005-2 with a yield of 80.7%. The mass spectrum was: 261.3 (M+H).

### Synthesis of a Compound La005

With reference to synthesis and purification methods of the compound La001, only the corresponding raw materials were required to be changed. The mass spectrum was: 263.3 (M+H).

### Synthesis of a Compound Ir(La005)₂(Lb012)

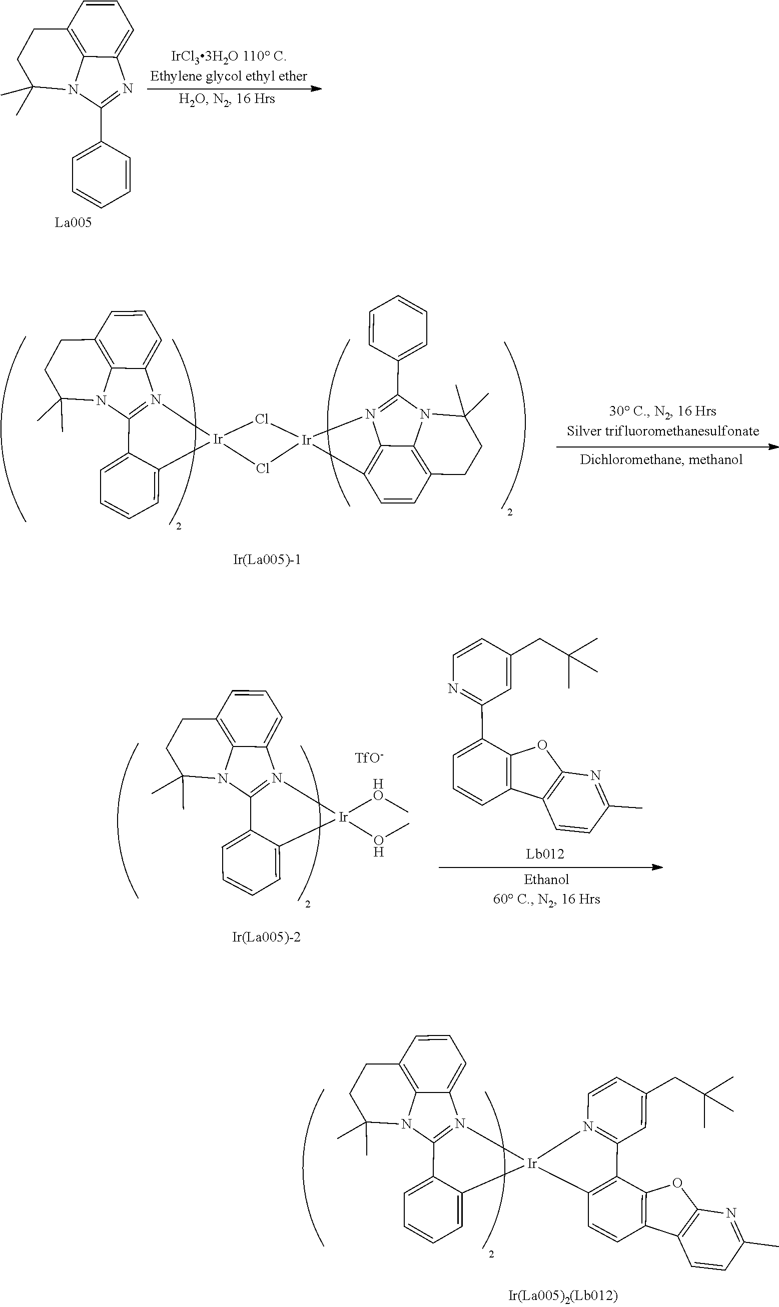

### Synthesis of a Compound Ir(La005)-1

With reference to synthesis and purification methods of the compound Ir(Lb002)-1, only the corresponding raw materials were required to be changed, and an obtained compound was directly used in the next step without purification.

### Synthesis of a Compound Ir(La005)-2

With reference to synthesis and purification methods of the compound Ir(Lb002)-2, only the corresponding raw materials were required to be changed, and an obtained compound was directly used in the next step without purification.

### Synthesis of a Compound Ir(La005)₂(Lb012)

With reference to synthesis and purification methods of the compound Ir(La001)(Lb002)₂, only the corresponding raw materials were required to be changed, and 3.14 g of a target compound Ir(La005)₂(Lb012) with a yield of 43.1% was obtained. 3.14 g of the crude product Ir(La005)₂(Lb012) was sublimated and purified to obtain 2.03 g of sublimated and purified Ir(La005)₂(Lb012) with a yield of 64.6%. The mass spectrum was: 1045.31 (M+H). ¹H NMR (400 MHZ, CDCl₃) δ 8.71 (, 1H), 8.40 (d, 1H), 7.81 (d, J=35.0 Hz, 3H), 7.69 (m, 3H), 7.62-7.38 (m, 8H), 7.22 (m, 3H), 7.03 (d, J=20.0 Hz, 2H), 3.21 (s, 2H), 2.97 (t, 4H), 2.68 (s, 3H), 2.21 (t, 4H), 1.45 (s, 12H), 0.89(s, 9H).

### Synthesis of a Compound Ir(La033)(Lb012)(Lc008)

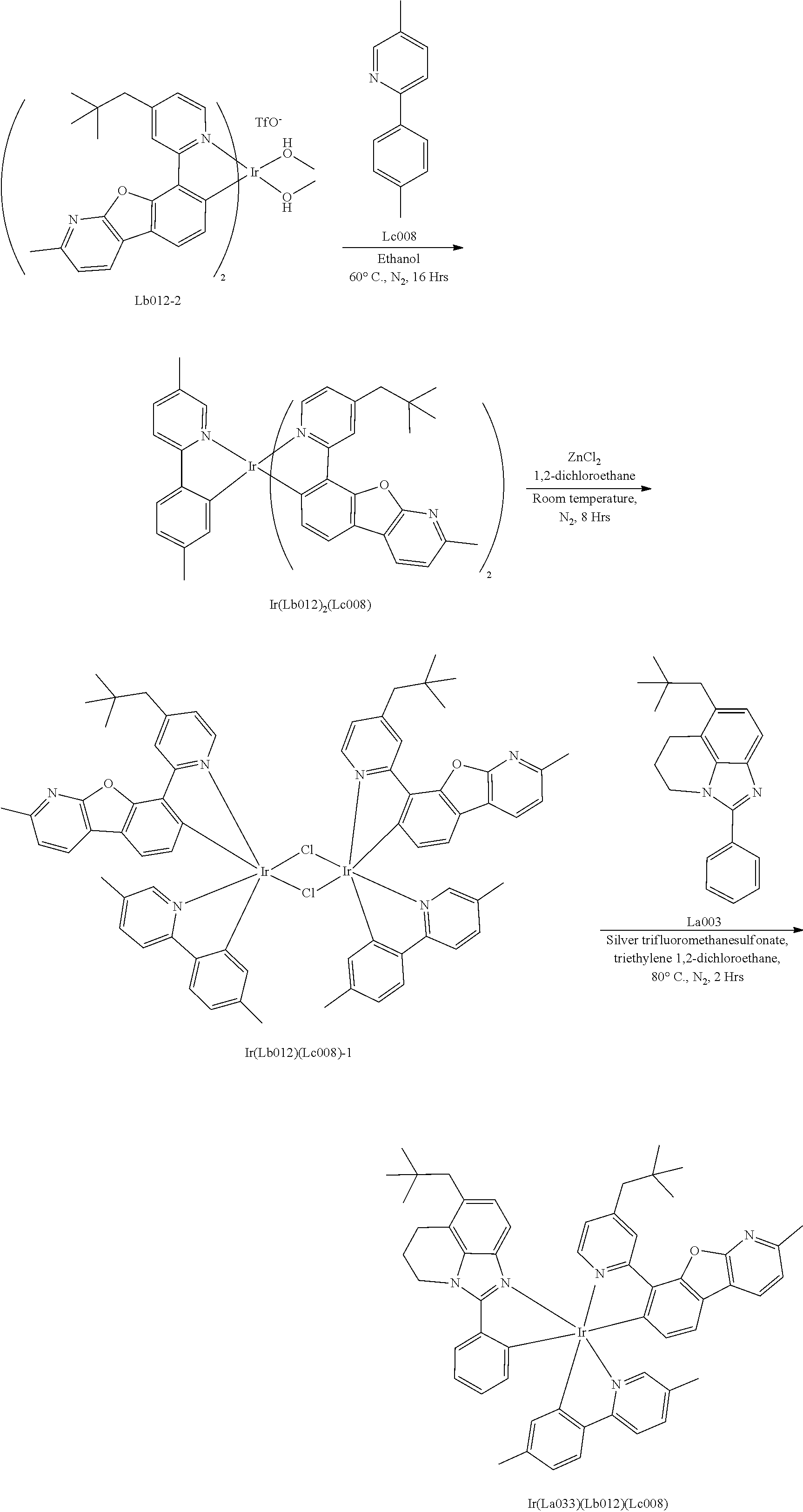

### Synthesis of a Compound Ir(Lb012)₂(Lc008)

With reference to synthesis and purification methods of the compound Ir(La001)(Lb002)₂, only the corresponding raw materials were required to be changed, and 5.33 g of a target compound Ir(Lb012)₂(Lc008) with a yield of 47.91% was obtained. The mass spectrum was: 887.11 (M+H).

### Synthesis of a Compound Ir(Lb012)(Lc008)-1

With reference to synthesis and purification methods of the compound Ir(La001)(Lb012)-1, only the corresponding raw materials were required to be changed, and an obtained compound was directly used in the next step without purification.

### Synthesis of a Compound Ir(La033)(Lb012)(Lc008)

With reference to synthesis and purification methods of the compound Ir(La001)(Lb012)(Lc003), only the corresponding raw materials were required to be changed, and 1.41 g of a target compound Ir(La033)(Lb012)(Lc008) with a yield of 31.22% was obtained. 1.41 g of the crude product Ir(La033)(Lb012)(Lc008) was sublimated and purified to obtain 0.88 g of sublimated and purified Ir(La033)(Lb012)(Lc008) with a yield of 62.41%. The mass spectrum was: 1045.31 (M+H). ¹H NMR (400 MHZ, CDCl₃)_{8 8.67} (s, 1H), 8.34 (d, J=35.5 Hz, 2H), 8.11 (m, 2H), 7.84 (m, 2H), 7.79-7.66 (m, 3H), 7.54 (d, J=40.0 Hz, 2H), 7.42 (m, 2H), 7.28 (d, J=15.0 Hz, 2H), 7.12-6.97 (m, 3H), 3.99 (t, 2H), 3.22 (s, 2H), 2.98 (t 2H), 2.67 (d, J=15.0 Hz, 5H), 2.31 (d, J=5.0 Hz, 6H), 2.26 (dt, 2H), 0.85 (s, 18H).

### Synthesis of a Ligand La034

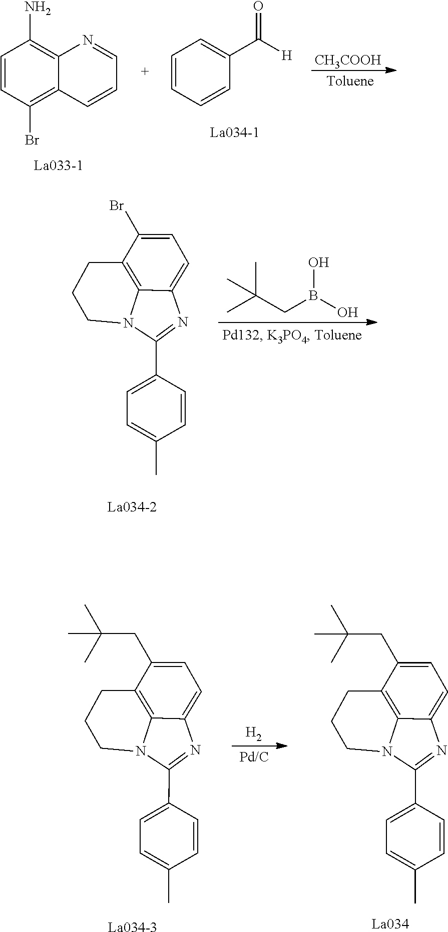

### Synthesis of a Compound La034-2

With reference to synthesis and purification methods of the compound La001-3, only the corresponding raw materials were required to be changed. The mass spectrum was: 326.2 (M+H).

### Synthesis of a Compound La034-3

With reference to synthesis and purification methods of the compound La033-4, only the corresponding raw materials were required to be changed. The mass spectrum was: 317.4 (M+H).

### Synthesis of a Compound La034

With reference to synthesis and purification methods of the compound La001, only the corresponding raw materials were required to be changed. The mass spectrum was: 319.4 (M+H).

### Synthesis of a Compound Ir(La034)(Lb012)(Lc008)

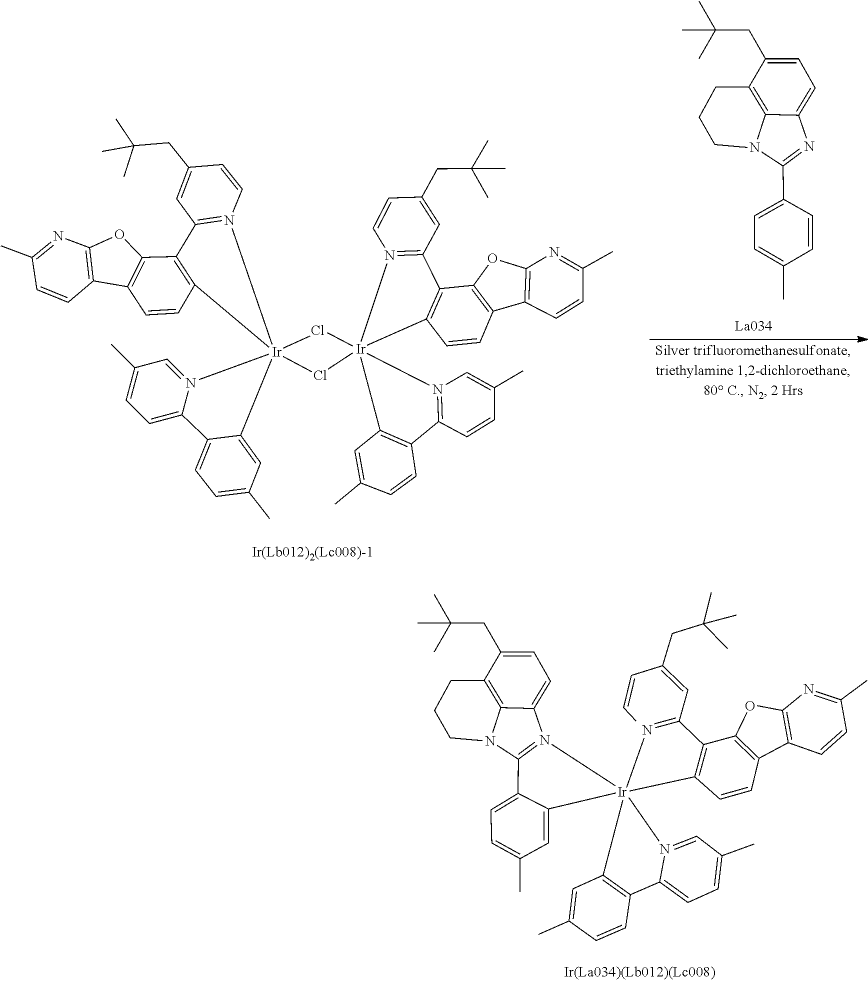

With reference to synthesis and purification methods of the compound Ir(La001)(Lb012)(Lc003), only the corresponding raw materials were required to be changed, and 1.12 g of a target compound Ir(La034)(Lb012)(Lc008) with a yield of 26.8% was obtained. 1.12 g of the crude product Ir(La034)(Lb012)(Lc008) was sublimated and purified to obtain 0.72 g of sublimated and purified Ir(La034)(Lb012)(Lc008) with a yield of 64.28%. The mass spectrum was: 1022.32 (M+H). ¹H NMR (400 MHZ, CDCl₃) δ 8.68 (d, J=38.5 Hz, 2H), 8.30 (m, 2H), 8.11 (m, 2H), 7.84 (m, 2H), 7.78-7.66 (m, 3H), 7.58 (d, 1H), 7.28 (d, J=15.0 Hz, 3H), 7.11-6.95 (m, 3H), 3.97 (t, 2H), 3.21 (s, 2H), 2.97 (t, 2H), 2.67 (d, J=15.0 Hz, 5H), 2.40-2.14 (m, 11H), 0.98 (s, 18H).

### Synthesis of a Ligand La035

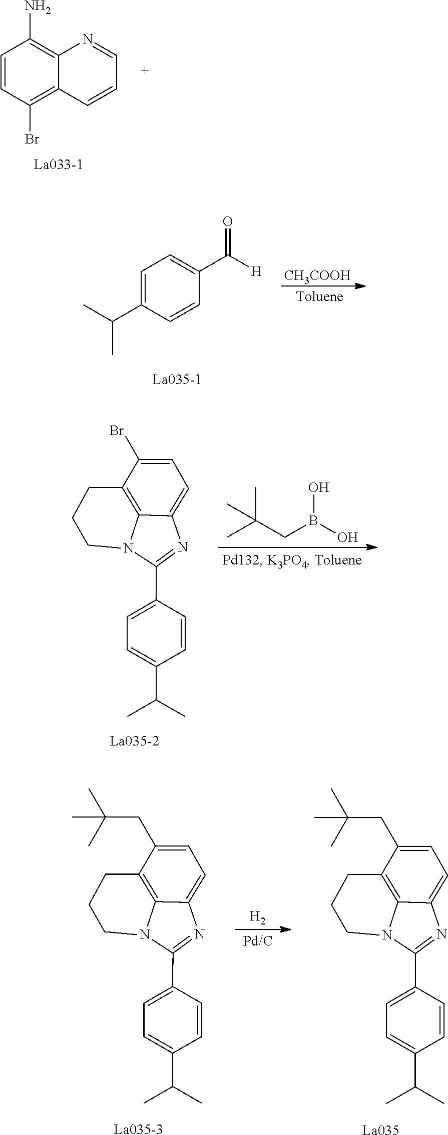

### Synthesis of a Compound La035-2

With reference to synthesis and purification methods of the compound La001-3, only the corresponding raw materials were required to be changed. The mass spectrum was: 354.2 (M+H).

### Synthesis of a Compound La035-3

With reference to synthesis and purification methods of the compound La033-4, only the corresponding raw materials were required to be changed. The mass spectrum was: 345.4 (M+H).

### Synthesis of a Compound La035

With reference to synthesis and purification methods of the compound La001, only the corresponding raw materials were required to be changed. The mass spectrum was: 347.5 (M+H).

### Synthesis of a Compound Ir(La035)(Lb012)(Lc008)

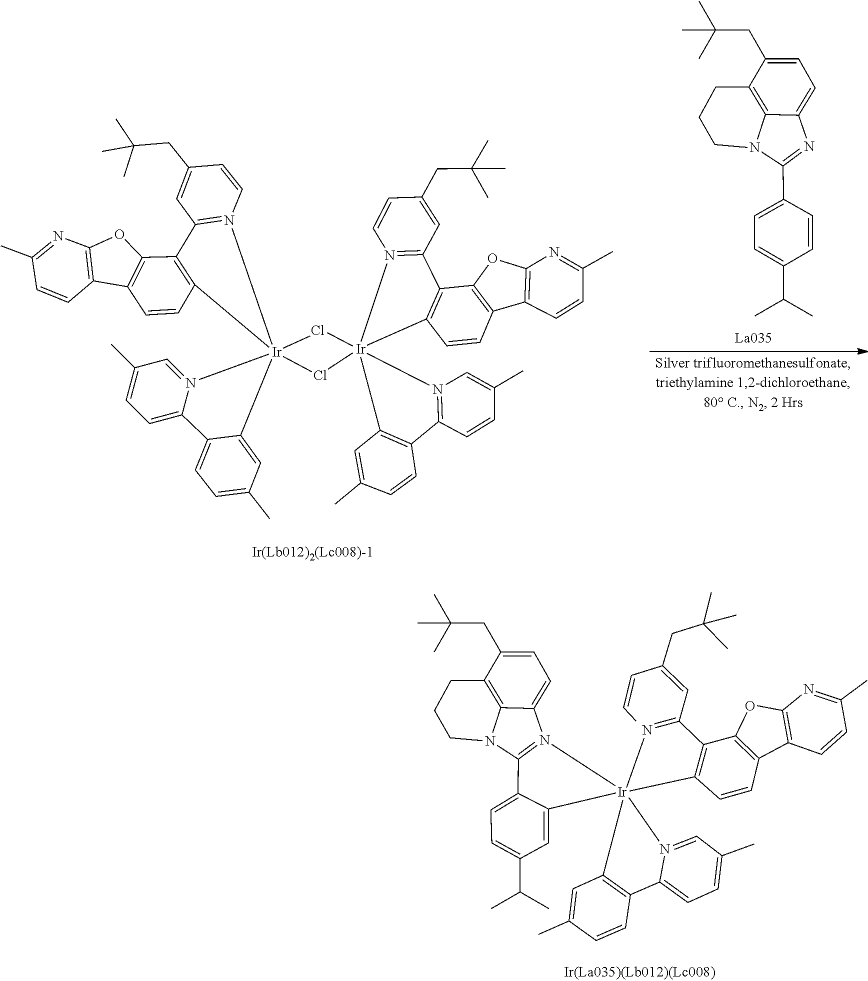

With reference to synthesis and purification methods of the compound Ir(La001)(Lb012)(Lc003), only the corresponding raw materials were required to be changed, and 1.24 g of a target compound Ir(La035)(Lb012)(Lc008) with a yield of 26.8% was obtained. 1.24 g of the crude product Ir(La035)(Lb012)(Lc008) was sublimated and purified to obtain 0.76 g of sublimated and purified Ir(La035)(Lb012)(Lc008) with a yield of 61.29%. The mass spectrum was: 1050.37 (M+H). ¹H NMR (400 MHZ, CDCl₃) δ 8.67 (s, 1H), 8.32 (d, J=22.1 Hz, 2H), 8.11 (m, 3H), 7.87-7.65 (m, 4H), 7.58 (d, J=5.0 Hz, 2H), 7.28 (d, J=15.0 Hz, 2H), 7.12-6.95 (m, 4H), 3.97 (t, 2H), 3.21 (s, 2H), 2.92 (d, J=50.0 Hz, 3H), 2.67 (d, J=15.0 Hz, 5H), 2.42-2.19 (m, 8H), 1.20 (s, 6H), 0.88 (s, 18H).

### Synthesis of a Ligand La036

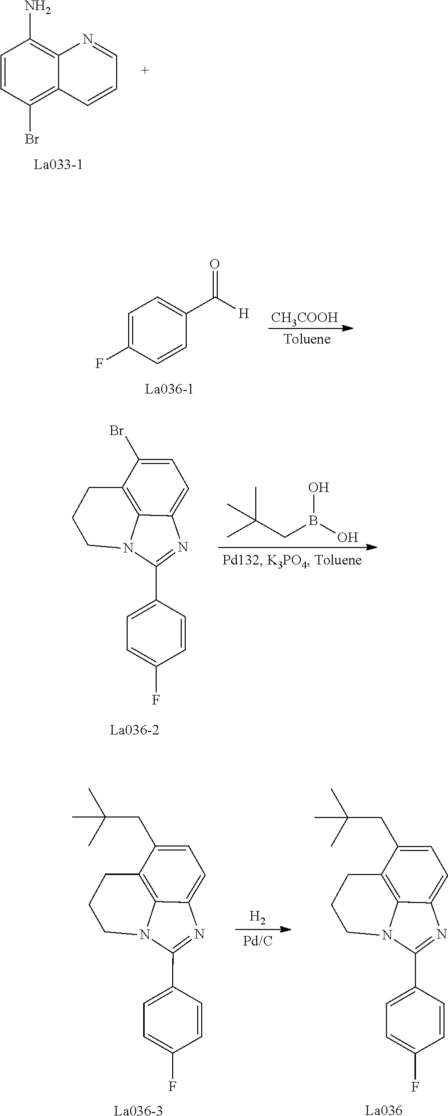

### Synthesis of a Compound La036-2

With reference to synthesis and purification methods of the compound La001-3, only the corresponding raw materials were required to be changed. The mass spectrum was: 330.1 (M+H).

### Synthesis of a Compound La036-3

With reference to synthesis and purification methods of the compound La033-4, only the corresponding raw materials were required to be changed. The mass spectrum was: 321.4 (M+H).

### Synthesis of a Compound La036

With reference to synthesis and purification methods of the compound La001, only the corresponding raw materials were required to be changed. The mass spectrum was: 323.4 (M+H).

### Synthesis of a Compound Ir(La036)(Lb012)(Lc008)

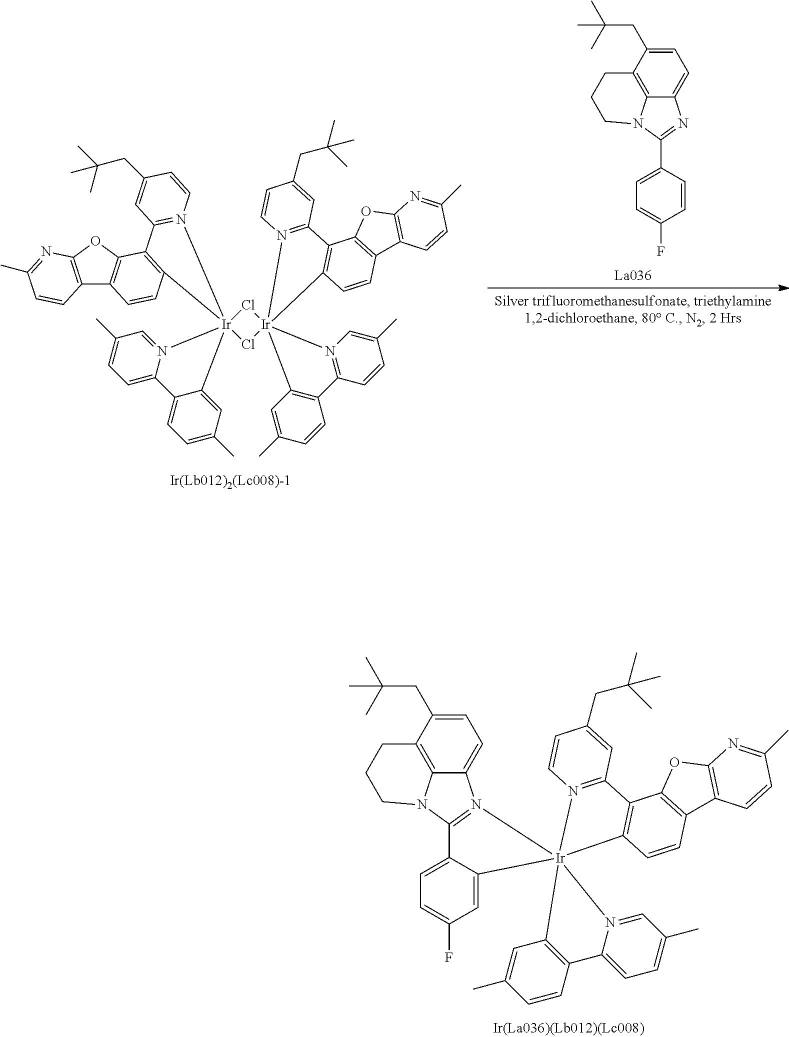

With reference to synthesis and purification methods of the compound Ir(La001)(Lb012)(Lc003), only the corresponding raw materials were required to be changed, and 1.22 g of a target compound Ir(La036)(Lb012)(Lc008) with a yield of 28.8% was obtained. 1.22 g of the crude product Ir(La036)(Lb012)(Lc008) was sublimated and purified to obtain 0.82 g of sublimated and purified Ir(La036)(Lb012)(Lc008) with a yield of 67.21%. The mass spectrum was: 1026.28 (M+H). ¹H NMR (400 MHZ, CDCl₃) δ 8.65 (d, J=40.5 Hz, 2H), 8.30 (m, 2H), 8.11 (m, 2H), 7.84 (s, 1H), 7.78-7.66 (m, 3H), 7.58 (m, 2H), 7.36-7.22 (m, 3H), 7.11-6.97 (m, 3H), 3.98 (t, 2H), 3.21 (s, 2H), 2.97 (t, 2H), 2.67 (d, J=15.0 Hz, 5H), 2.40-2.19 (m, 8H), 0.89 (s, 18H).

### Synthesis of a Ligand La037

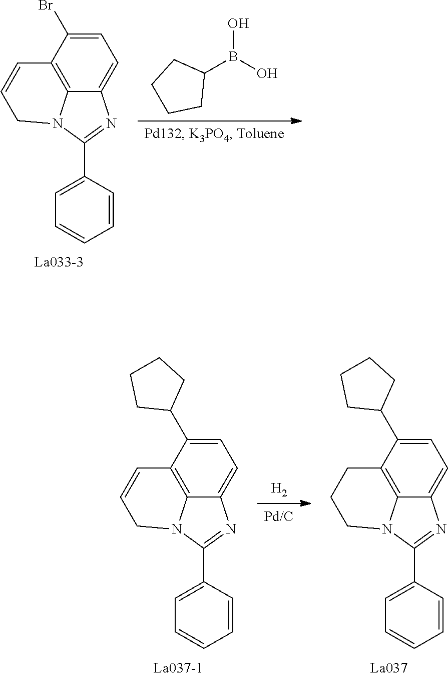

### Synthesis of a Compound La037-1

With reference to synthesis and purification methods of the compound La033-4, only the corresponding raw materials were required to be changed. The mass spectrum was: 301.4 (M+H).

### Synthesis of a Compound La037

With reference to synthesis and purification methods of the compound La001, only the corresponding raw materials were required to be changed. The mass spectrum was: 303.4 (M+H).

### Synthesis of a Compound Ir(La037)(Lb012)(Lc008)

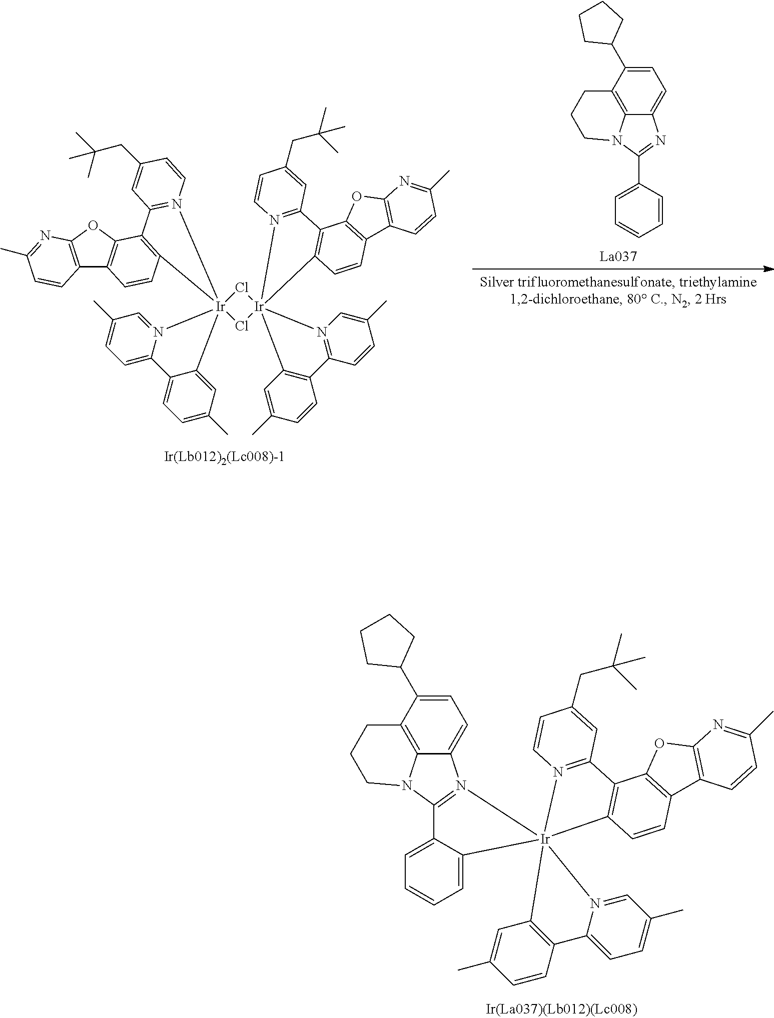

With reference to synthesis and purification methods of the compound Ir(La001)(Lb012)(Lc003), only the corresponding raw materials were required to be changed, and 1.38 g of a target compound Ir(La037)(Lb012)(Lc008) with a yield of 32.11% was obtained. 1.38 g of the crude product Ir(La037)(Lb012)(Lc008) was sublimated and purified to obtain 1.02 g of sublimated and purified Ir(La037)(Lb012)(Lc008) with a yield of 73.91%. The mass spectrum was: 1006.28 (M+H). ¹H NMR (400 MHZ, CDCl₃) δ 8.66(s, 1H), 8.32 (d, J=17.9 Hz, 2H), 8.11 (m, 4H), 7.88-7.65 (m, 5H), 7.46 (d, J=40.0 Hz, 2H), 7.28 (d, J=15.0 Hz, 2H), 7.11-6.97 (m, 4H), 3.99 (t, 2H), 3.21 (s, 2H), 2.97 (t, 2H), 2.64 (d, J=42.9 Hz, 4H), 2.41-2.19 (m, 8H), 2.00 (s, 2H), 1.71 (t, J=25.0 Hz, 6H), 0.85 (s, 9H).

### Synthesis of a Ligand La057

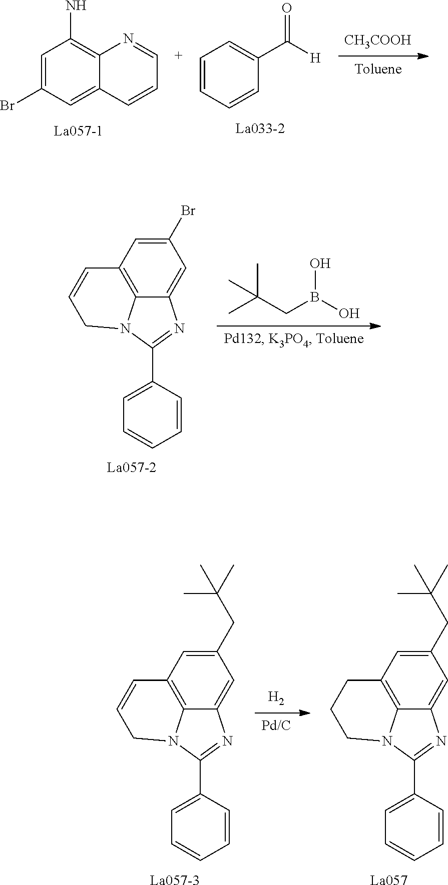

### Synthesis of a Compound La057-2

With reference to synthesis and purification methods of the compound La001-3, only the corresponding raw materials were required to be changed. The mass spectrum was: 312.8 (M+H).

### Synthesis of a Compound La057-3

With reference to synthesis and purification methods of the compound La033-4, only the corresponding raw materials were required to be changed. The mass spectrum was: 303.4 (M+H).

### Synthesis of a Compound La057

With reference to synthesis and purification methods of the compound La001, only the corresponding raw materials were required to be changed. The mass spectrum was: 305.4 (M+H).

### Synthesis of a Compound Ir(La057)(Lb012)(Lc008)

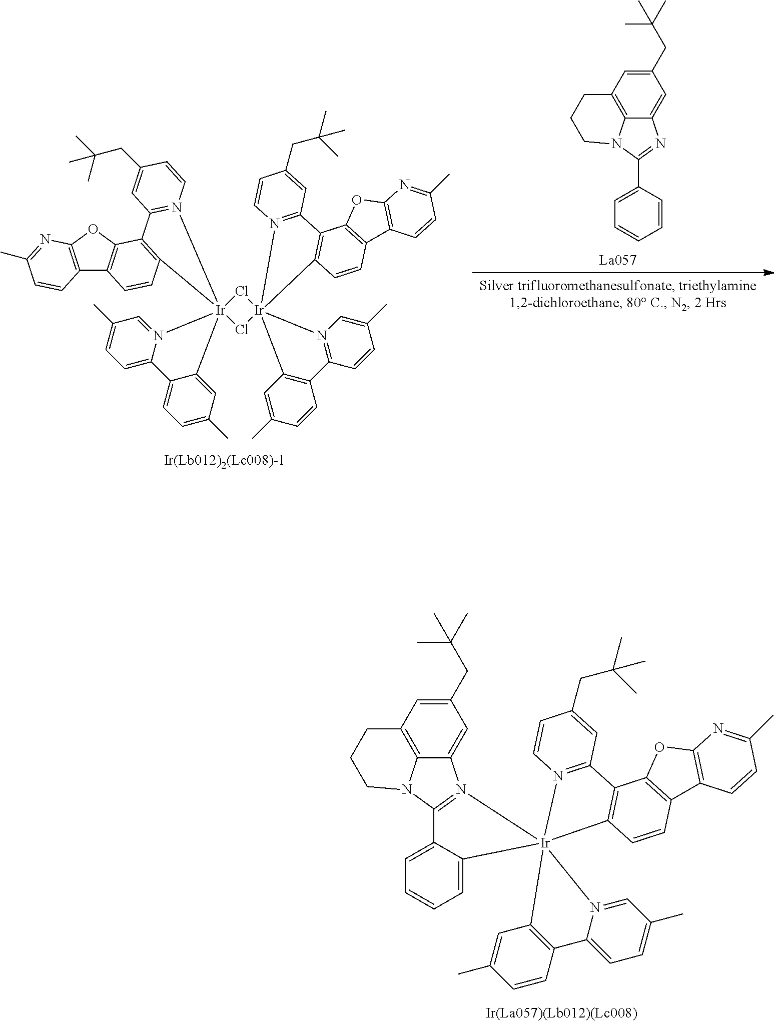

With reference to synthesis and purification methods of the compound Ir(La001)(Lb012)(Lc003), only the corresponding raw materials were required to be changed, and 1.2 g of a target compound Ir(La057)(Lb012)(Lc008) with a yield of 26.7% was obtained. 1.2 g of the crude product Ir(La057)(Lb012)(Lc008) was sublimated and purified to obtain 0.83 g of sublimated and purified Ir(La057)(Lb012)(Lc008) with a yield of 69.16%. The mass spectrum was: 1008.29 (M+H). ¹H NMR (400 MHZ, CDCl₃) 8 8.65 (s, 1H), 8.31 (d, J=15.0 Hz, 2H), 8.11 (m, 4H), 7.88-7.65 (m, 4H), 7.46 (d, J=40.0 Hz, 2H), 7.37-7.21 (m, 4H), 7.11-6.89 (m, 3H), 3.98(t, 2H), 3.21 (s, 2H), 2.97 (t, 2H), 2.68 (s, 3H), 2.43 (s, 2H), 2.37-2.21 (m, 8H), 0.88 (s, 18H).

### Synthesis of a Ligand La085

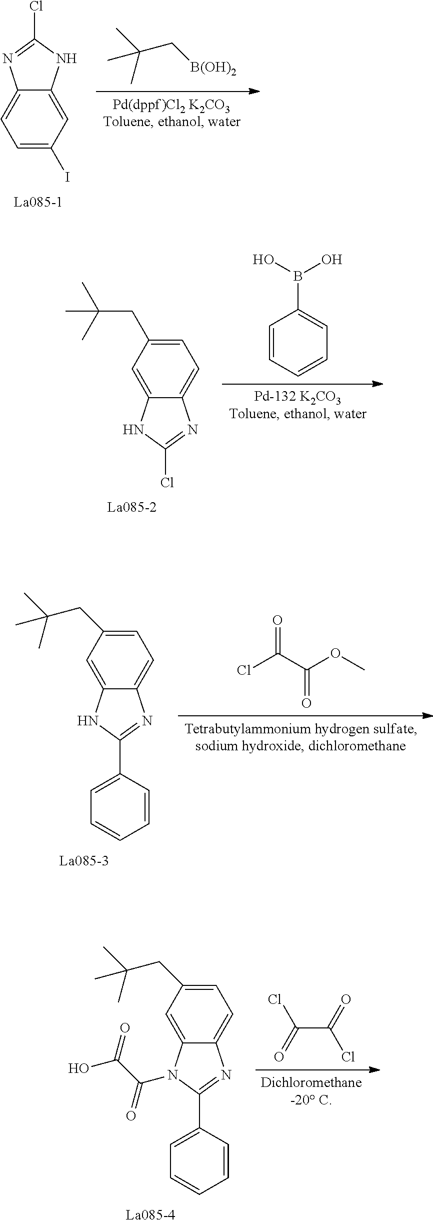

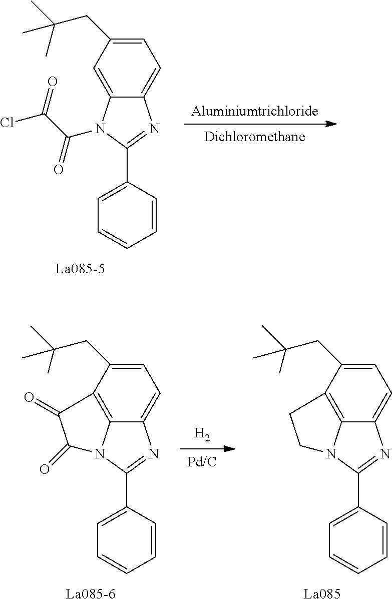

### Synthesis of a Compound La085-2

A compound La085-1 (25 g, 89.77 mmol, 1.0 eq), isobutaneboronic acid (10.93 g, 94.26 mmol, 1.05 eq), [1,1′-bis(diphenylphosphino)ferrocene]dichloropalladium (1.31 g, 1.8 mmol, 0.02 eq), potassium carbonate (24.81 g, 179.55 mmol, 2.0 eq), toluene (200 ml), ethanol (40 ml) and deionized water (40 ml) were sequentially added into a 500 ml three-necked flask, vacuumization was performed for nitrogen replacement for 3 times, and the above compounds were heated to about 80° C. in an oil bath and stirred for 16 hours. According to monitoring of a sample by TLC, the raw material La085-1 was basically completely reacted. Cooling was performed to room temperature, and deionized water was added for water washing for 3 times (100 ml/time). Then, liquid separation was performed, and an organic phase was concentrated under reduced pressure to obtain a solid. The crude product was separated by column chromatography (with a mixture of EA and Hex at a ratio of 1:30), and a resulting product was dried to obtain 15.1 g of a white-like solid compound La085-2 with a yield of 75.8%. The mass spectrum was: 223.7 (M+H).

### Synthesis of a Compound La085-3

The compound La085-2 (15 g, 67.35 mmol, 1.0 eq), isobutaneboronic acid (8.21 g, 67.35 mmol, 1.0 eq), bis(di-tert-butyl(4-dimethylaminophenyl)phosphine)dichloropalladium (II) (0.95 g, 1.35 mmol, 0.02 eq), potassium carbonate (18.62 g, 134.7 mmol, 2.0 eq), toluene (150 ml), ethanol (30 ml) and deionized water (30 ml) were sequentially added into a 500 ml three-necked flask, vacuumization was performed for nitrogen replacement for 3 times, and the above compounds were heated to about 80° C. in an oil bath and stirred for 8 hours. According to monitoring of a sample by TLC, the raw material La085-2 was basically completely reacted. Cooling was performed to room temperature, and deionized water was added for water washing for 3 times (100 ml/time). Then, liquid separation was performed, and an organic phase was concentrated under reduced pressure to obtain a solid. The crude product was separated by column chromatography (with a mixture of EA and Hex at a ratio of 1:20), and a resulting product was dried to obtain 15.44 g of a white-like solid compound La085-3 with a yield of 86.7%. The mass spectrum was: 265.3 (M+H).

### Synthesis of a Compound La085-4

The compound La085-3 (15 g, 56.74 mmol, 1.0 eq), tetrabutylammonium hydrogen sulfate (3.85 g, 11.35 mmol, 0.2 eq), sodium hydroxide (4.54 g, 113.48 mmol, 2.0 eq) and dichloromethane (150 ml) were sequentially added into a 500 ml three-necked flask, vacuumization was performed for nitrogen replacement for 3 times, and the system was cooled to 0° C. and stirred for 0.5 hour. Methyl chloroformylformate (13.9 g, 113.48 mmol, 2.0 eq) was slowly added dropwise into a reaction solution, and after the dropping was completed, the above compounds were stirred at room temperature for 2 hours. According to monitoring of a sample by TLC, the raw material La085-3 was basically completely reacted. Cooling was performed to room temperature, the reaction solution was concentrated and dried, dichloromethane (200 ml) was added and stirred for dissolution, and deionized water was added for water washing for 3 times (100 ml/time). Then, liquid separation was performed, and an organic phase was concentrated and dried. A crude product was separated by column chromatography (with a mixture of EA and Hex at a ratio of 1:15), and a resulting product was dried to obtain 13.61 g of a white-like solid compound La085-4 with a yield of 71.3%. The mass spectrum was: 337.3 (M+H).

### Synthesis of a Compound La085-5

The compound La085-4 (12 g, 37.45 mmol, 1.0 eq) and dichloromethane (120 ml) were sequentially added into a 500 ml three-necked flask and stirred for dissolved clarification, and a reaction solution was cooled to 0° C. Oxalyl chloride (7.13 g, 56.18 mmol, 1.5 eq) was slowly added dropwise into the reaction solution, and after the dropping was completed, the above compounds were stirred at room temperature for 2 hours. According to monitoring of a sample by TLC, the raw material La085-4 was basically completely reacted. Cooling was performed to room temperature, the reaction solution was concentrated and dried, and a resulting crude product was directly used in a reaction in the next step. 12.06 g of a white-like solid compound La085-5 with a yield of 95.3% was obtained. The mass spectrum was: 355.8 (M+H).

### Synthesis of a Compound La085-6

The compound La085-5 (14 g, 39.46 mmol, 1.0 eq), aluminiumtrichloride (13.15 g, 98.64 mmol, 2.5 eq) and dichloromethane (150 ml) were sequentially added into a 500 ml three-necked flask, vacuumization was performed for nitrogen replacement for 3 times, and the above compounds were stirred at room temperature for 2 hours. According to monitoring of a sample by TLC, the raw material La085-5 was basically completely reacted. Cooling was performed to room temperature, and deionized water (300 ml) was slowly added for quenching in an ice bath. Then, water washing and liquid separation were performed, and an organic phase was concentrated under reduced pressure to obtain a solid. The crude product was separated by column chromatography (with a mixture of EA and Hex at a ratio of 1:10), and a resulting product was dried to obtain 9.95 g of a white-like solid compound La085-6 with a yield of 79.2%. The mass spectrum was: 319.3 (M+H).

### Synthesis of a Compound La085

With reference to synthesis and purification methods of the compound La001, only the corresponding raw materials were required to be changed. The mass spectrum was: 291.4 (M+H).

### Synthesis of a Compound Ir(La085)(Lb005)₂

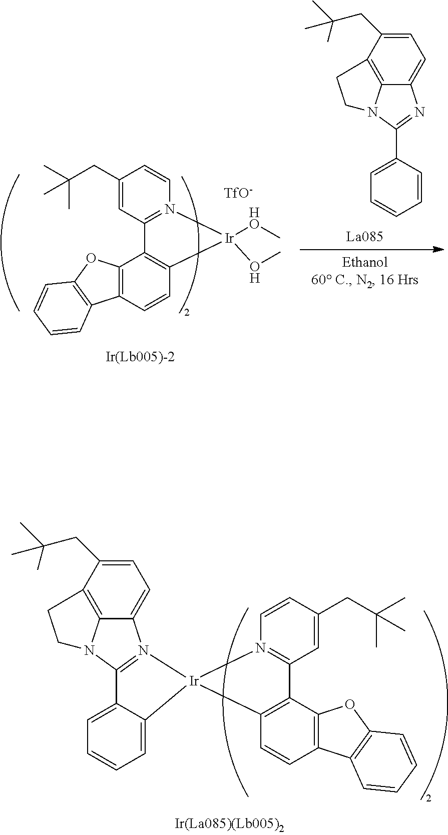

With reference to synthesis and purification methods of the compound Ir(La001)(Lb002)₂, only the corresponding raw materials were required to be changed, and 2.37 g of a target compound Ir(La085)(Lb005)₂ with a yield of 34.4% was obtained. 2.37 g of the crude product Ir(La085)(Lb005)₂ was sublimated and purified to obtain 1.42 g of sublimated and purified Ir(La085)(Lb005)₂ with a yield of 59.9%. The mass spectrum was: 1111.41 (M+H). ¹H NMR (400 MHZ, CDCl₃) δ 8.66 (s, 2H), 7.98 (m, 4H), 7.87-7.65 (m, 6H), 7.62-7.45 (m, 4H), 7.45-7.26 (m, 5H), 7.06 (d, J=10.0 Hz, 3H), 4.50 (d, J=20.6 Hz, 2H), 3.33 (t, 2H), 3.21 (s, 4H), 2.65 (s, 2H), 0.87 (s, 27H).

### Synthesis of a Ligand La093

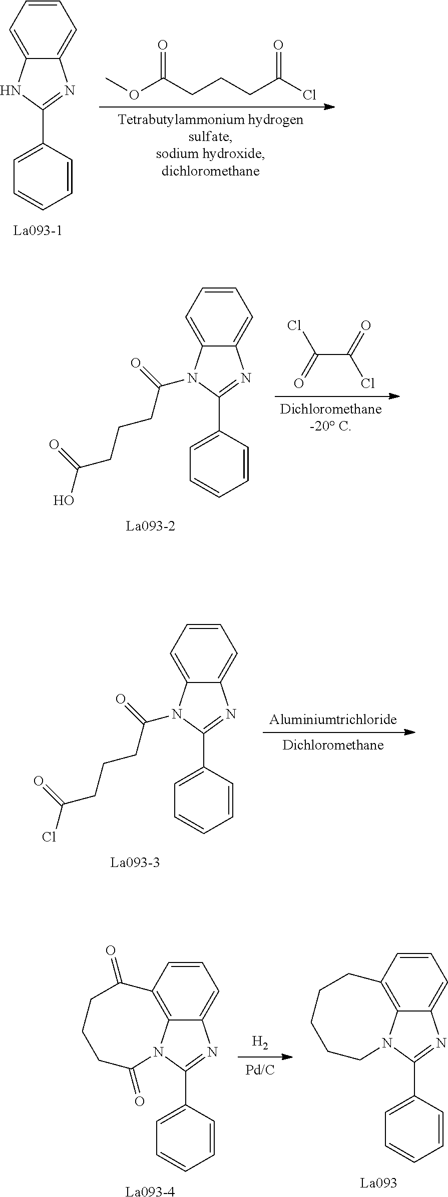

### Synthesis of a Compound La093-2

With reference to synthesis and purification methods of the compound La085-4, only the corresponding raw materials were required to be changed. The mass spectrum was: 309.3 (M+H).

### Synthesis of a Compound La093-3

With reference to synthesis and purification methods of the compound La085-5, only the corresponding raw materials were required to be changed. The mass spectrum was: 327.7 (M+H).

### Synthesis of a Compound La093-4

With reference to synthesis and purification methods of the compound La085-6, only the corresponding raw materials were required to be changed. The mass spectrum was: 291 (M+H).

### Synthesis of a Compound La093

With reference to synthesis and purification methods of the compound La085, only the corresponding raw materials were required to be changed. The mass spectrum was: 263.3 (M+H).

### Synthesis of a Compound Ir(La093)(Lb005)₂

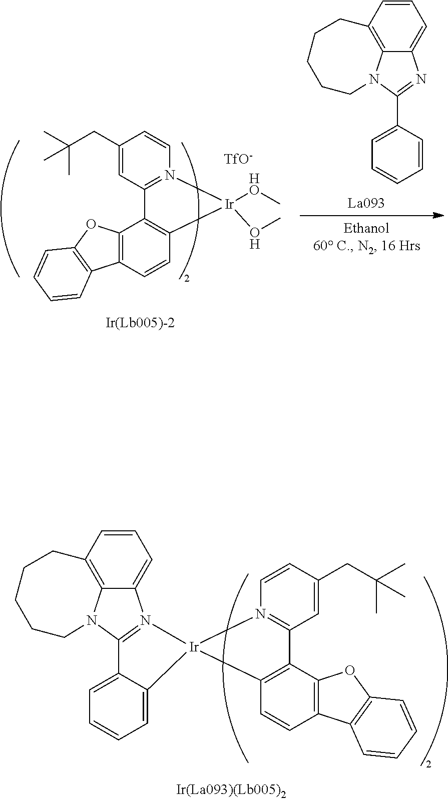

With reference to synthesis and purification methods of the compound Ir(La001)(Lb002)₂, only the corresponding raw materials were required to be changed, and 1.87 g of a target compound Ir(La093)(Lb005)₂ with a yield of 28.8% was obtained. 1.87 g of the crude product Ir(La093)(Lb005)₂ was sublimated and purified to obtain 1.05 g of sublimated and purified Ir(La093)(Lb005)₂ with a yield of 56.14%. The mass spectrum was: 1083.3 (M+H). ¹H NMR (400 MHZ, CDCl₃) δ 8.66(s, 2H), 7.98 (s, 2H), 7.84 (m, 3H), 7.77 (m, 2H), 7.69 (m, 3H), 7.61-7.47 (m, 4H), 7.46-7.35 (m, 4H), 7.31 (m, 2H), 7.22 (d, 1H), 7.05 (d, 2H), 5.66 (t, 1H), 5.16 (t, 1H), 3.21 (t, 4H), 2.74 (t, 2H), 1.84 (m, 2H), 1.62 (m, 2H), 1.32 (m, 2H), 0.85 (s, 18H).

### Synthesis of a Ligand La097

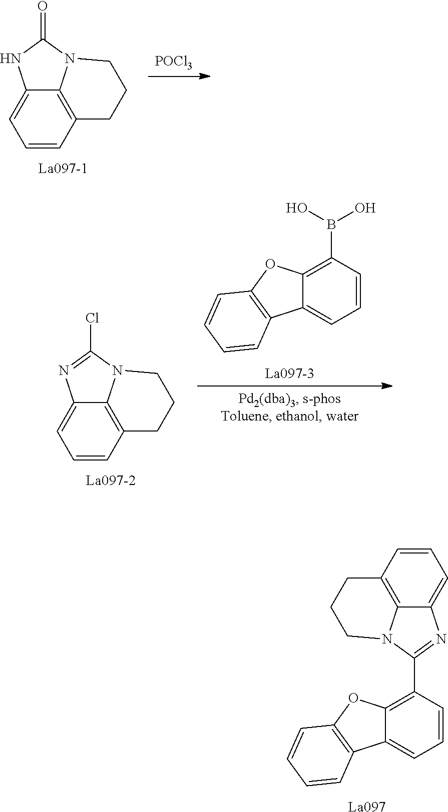

### Synthesis of a Compound La097-2

A compound La097-1 (8.0 g, 45.92 mmol, 1.0 eq) and phosphorus oxychloride (100 ml) were sequentially added into a 500 ml three-necked flask, vacuumization was performed for nitrogen replacement for 3 times, and the above compounds were stirred at room temperature for 2 hours. According to monitoring of a sample by TLC, the raw material La097-1 was basically completely reacted. Cooling was performed to room temperature, and deionized water (300 ml) was slowly added for quenching in an ice bath. Then, ethyl acetate (100 ml) was added for extraction and liquid separation, and an organic phase was washed with water to neutral, collected and concentrated under reduced pressure to obtain a solid. The crude product was separated by column chromatography (with a mixture of dichloromethane (DCM) and Hex at a ratio of 1:10), and a resulting product was dried to obtain 7.38 g of a white-like solid compound La097-2 with a yield of 83.4%. The mass spectrum was: 193.6 (M+H).

### Synthesis of a Compound La097

With reference to synthesis and purification methods of the compound La085-3, only the corresponding raw materials were required to be changed. The mass spectrum was: 325.3 (M+H).

### Synthesis of a Compound Ir(La097)(Lb005)₂

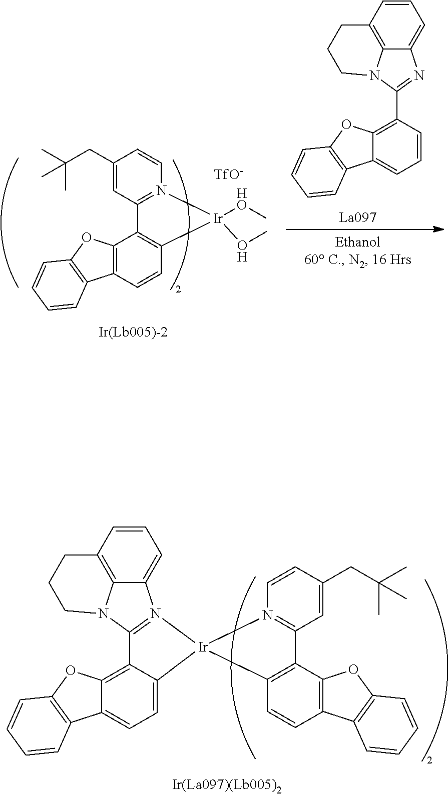

With reference to synthesis and purification methods of the compound Ir(La001)(Lb002)₂, only the corresponding raw materials were required to be changed, and 1.87 g of a target compound Ir(La097)(Lb005)₂ with a yield of 28.8% was obtained. 1.87 g of the crude product Ir(La097)(Lb005)₂ was sublimated and purified to obtain 1.05 g of sublimated and purified Ir(La097)(Lb005)₂ with a yield of 56.14%. The mass spectrum was: 1083.3 (M+H). ¹H NMR (400 MHZ, CDCl₃) δ 8.65 (s, 2H), 7.98 (m, 4H), 7.84 (m, 4H), 7.69 (m, 3H), 7.56 (d, J=20.0 Hz, 4H), 7.47-7.17 (m, 8H), 7.05 (m, 2H), 3.99 (t, 2H), 3.21 (s, 4H), 2.97 (t, 3H), 2.26 (m, 2H), 0.88 (s, 18H).

### Synthesis of a Ligand La098

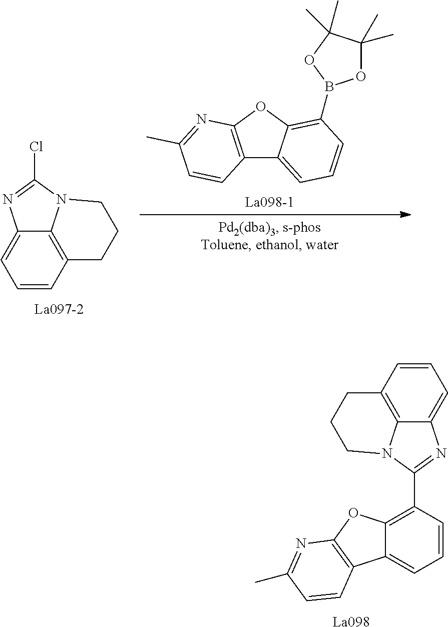

With reference to synthesis and purification methods of the compound La085-3, only the corresponding raw materials were required to be changed. The mass spectrum was: 340.3 (M+H).

### Synthesis of a Compound Ir(La098)(Lb005)₂

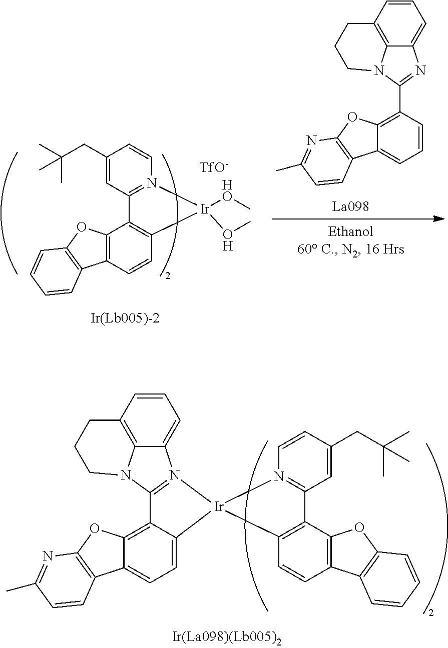

With reference to synthesis and purification methods of the compound Ir(La001)(Lb002)₂, only the corresponding raw materials were required to be changed, and 2.02 g of a target compound Ir(La098)(Lb005)₂ with a yield of 34.7% was obtained. 2.02 g of the crude product Ir(La098)(Lb005)₂ was sublimated and purified to obtain 1.34 g of sublimated and purified Ir(La098)(Lb005)₂ with a yield of 66.33%. The mass spectrum was: 1160.4 (M+H). ¹H NMR (400 MHZ, CDCl₃) δ 8.58 (d, J=24.2 Hz, 3H), 7.98 (m, 3H), 7.84 (m, 3H), 7.69 (m, 4H), 7.56 (d, J=20.0 Hz, 3H), 7.48-7.17 (m, 6H), 7.03 (d, J=20.0 Hz, 3H), 3.99 (t, 2H), 3.21 (s, 4H), 2.97 (t, 2H), 2.68 (s, 3H), 2.26 (m, 2H), 0.85 (s, 18H).

### Synthesis of a Ligand La099

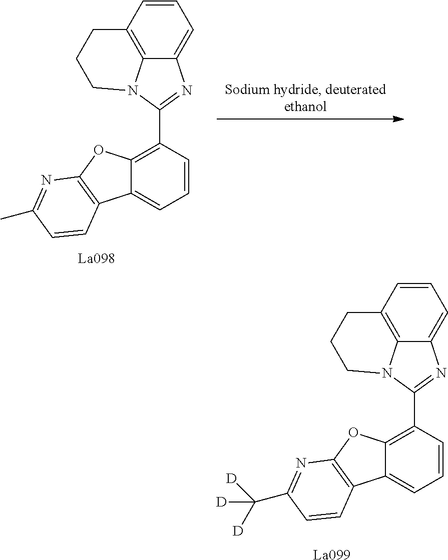 [SMILES: Cc1ccc2c(n1)oc1c(-c3nc4cccc5c4n3CCC5)cccc12 ; "Sodium hydride, deuteratedethanol" ; "La098" ; [2H]C([2H])([2H])c1ccc2c(n1)oc1c(-c3nc4cccc5c4n3CCC5)cccc12 ; "La099"]

The La098 (6.8 g, 20.04 mmol, 1.0 eq), sodium hydride (1.44 g, 60.11 mmol, 3.0 eq) and deuterated ethanol (102 ml) were put into a 1 L one-necked flask. Vacuumization was performed for nitrogen replacement for 3 times, and the above compounds were heated to 75° C. to carry out a reaction for 16 hours under the protection of nitrogen. A reaction solution was cooled to room temperature. Heavy water (50 ml) was added and stirred to precipitate a solid, and the solid was collected by filtration. The crude product was separated by column chromatography with silica gel (with an eluting agent including dichloromethane and n-hexane at a ratio of 1:15) to obtain a solid, and the solid was recrystallized with dichloromethane (35 ml)/methanol (42 ml) for 2 times to obtain 4.61 g of a compound La099 with a yield of 67.2%. The mass spectrum was: 343.4 (M+H).

### Synthesis of a Compound Ir(La099)(Lb005)₂

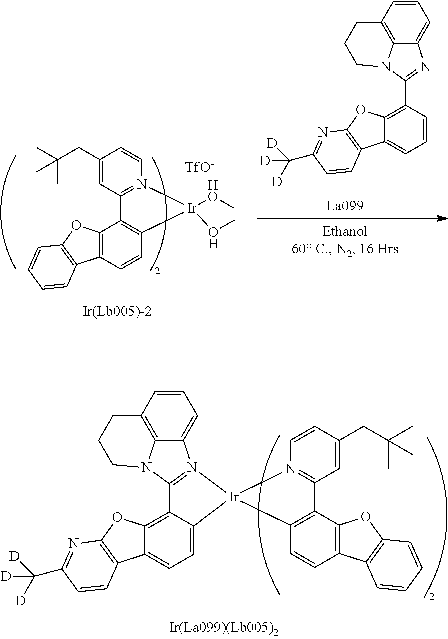

With reference to synthesis and purification methods of the compound Ir(La001)(Lb002)₂, only the corresponding raw materials were required to be changed, and 2.07 g of a target compound Ir(La099)(Lb005)₂ with a yield of 31.9% was obtained. 2.07 g of the crude product Ir(La099)(Lb005)₂ was sublimated and purified to obtain 1.52 g of sublimated and purified Ir(La099)(Lb005)₂ with a yield of 73.4%. The mass spectrum was: 1163.4 (M+H). ¹H NMR (400 MHZ, CDCl₃) δ 8.53 (d, J=29.9 Hz, 3H), 7.98 (m, 3H), 7.84 (m, 3H), 7.69 (m, 4H), 7.56 (d, J=20.0 Hz, 3H), 7.48-7.15 (m, 6H), 7.03 (d, J=20.0 Hz, 3H), 3.96 (t, 2H), 3.20 (s, 4H), 2.95 (s, 2H), 2.26 (m, 2H), 0.85 (s, 18H).

Other compounds can be synthesized and sublimated by selecting corresponding materials based on same or similar methods.

### Application Example: Manufacturing of an Organic Electroluminescent Device

A glass substrate with a size of 50 mm*50 mm*1.0 mm including an indium tin oxide (ITO, 100 nm) transparent electrode was ultrasonically cleaned in ethanol for 10 minutes, dried at 150° C., and then treated with N₂ plasma for 30 minutes. The washed glass substrate was installed on a substrate support of a vacuum evaporation device. At first, a compound HATCN for covering the transparent electrode was evaporated on the surface of the side having a transparent electrode line to form a thin film with a thickness of 5 nm. Then, a layer of HTM1 was evaporated to form a thin film with a thickness of 60 nm. Then, a layer of HTM2 was evaporated on the HTM1 thin film to form a thin film with a thickness of 10 nm. Then, a main material 1, a main material 2 and a doping compound (including a reference compound X and the compound of the present invention) were co-evaporated on the HTM2 film layer to obtain a film with a thickness of 30 nm, wherein the ratio of the main material 1 to the main material 2 to the doping material was 45%:45%:10%. Then, an electron transport layer (ETL) and an electron injection layer (EIL) were sequentially evaporated on a light-emitting layer to obtain a film with a thickness of 35 nm, wherein the ratio of the ETL to the EIL was 10 50%:50%. Finally, a metal Al layer (100 nm) was evaporated to serve as an electrode.

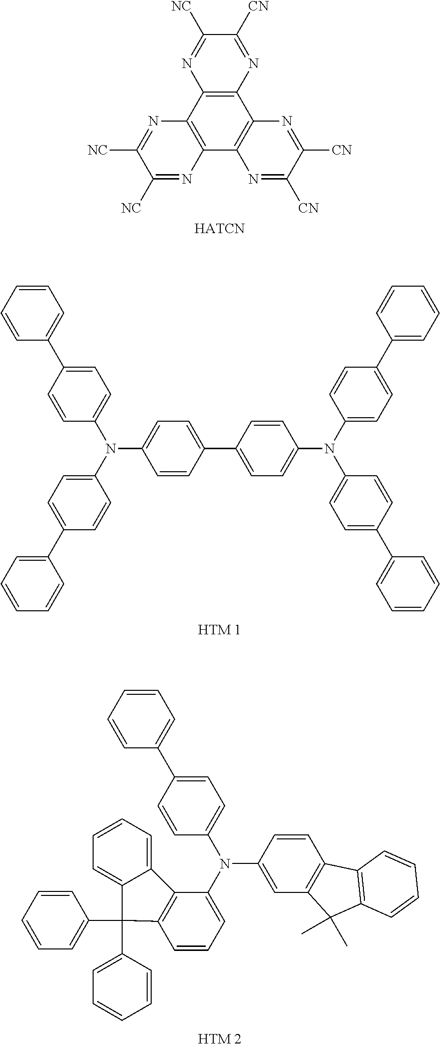

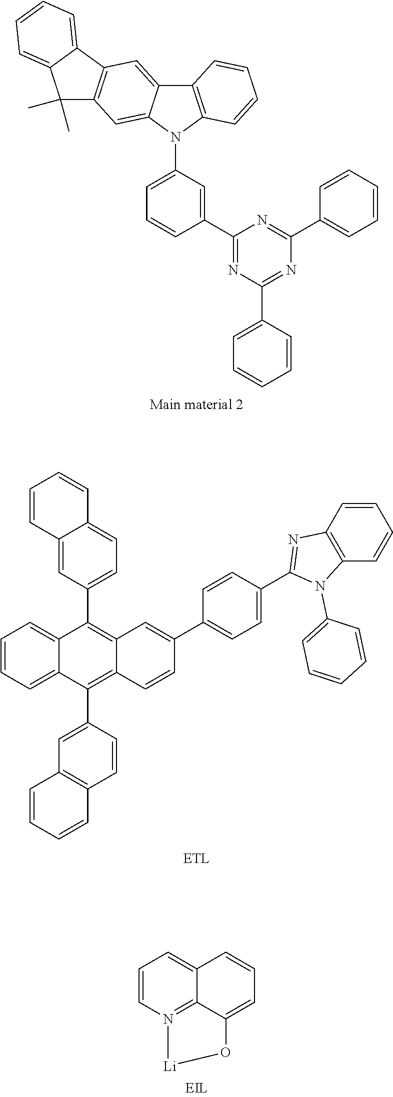

Evaluation: Properties of a device obtained above were tested. In various examples and comparative examples, a constant-current power supply (Keithley 2400) was used, a current at a fixed density was used for flowing through light-emitting elements, and a spectroradiometer (CS 2000) was used for testing the light-emitting spectrum. Meanwhile, the voltage value was measured, and the time (LT95) when the brightness was reduced to 95% of the initial brightness was tested. Results are shown as 10 follows.

| | | Peak | | Starting | Current | LT95@ |
|---|---|---|---|---|---|---|
| | | wavelength | FWHM | voltage | efficiency | 10000 |
| | Doping material | nm | nm | V | Cd/A | nits |
| Example 1 | Ir(La001)(Lb002)₂ | 521 | 41 | 4.40 | 80 | 330 |
| Example 2 | Ir(La001)(Lb005)₂ | 525 | 38 | 4.41 | 82 | 360 |
| Example 3 | Ir(La001)(Lb012)₂ | 520 | 35 | 4.37 | 84 | 332 |
| Example 4 | Ir(La001)₂(Lb012) | 529 | 48 | 4.42 | 79 | 316 |
| Example 5 | Ir(La001)(Lb012)(Lc003) | 525 | 46 | 4.39 | 79 | 295 |
| Example 6 | Ir(La001)(Lb012)(Lc008) | 526 | 47 | 4.40 | 80 | 297 |
| Example 7 | Ir(La001)(Lb012)(Lc026) | 528 | 46 | 4.41 | 81 | 300 |
| Example 8 | Ir(La001)(Lb012)(Lc062) | 523 | 42 | 4.38 | 84 | 378 |
| Example 9 | Ir(La001)(Lb001)(Lb012) | 525 | 43 | 4.42 | 82 | 326 |
| Example 10 | Ir(La001)(La033)(Lb012) | 528 | 40 | 4.44 | 82 | 366 |
| Example 11 | Ir(La005)₂(Lb012) | 521 | 37 | 4.36 | 85 | 389 |
| Example 12 | Ir(La033)(Lb012)(Lc008) | 520 | 44 | 4.32 | 79 | 292 |
| Example 13 | Ir(La034)(Lb012)(Lc008) | 521 | 45 | 4.33 | 81 | 296 |
| Example 14 | Ir(La035)(Lb012)(Lc008) | 523 | 47 | 4.36 | 82 | 309 |
| Example 15 | Ir(La036)(Lb012)(Lc008) | 519 | 47 | 4.36 | 80 | 299 |
| Example 16 | Ir(La037)(Lb012)(Lc008) | 526 | 43 | 4.33 | 83 | 318 |
| Example 17 | Ir(La057)(Lb012)(Lc008) | 527 | 42 | 4.32 | 84 | 329 |
| Example 18 | Ir(La085)(Lb005)₂ | 524 | 41 | 4.41 | 83 | 332 |
| Example 19 | Ir(La093)(Lb005)₂ | 526 | 45 | 4.43 | 80 | 312 |
| Example 20 | Ir(La097)(Lb005)₂ | 521 | 45 | 4.38 | 81 | 356 |
| Example 21 | Ir(La098)(Lb005)₂ | 519 | 46 | 4.42 | 79 | 329 |
| Example 22 | Ir(La099)(Lb005)₂ | 520 | 47 | 4.39 | 80 | 412 |
| Comparative | Reference compound 1 | 509 | 73 | 5.01 | 53 | 60 |
| Example 1 | | | | | | |
| Comparative | Reference compound 2 | 530 | 76 | 5.11 | 77 | 152 |
| Example 2 | | | | | | |
| Comparative | Reference compound 3 | 549 | 69 | 4.86 | 76 | 183 |
| Example 3 | | | | | | |
| Comparative | Reference compound 4 | 523 | 75 | 5.06 | 52 | 98 |
| Example 4 | | | | | | |
| Comparative | Reference compound 5 | 519 | 72 | 4.82 | 54 | 121 |
| Example 5 | | | | | | |
| Comparative | Reference compound 6 | 528 | 66 | 4.76 | 72 | 130 |
| Example 6 | | | | | | |
| Comparative | Reference compound 7 | 524 | 68 | 4.92 | 71 | 200 |
| Example 7 | | | | | | |

Through comparison of the data in the above table, it can be seen that compared with reference compounds, the compound of the present invention used as a dopant in an organic electroluminescent device has more excellent properties, such as driving voltage, luminous efficiency and device service life.

The above results show that the compound of the present invention has the advantages of high optical and electrical stability, narrow emission half-peak width, high color saturation, high luminous efficiency, long device service life and the like, and can be used in organic electroluminescent devices. In particular, the compound has the potential for application in the OLED industry as a green light-emitting dopant.

1. An organometallic compound, having a general formula of Ir(La)(Lb)(Lc), wherein La is a structure represented by Formula (1): 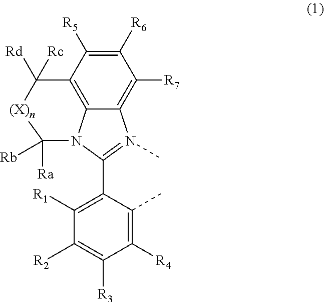
wherein dotted lines refer to positions connected to the metal Ir;
X is O, S, Se, CRpRq, SiRrRs or NRt;
n is an integer from 0 to 3, and when the n is equal to or greater than 2, multiple X groups are present at the same time and are the same or different;
Ra, Rb, Rc, Rd, Rp, Rq, Rr, Rs and Rt are independently selected from hydrogen, deuterium, halogen, substituted or unsubstituted C₁-C₁₀ alkyl, substituted or unsubstituted C₃-C₂₀ cycloalkyl, substituted or unsubstituted C₆-C₁₈ aryl, and substituted or unsubstituted C₂-C₁₇ heteroaryl;
R₁-R₇ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₇ are connected to each other to form an aliphatic ring structure or an aromatic ring structure;
the heteroalkyl and the heteroaryl at least contain one O, N or S heteroatom;
both Lb and Lc are a monoanionic bidentate ligand, the La, the Lb and the Lc are the same or at least one is different, and the different indicates different parent nuclear structures, a same parent nuclear structure with different substituents, or a same parent nuclear structure with different substituent positions;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

2. The organometallic compound according to claim 1, wherein the X is CRpRq; the Ra, the Rb, the Rc, the Rd, the Rp and the Rq are independently selected from hydrogen, deuterium, halogen, substituted or unsubstituted C₁-C₁₀ alkyl, and substituted or unsubstituted C₃-C₂₀ cycloalkyl;
and the “substituted” refers to substitution with deuterium, F, Cl, Br, C₁-C₆ alkyl, and C₃-C₆ cycloalkyl, and the substitution ranges from a single substitution number to a maximum substitution number.

3. The organometallic compound according to claim 2, wherein the R₄ and the R₇ are independently selected from hydrogen, the R₁-R₃ and the R₅-R₆ are independently selected from hydrogen, deuterium, halogen, hydroxyl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₆-C₁₈ aryl, and substituted or unsubstituted C₂-C₁₇ heteroaryl, or any two adjacent groups of the R₁-R₂ are connected to each other to form an aliphatic ring.

4. The organometallic compound according to claim 3, wherein the Ra, the Rb, the Rc, the Rd, the Rp and the Rq are independently selected from hydrogen, deuterium, and substituted or unsubstituted C₁-C₁₀ alkyl;
the R₄ and the R₇ are independently selected from hydrogen; the R₃, the R₅ and the R₆ are independently selected from hydrogen, deuterium, halogen, substituted or unsubstituted C₁-C₁₀ alkyl, substituted or unsubstituted C₃-C₂₀ cycloalkyl, and substituted or unsubstituted C₆-C₁₈ aryl; and the R₁ and the R₂ are selected from hydrogen, deuterium, halogen, hydroxyl, substituted or unsubstituted C₁-C₁₀ alkyl, substituted or unsubstituted C₁-C₁₀ heteroalkyl, substituted or unsubstituted C₆-C₁₈ aryl, and substituted or unsubstituted C₂-C₁₇ heteroaryl, or any two adjacent groups are connected to each other to form an aliphatic ring.

5. The organometallic compound according to claim 1, wherein the Lb is a structure represented by Formula (2): 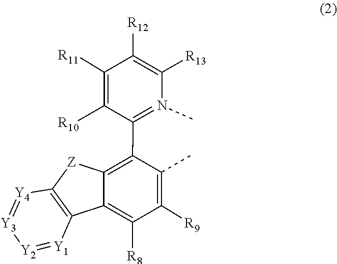
wherein dotted lines refer to positions connected to the metal Ir;
Y₁-Y₄ are independently selected from CR₀ or N;
Z is O, S, Se, CRpRq, SiRrRs or NRt;
R₀ and R₈-R₁₃ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₈-R₁₃ are connected to each other to form an aliphatic ring structure or an aromatic ring structure;
the heteroalkyl and the heteroaryl at least contain one O, N or S heteroatom;
Rp, Rq, Rr, Rs and Rt are defined the same as claim 1;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

6. The organometallic compound according to claim 5, wherein the Y₁-Y₃ are independently selected from CR₀; the Y₄ is independently selected from CR₀ or N; the Z is O;
the R₀ and the R₈-R₁₃ are independently selected from hydrogen, deuterium, halogen, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₆-C₁₈ aryl, and substituted or unsubstituted C₂-C₁₇ heteroaryl, or any two adjacent groups of the R₈-R₁₃ are connected to each other to form an aliphatic ring structure or an aromatic ring structure;
and the “substituted” refers to substitution with deuterium, F, Cl, Br, C₁-C₆ alkyl, and C₃-C₆ cycloalkyl, and the substitution ranges from a single substitution number to a maximum substitution number.

7. The organometallic compound according to claim 6, wherein the R₀, the R₉ and the R₁₀ are independently selected from hydrogen, the R₁-R₁₃ are independently selected from hydrogen, deuterium, halogen, substituted or unsubstituted C₁-C₁₀ alkyl, substituted or unsubstituted C₁-C₁₀ heteroalkyl, and substituted or unsubstituted C₃-C₂₀ cycloalkyl, or any two adjacent groups of the R₈-R₁₃ are connected to each other to form an aliphatic ring structure or an aromatic ring structure.

8. The organometallic compound according to claim 1, wherein the Lc is the same as the La or the Lb, and the La is different from the Lb.

9. The organometallic compound according to claim 1, wherein the Lc is a structure represented by Formula (3): 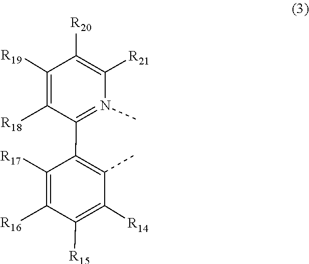
wherein dotted lines refer to positions connected to the metal Ir;
R₁₄-R₂₁ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁₄-R₂₁ are connected to each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

10. The organometallic compound according to claim 9, wherein the R₁₄-R₂₁ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₆-C₁₈ aryl, and substituted or unsubstituted C₂-C₁₇ heteroaryl, or any two adjacent groups of the R₁₄-R₂₁ are connected to each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, and C₃-C₆ cycloalkyl, and the substitution ranges from a single substitution number to a maximum substitution number.

11. The organometallic compound according to claim 10, wherein the R₁₇ and the R₁₈ are connected to each other to form a five-membered or six-membered aliphatic ring or aromatic ring structure.

12. The organometallic compound according to claim 1, wherein the La has one of the following structural formulas, or is partially or completely deuterated or fluorinated correspondingly,

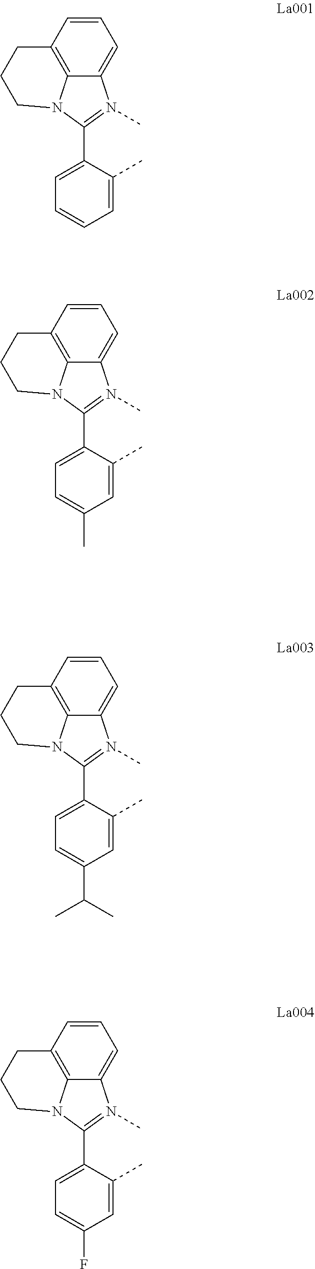

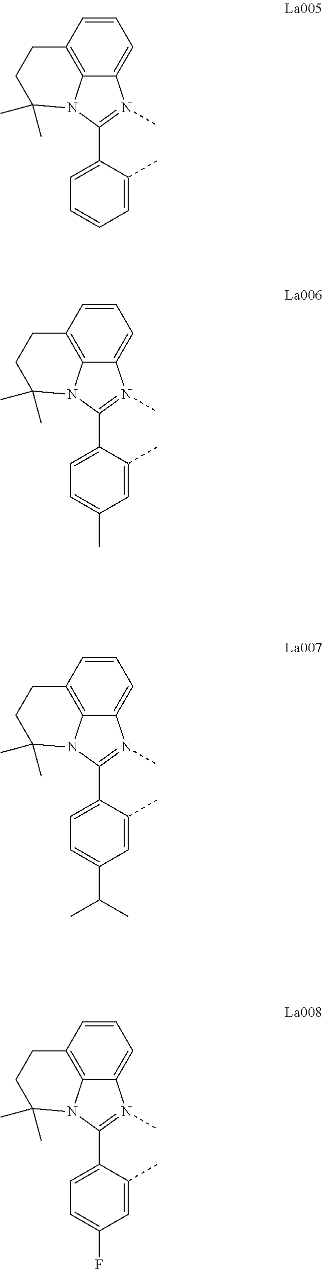

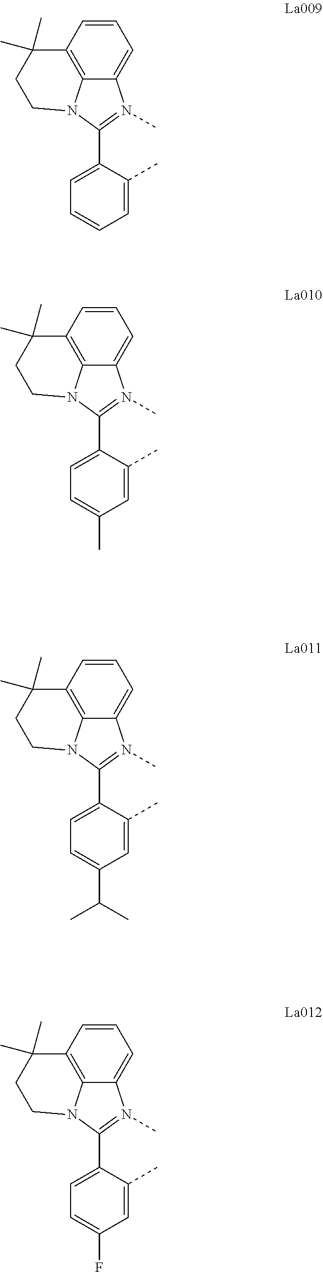

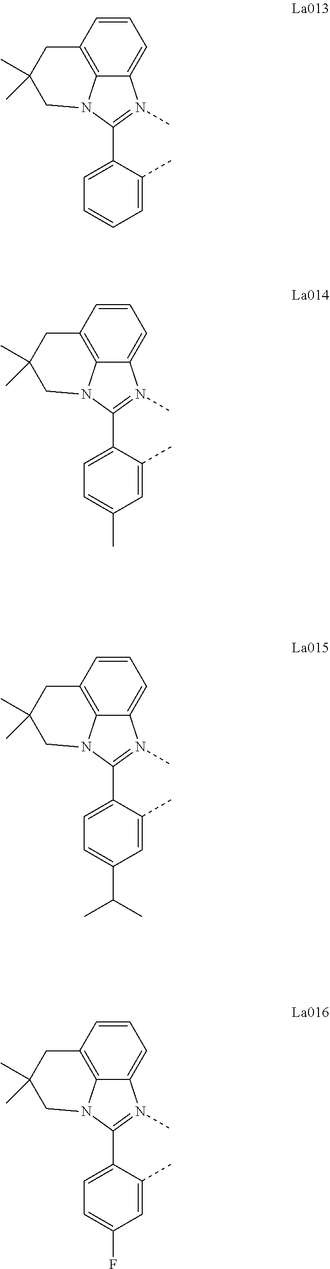

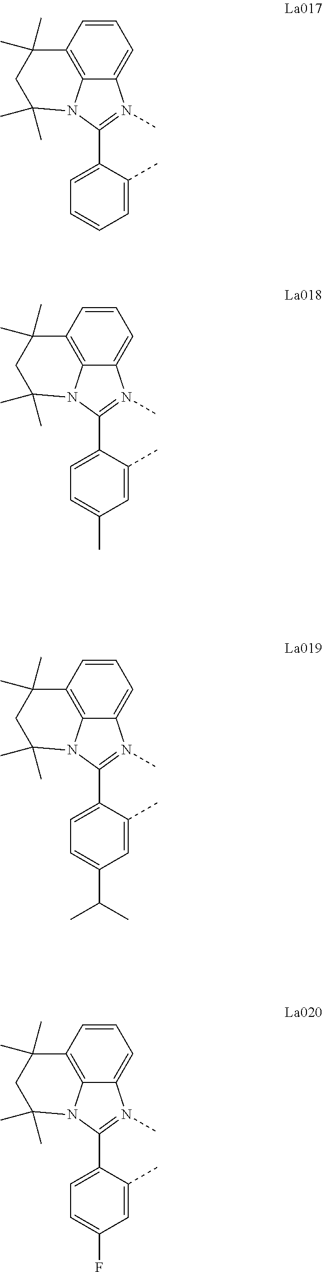

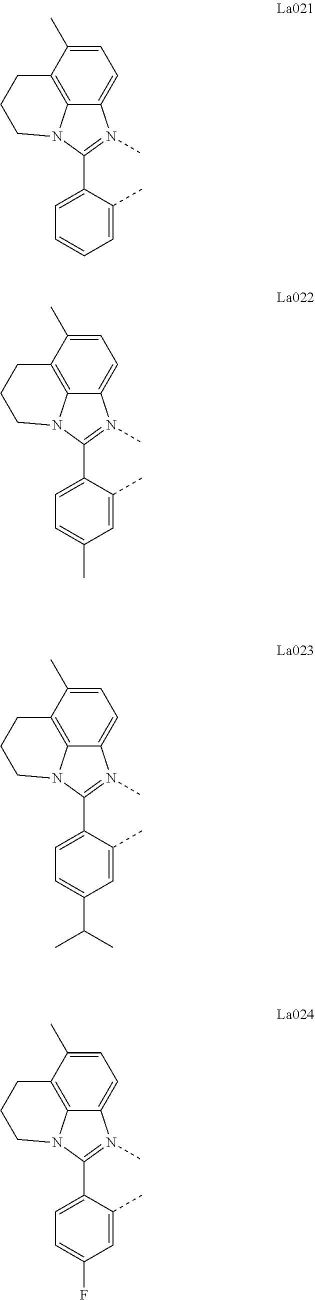

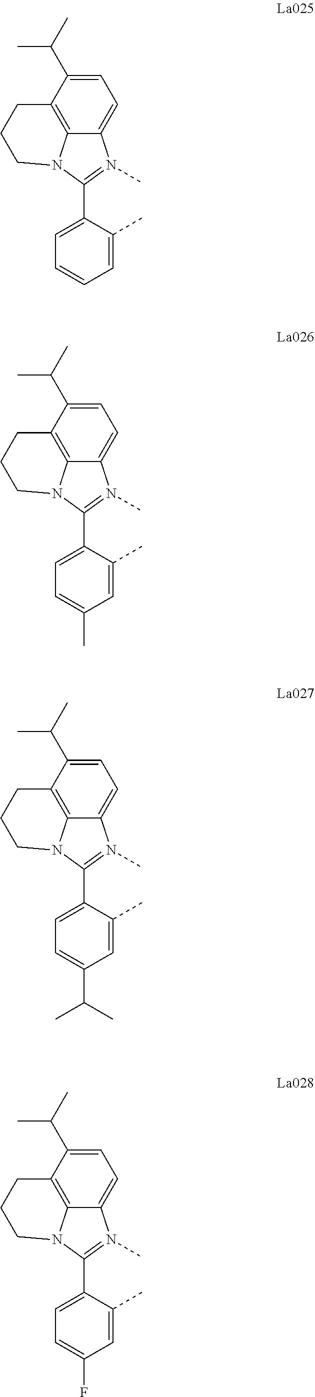

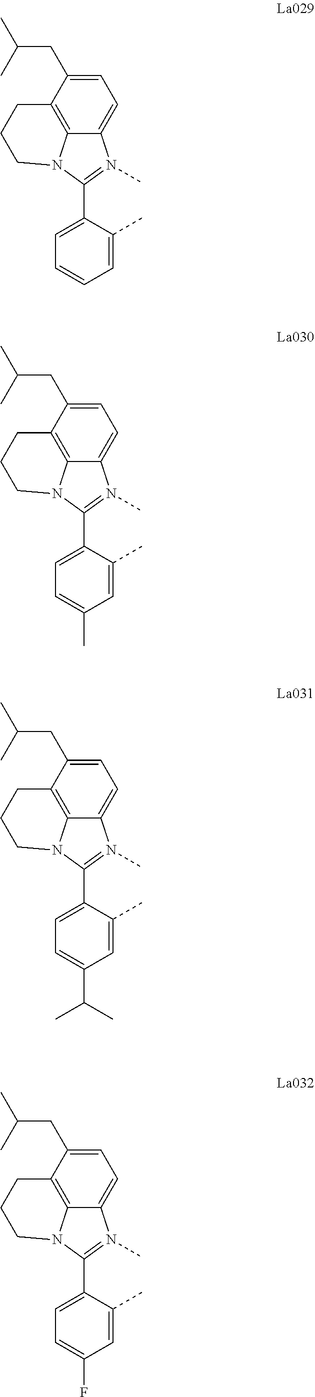

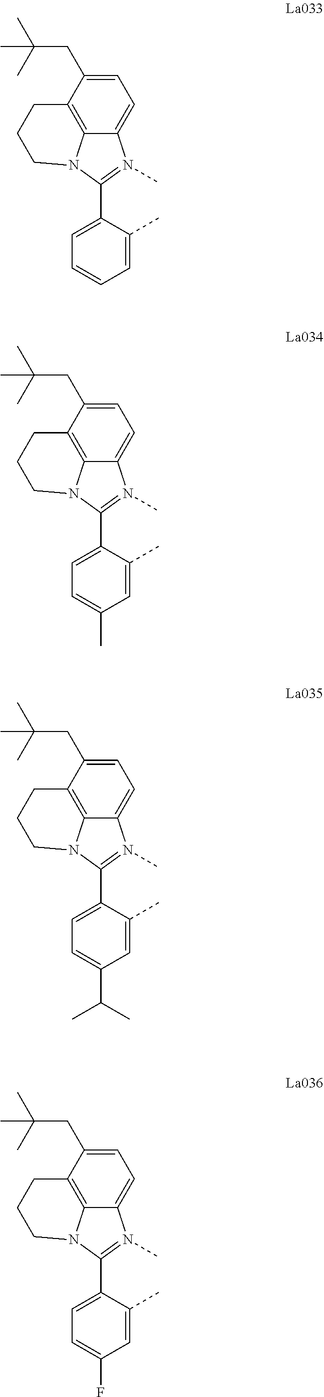

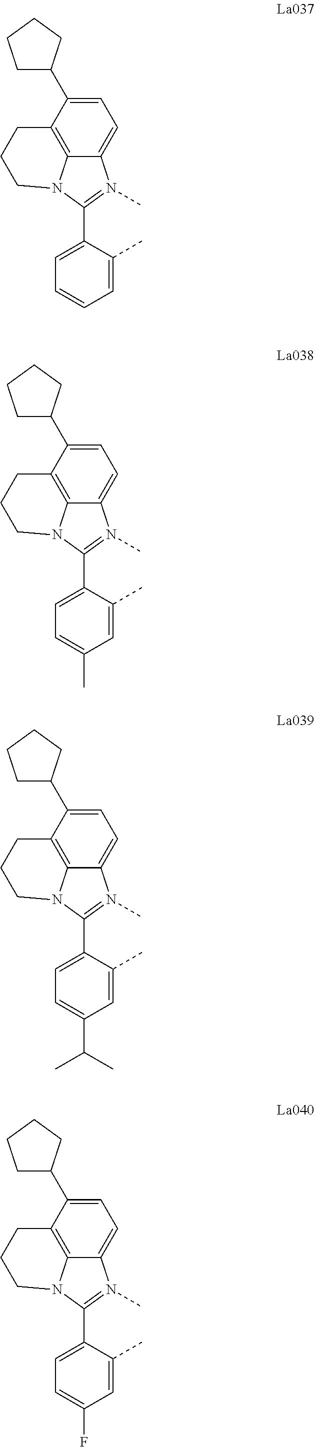

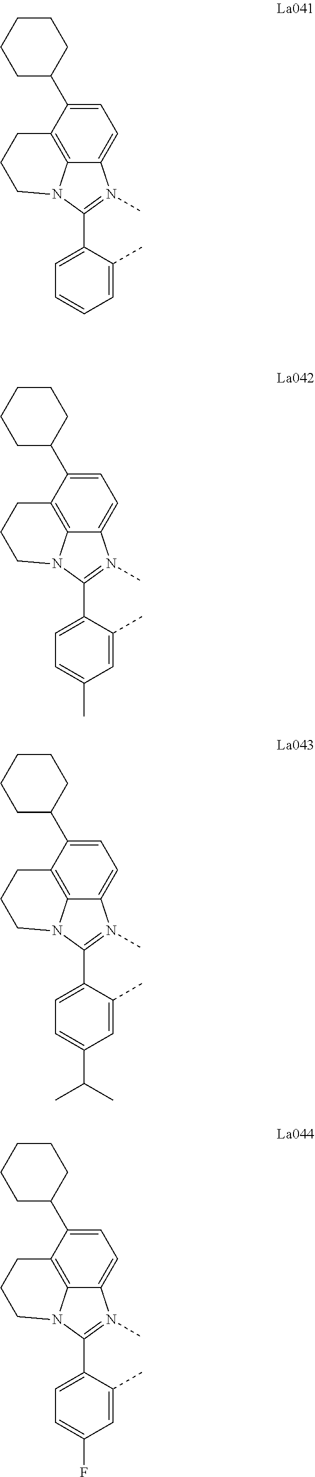

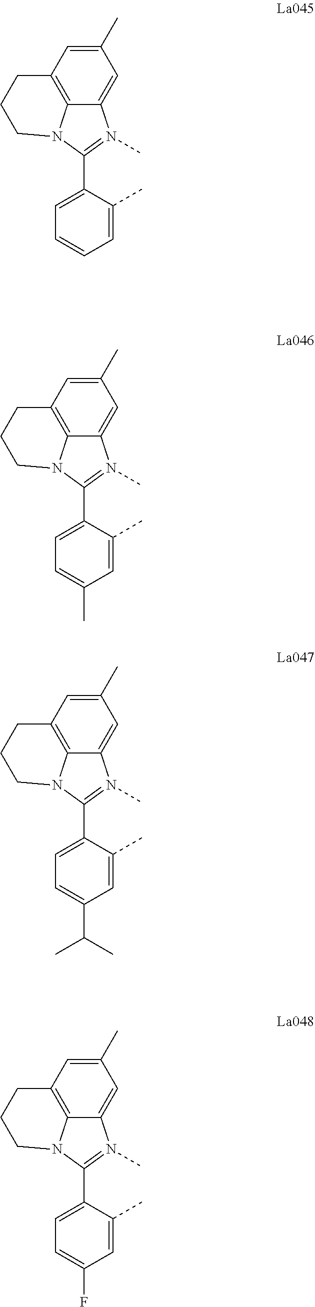

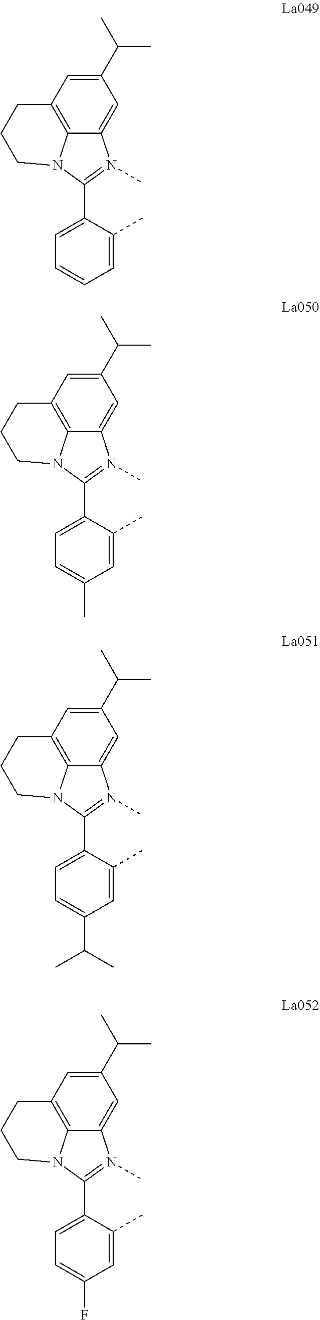

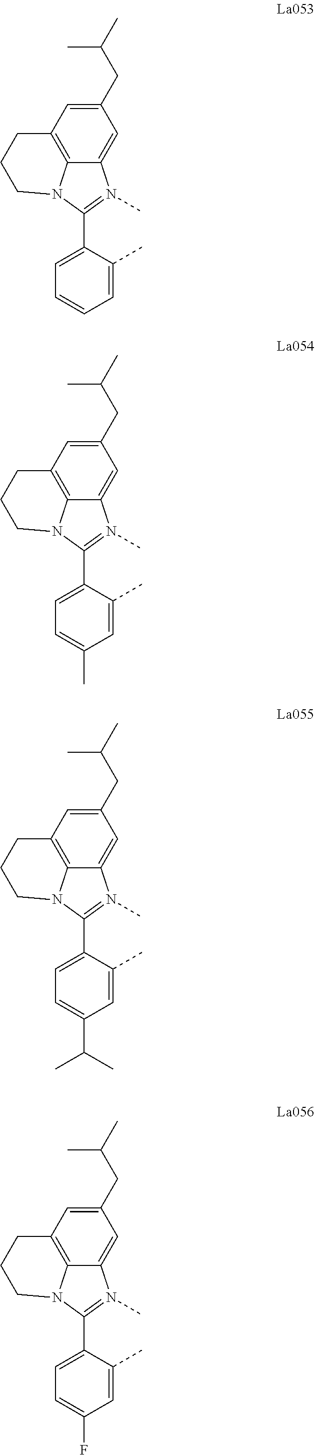

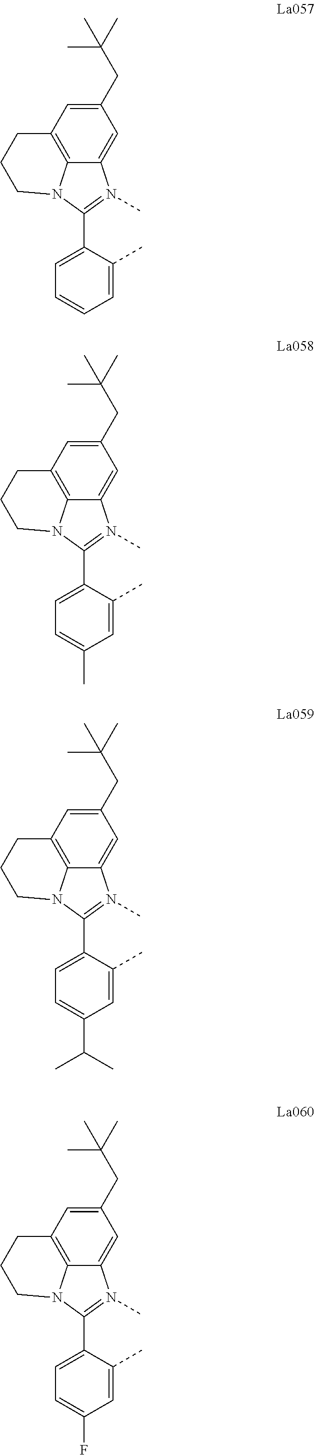

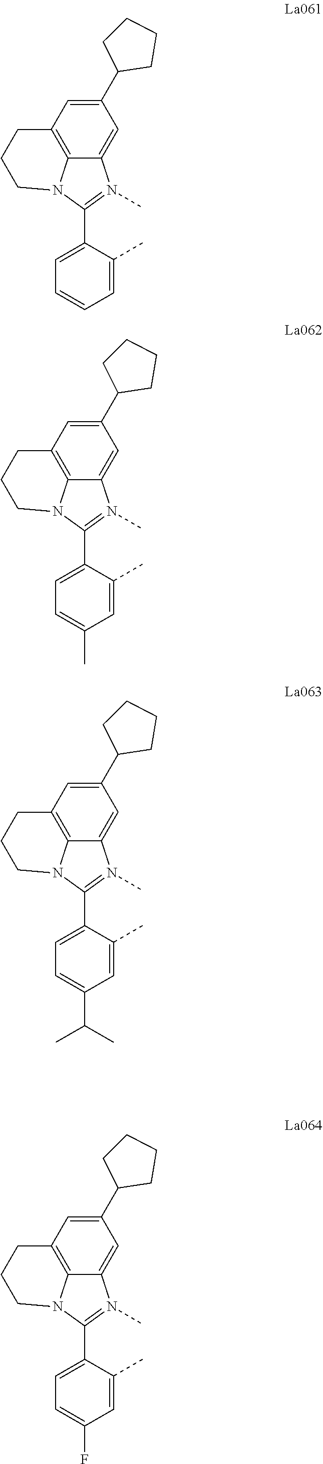

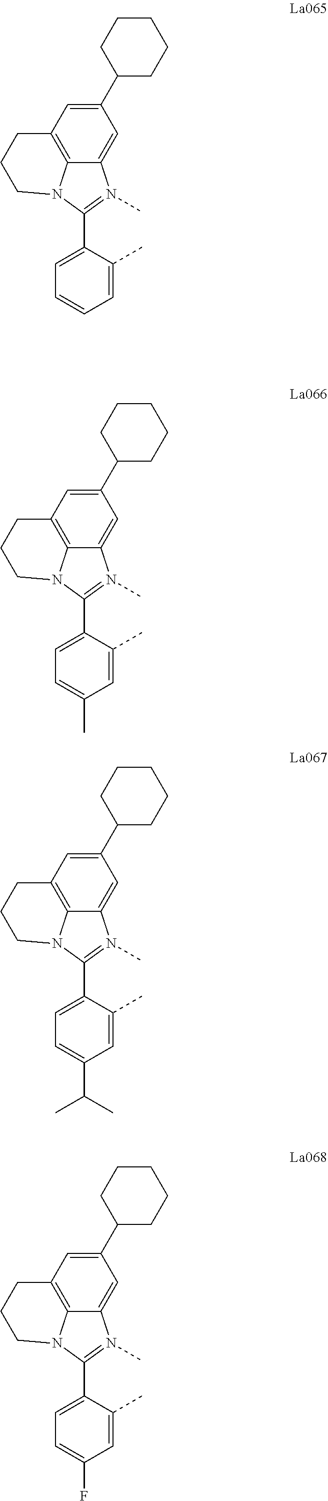

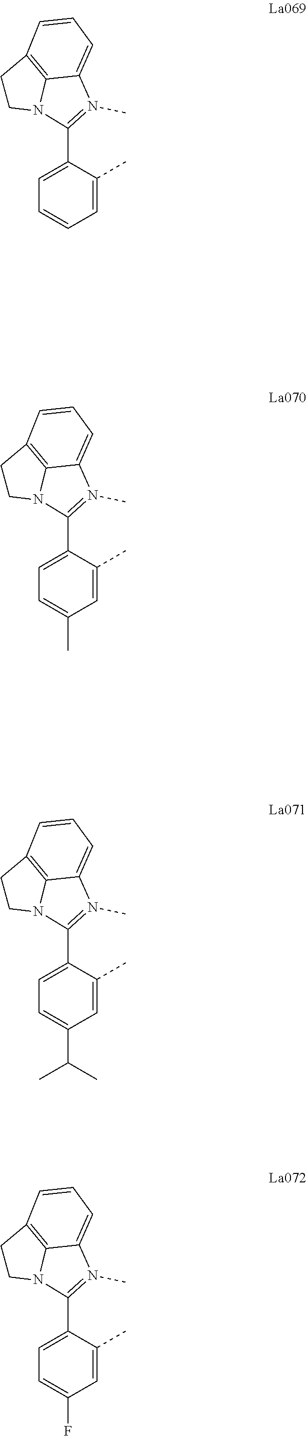

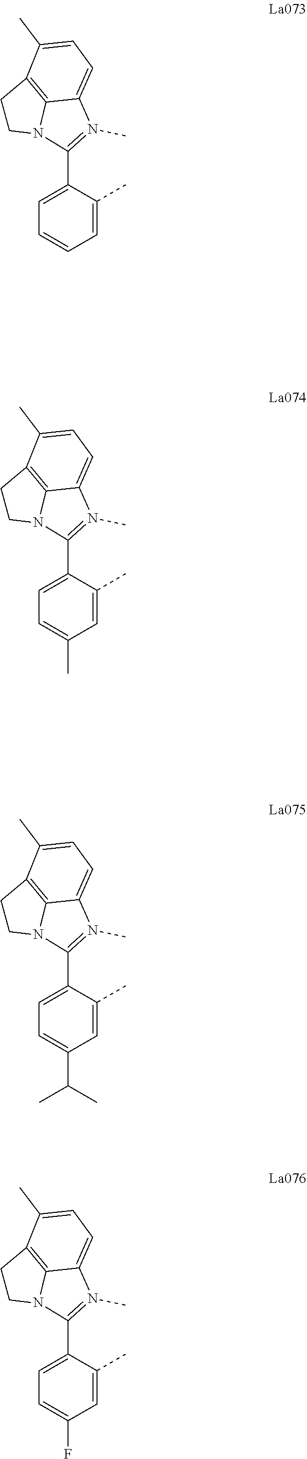

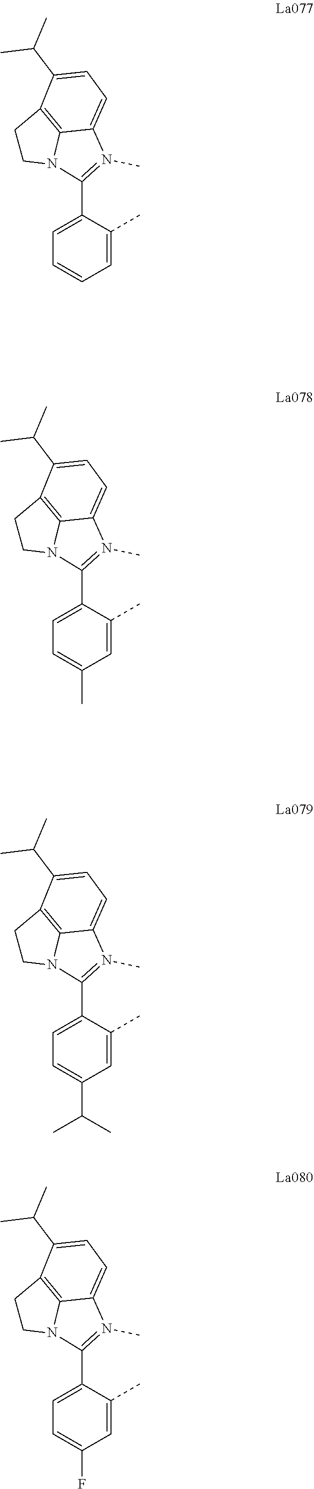

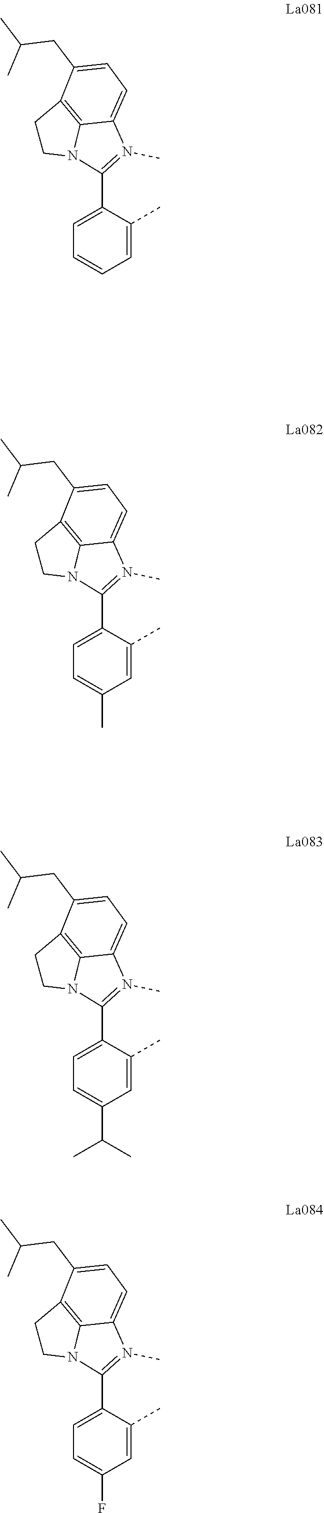

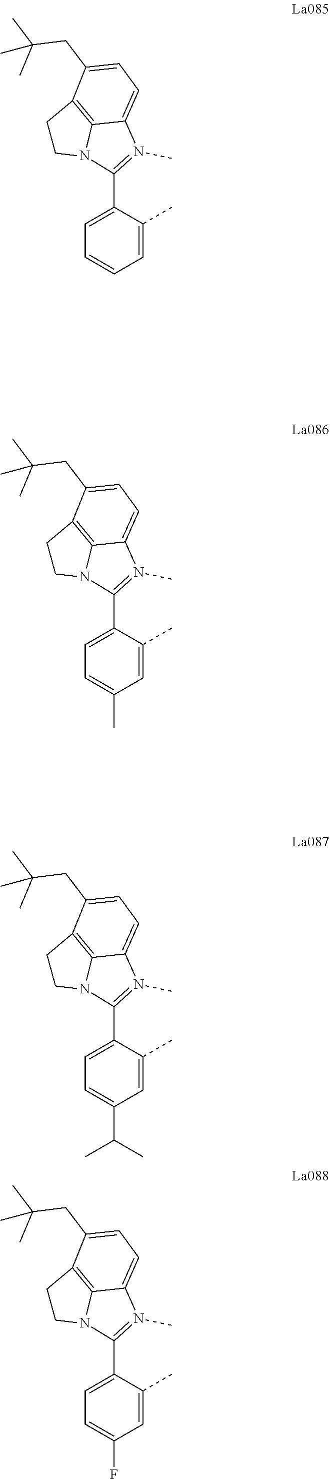

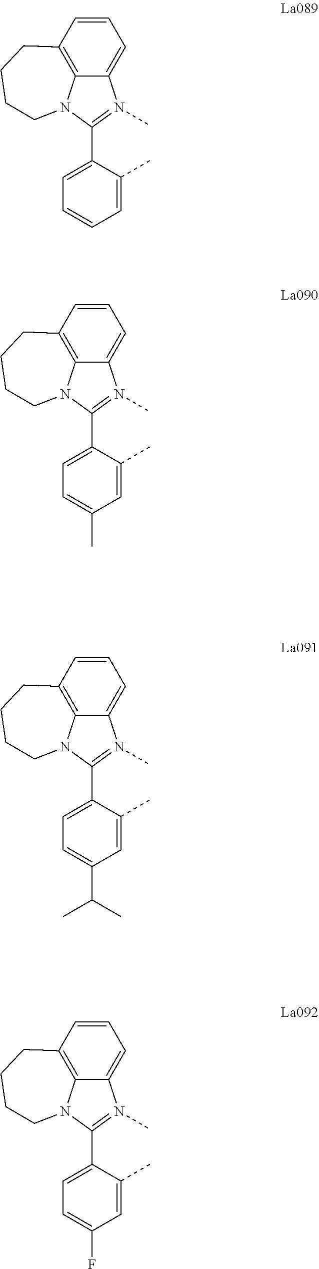

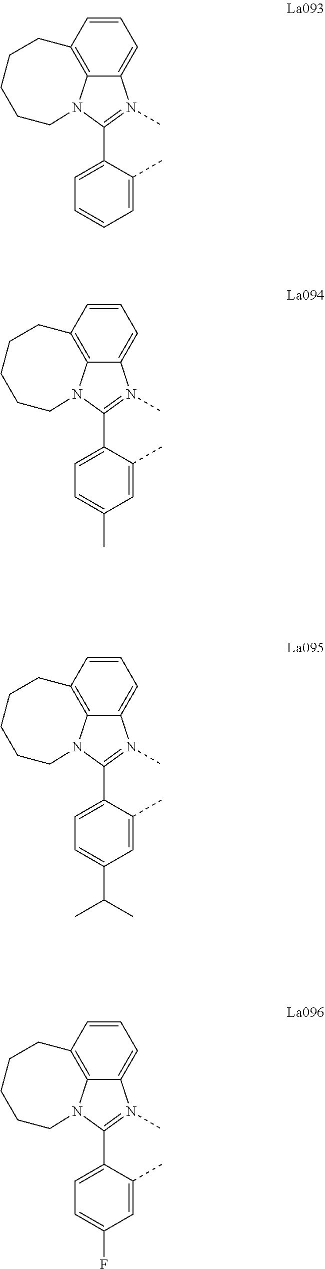

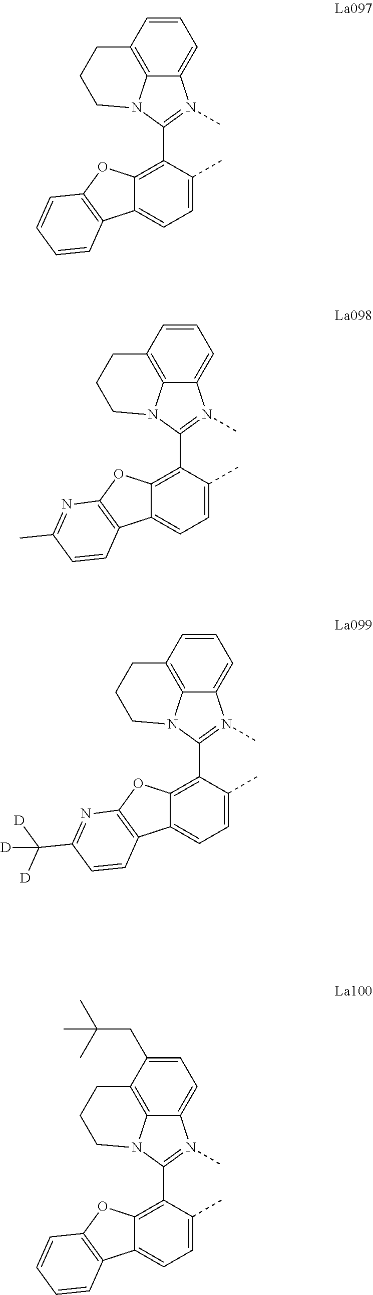

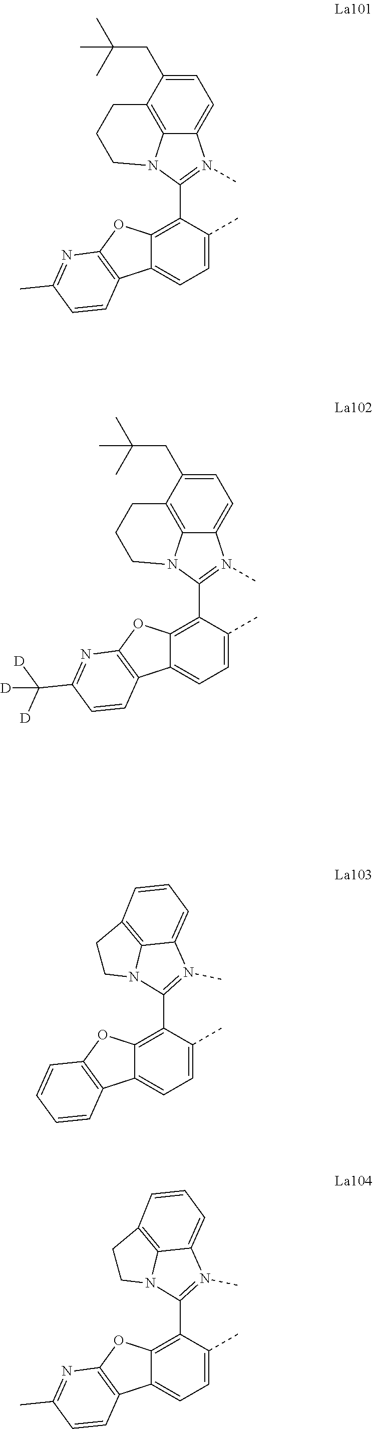

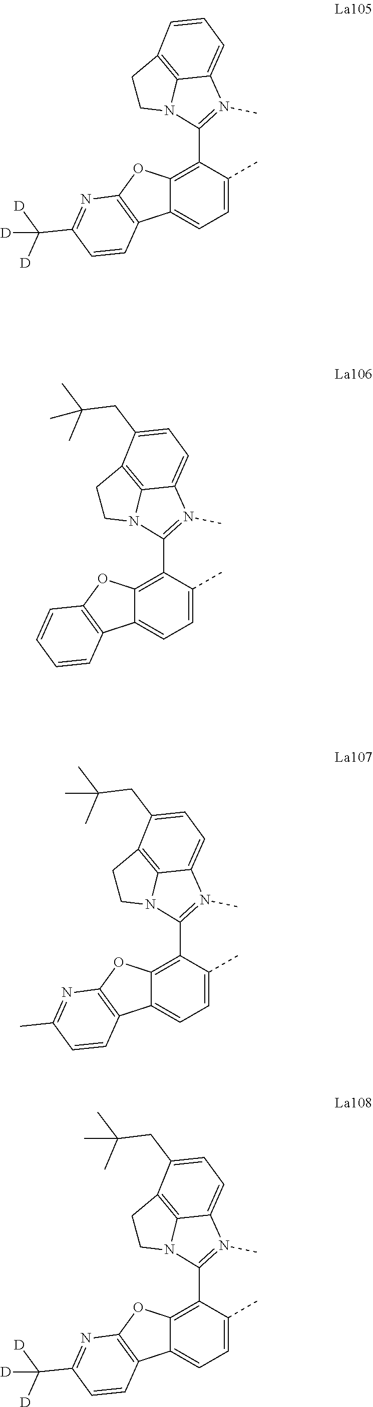

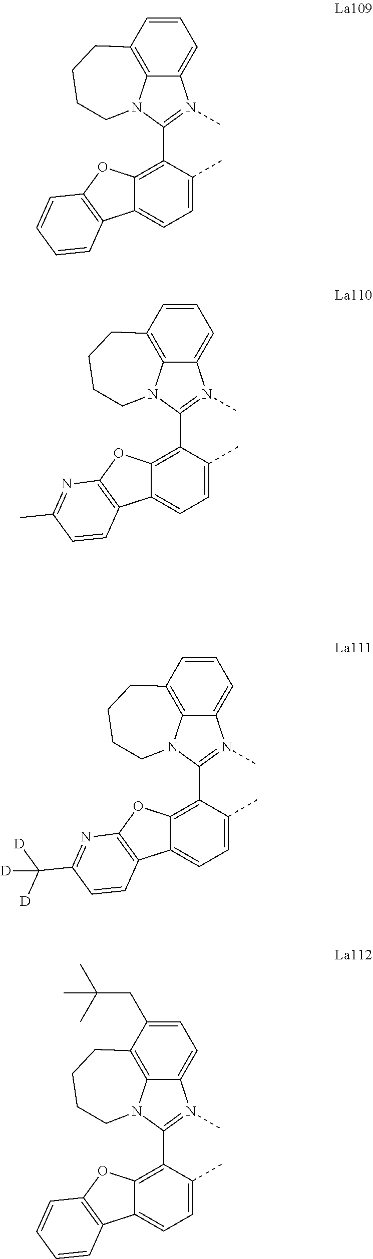

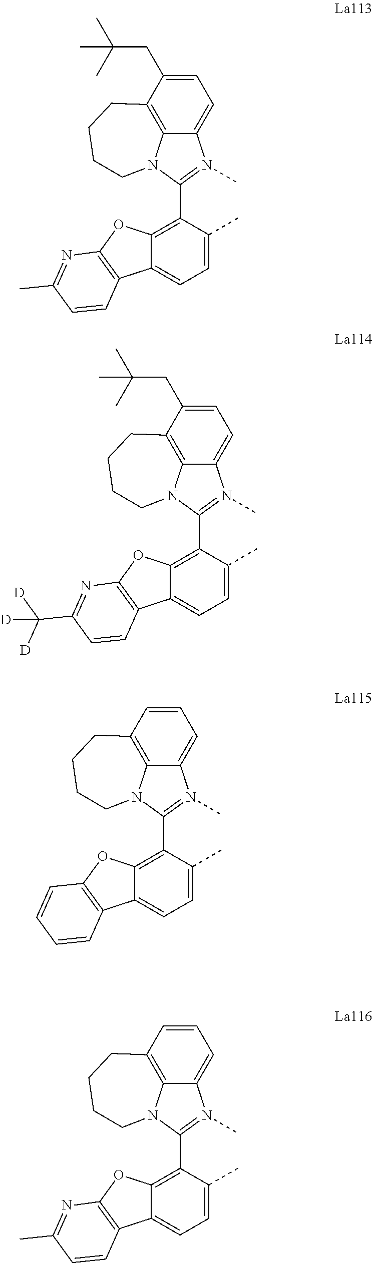

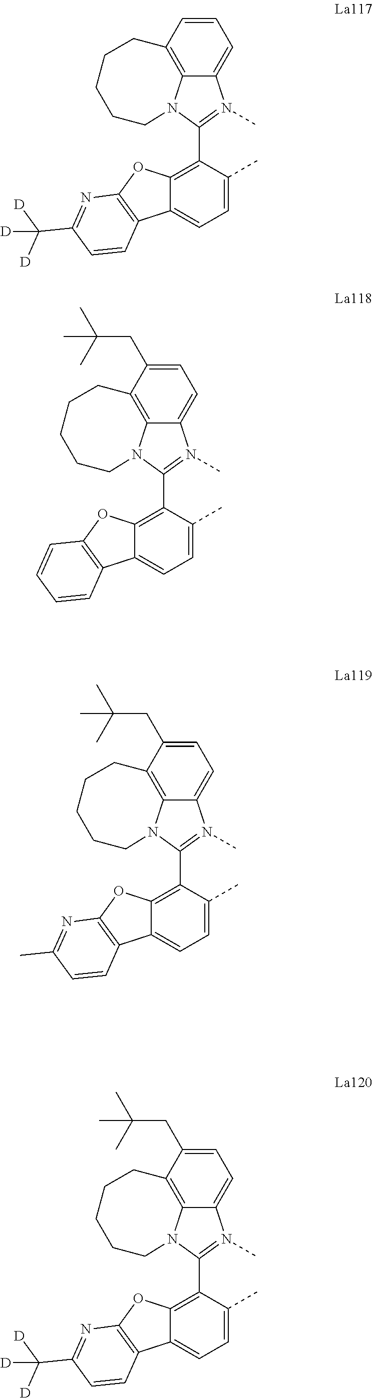

13. The organometallic compound according to claim 5, wherein the Lb has one of the following structural formulas, or is partially or completely deuterated or fluorinated correspondingly,

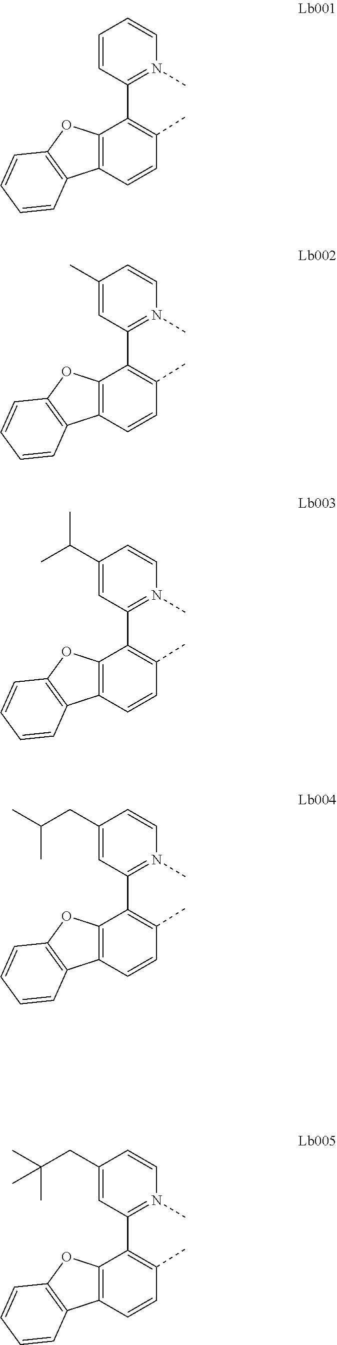

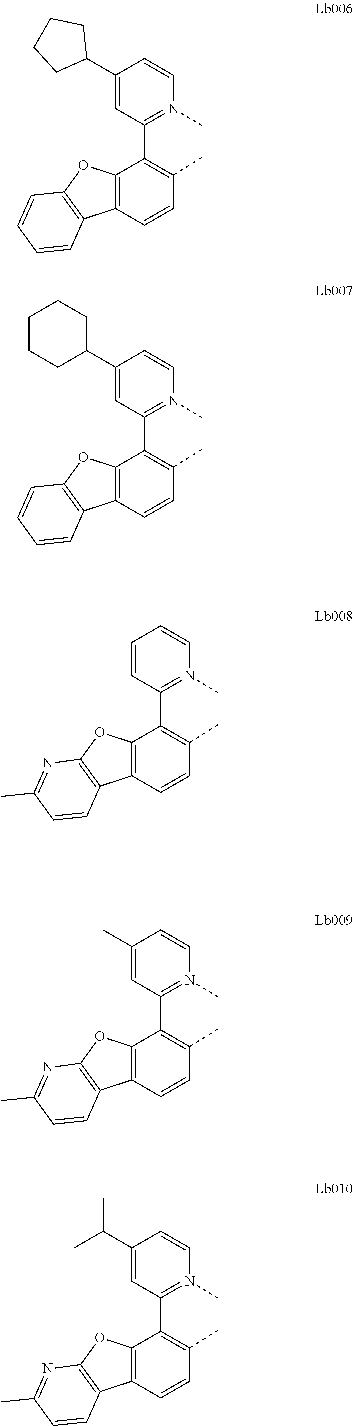

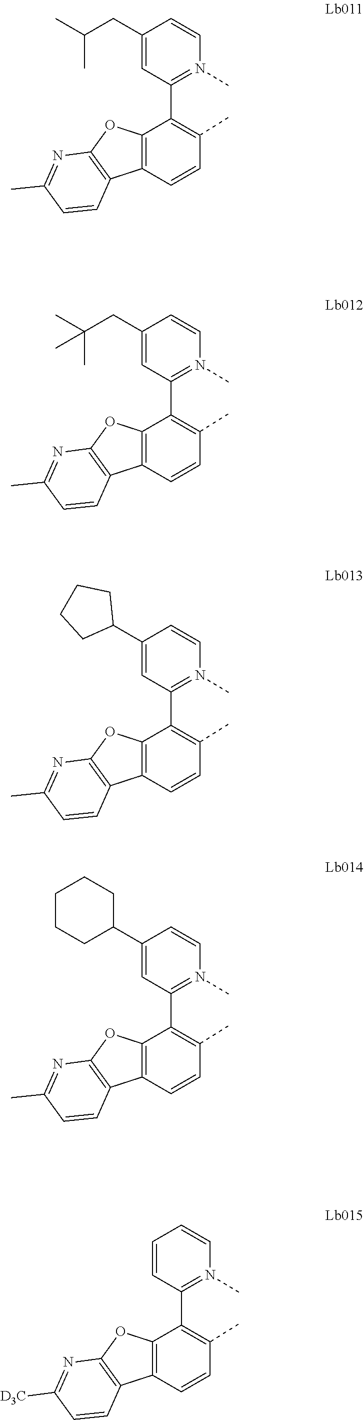

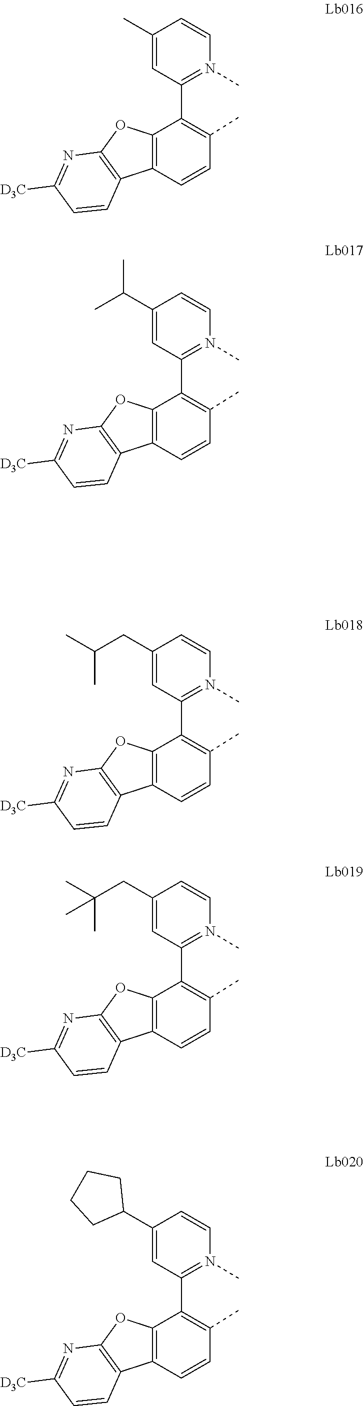

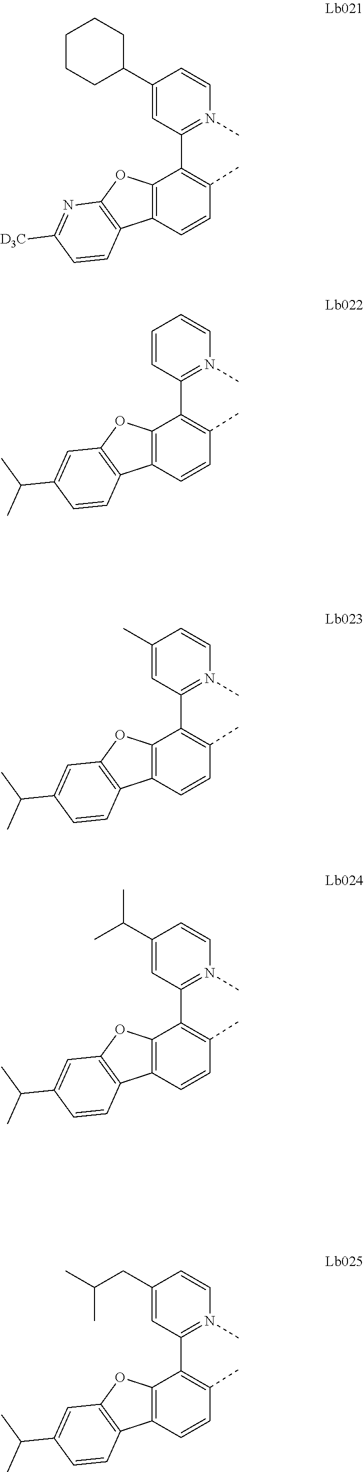

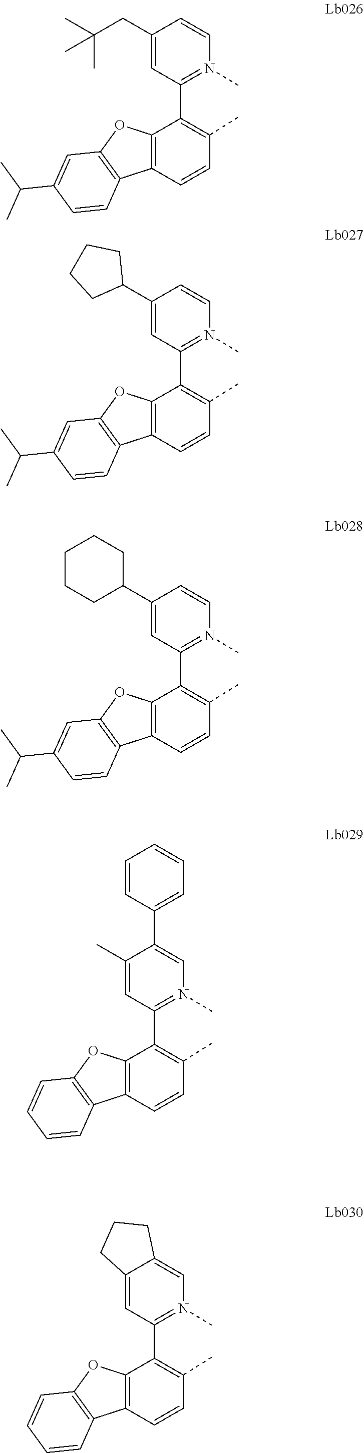

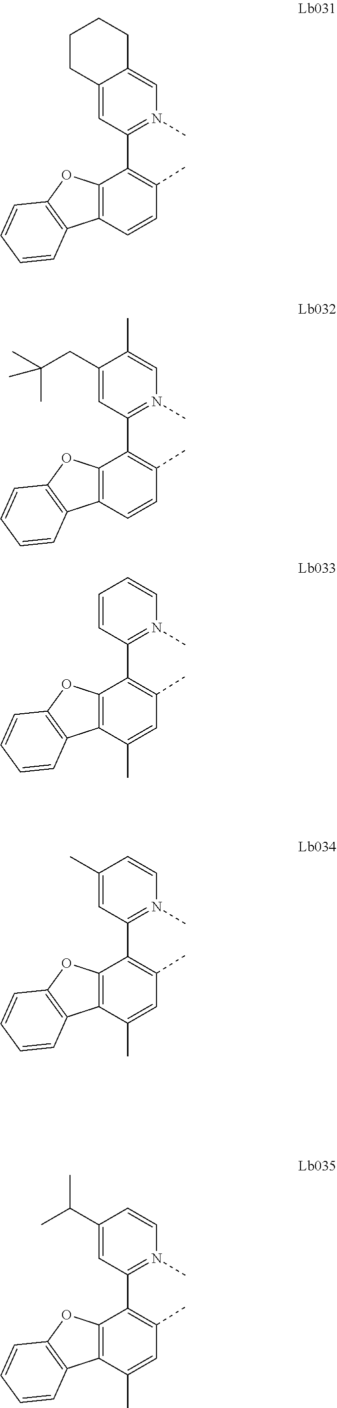

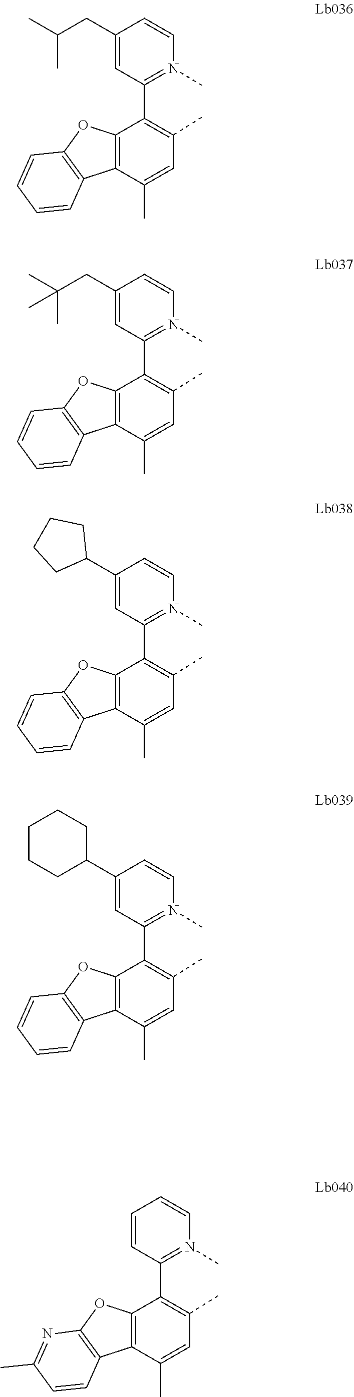

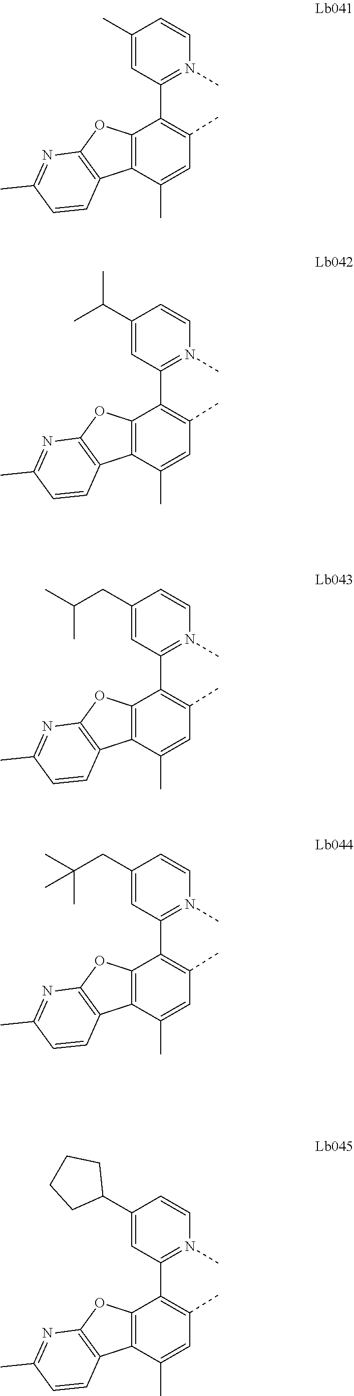

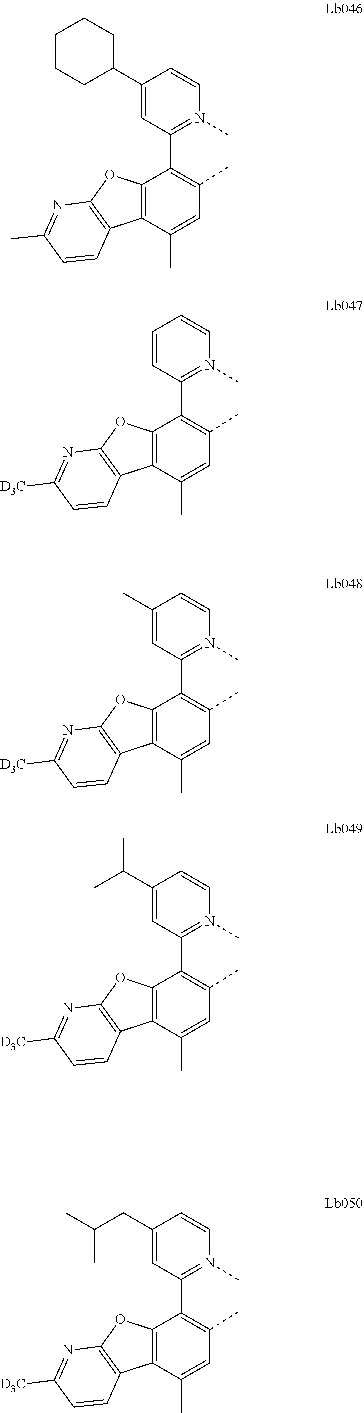

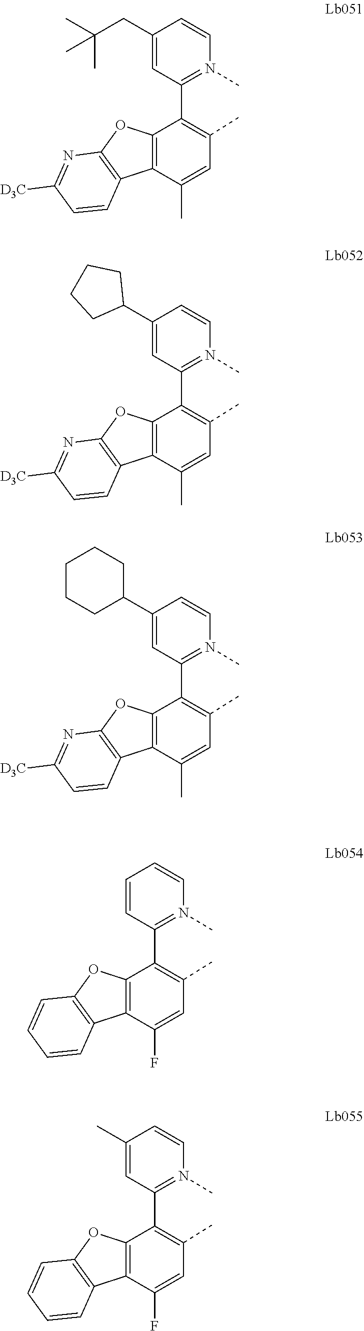

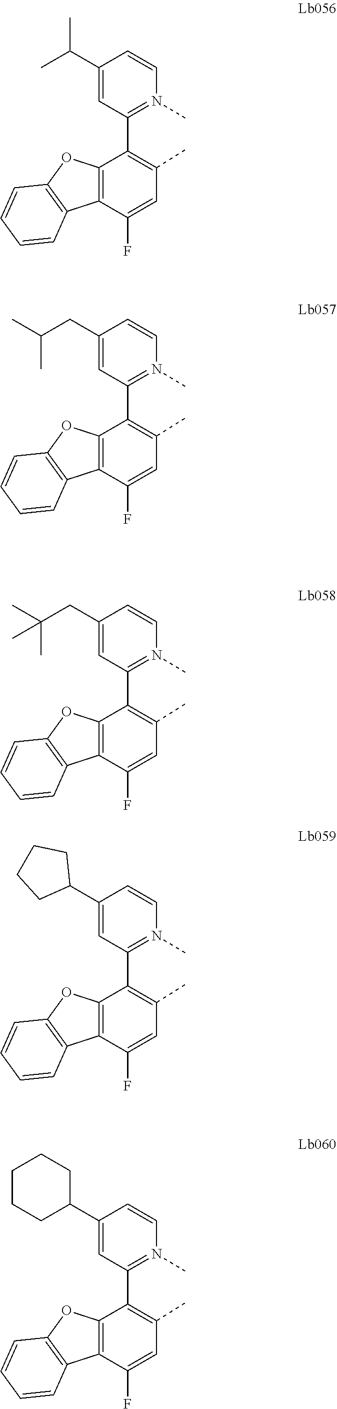

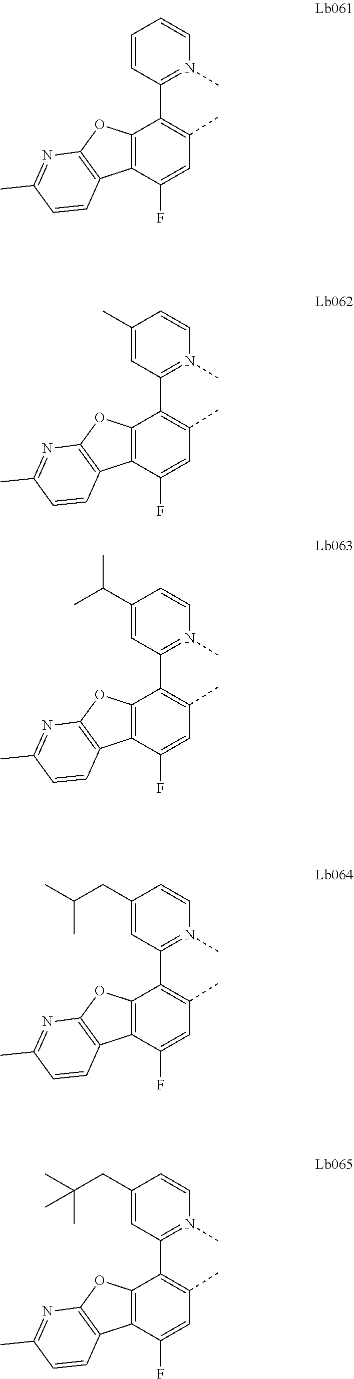

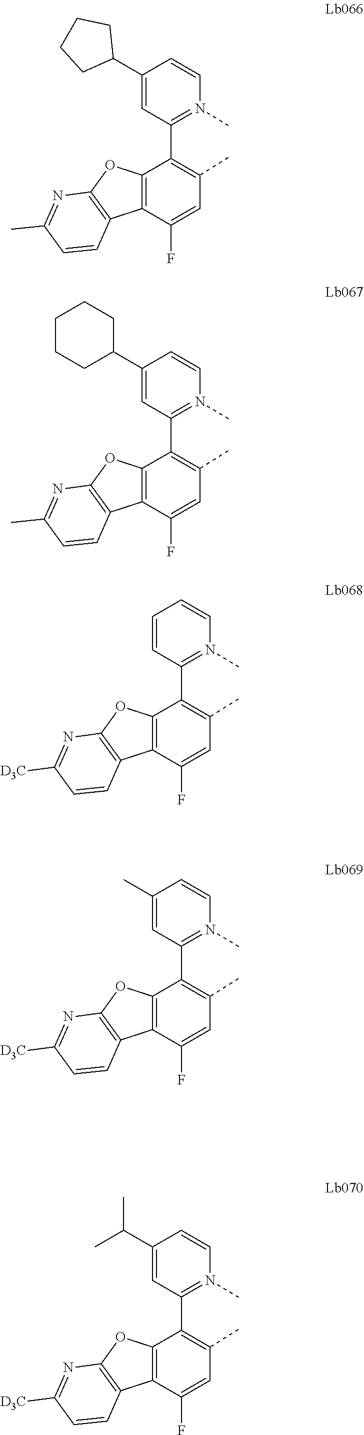

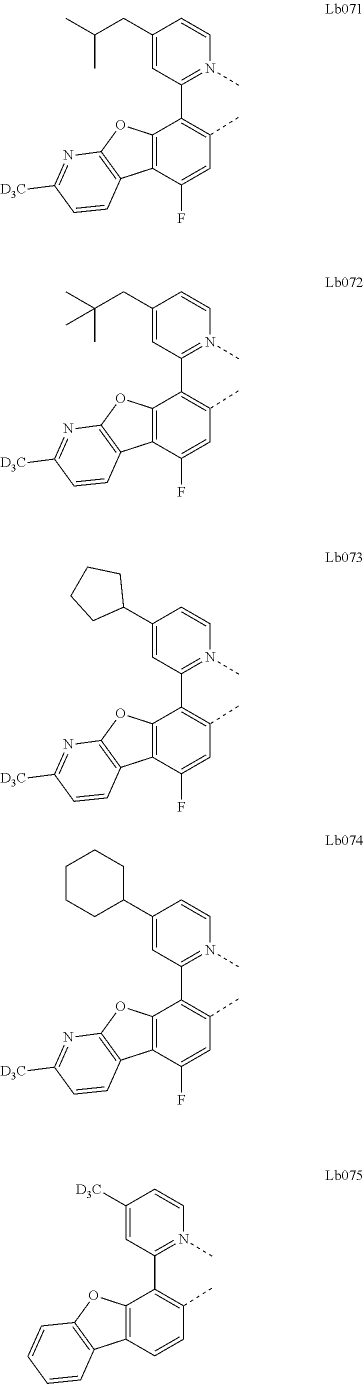

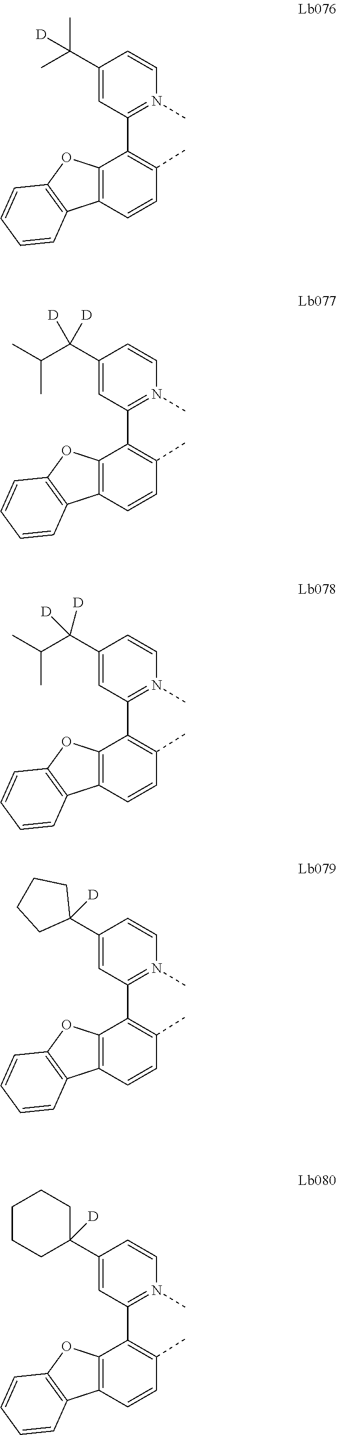

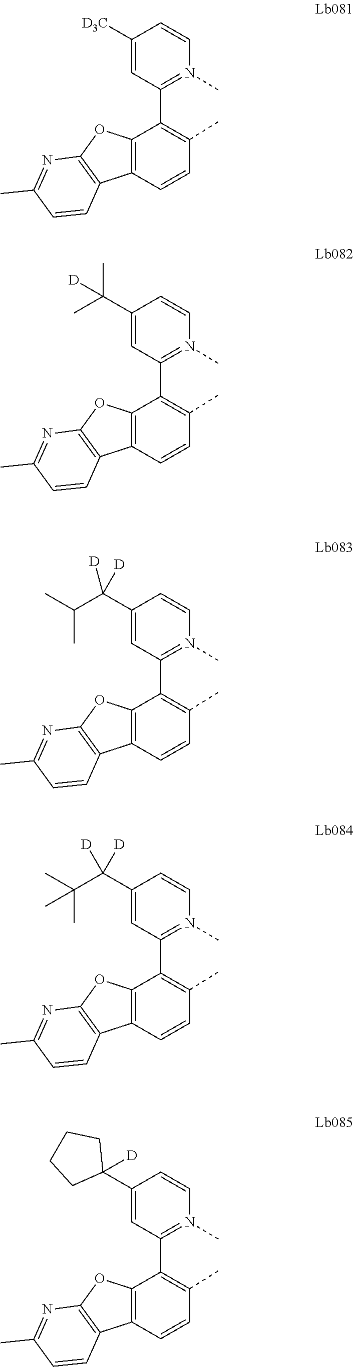

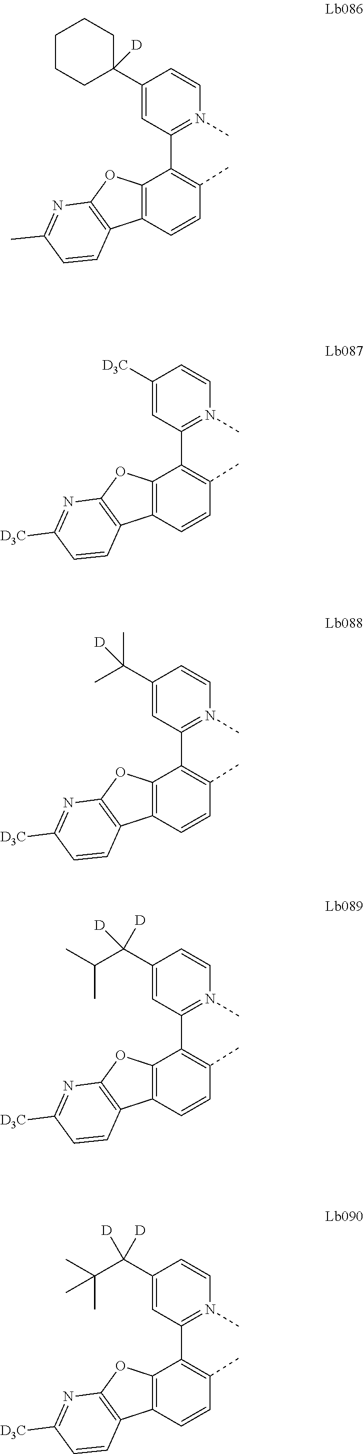

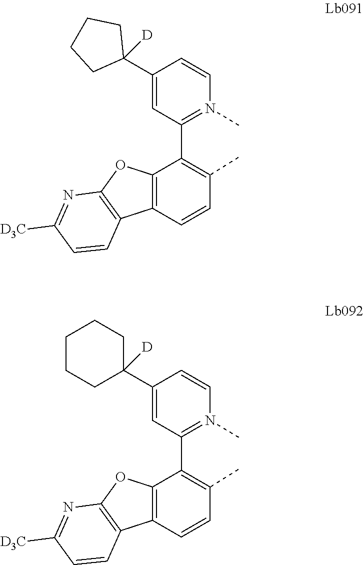

14. The organometallic compound according to claim 9, wherein the Lc has one of the following structural formulas, or is partially or completely deuterated or fluorinated correspondingly,

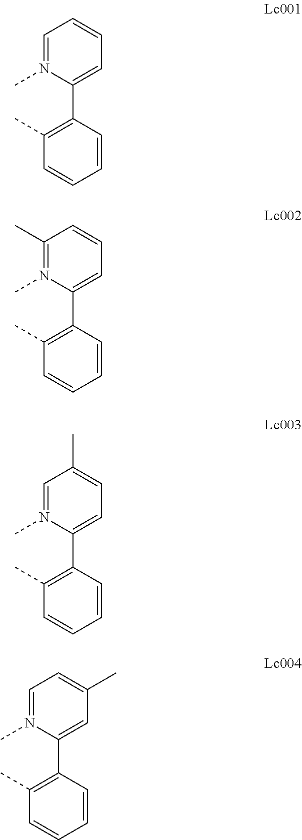

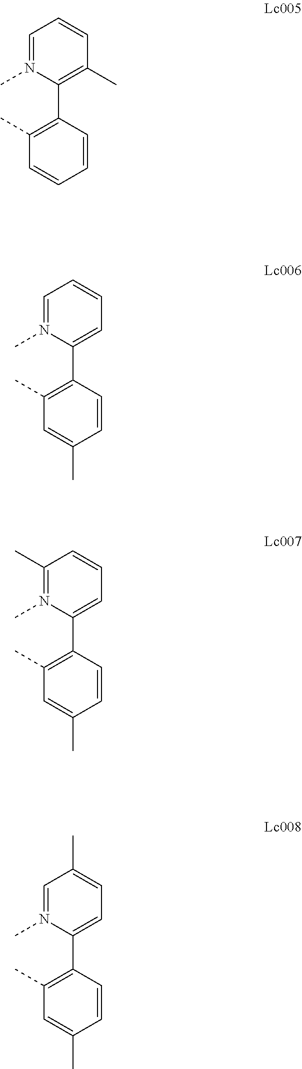

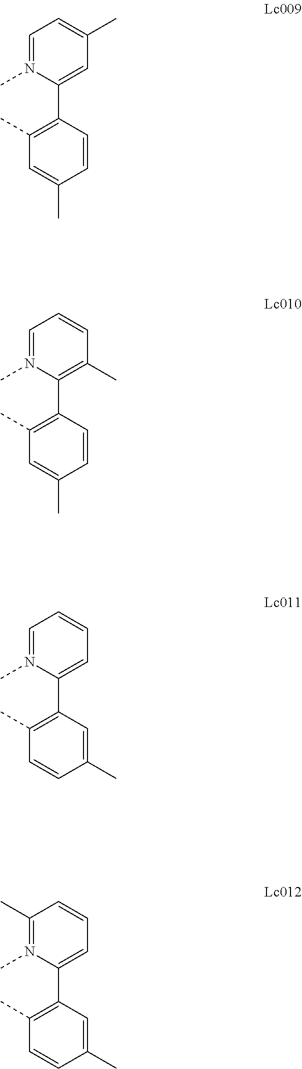

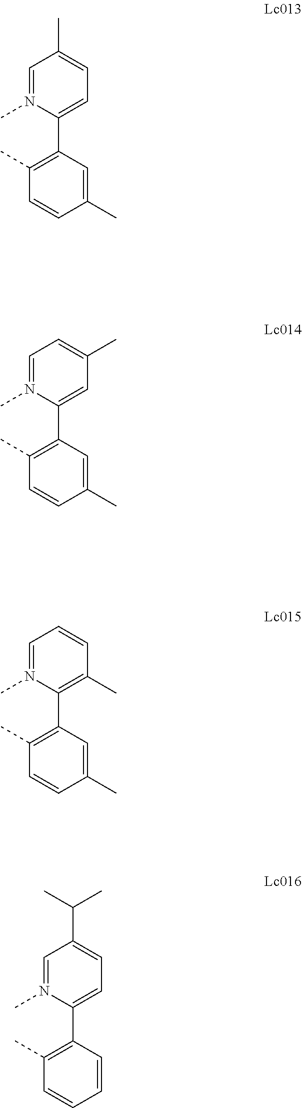

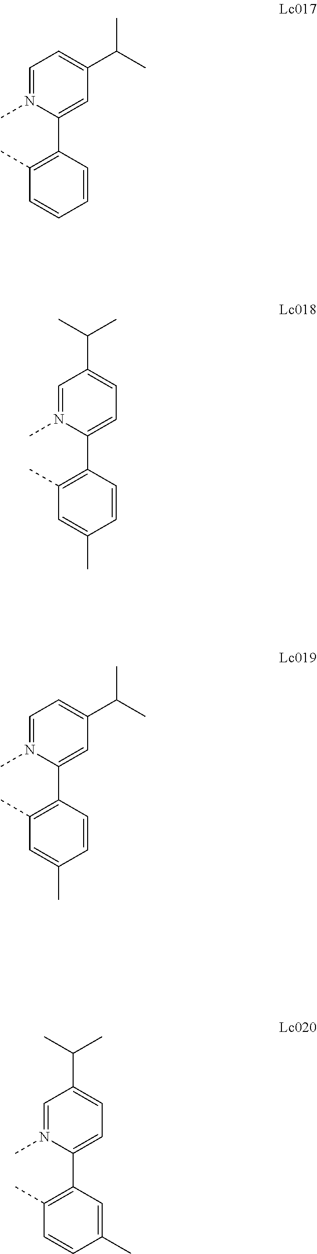

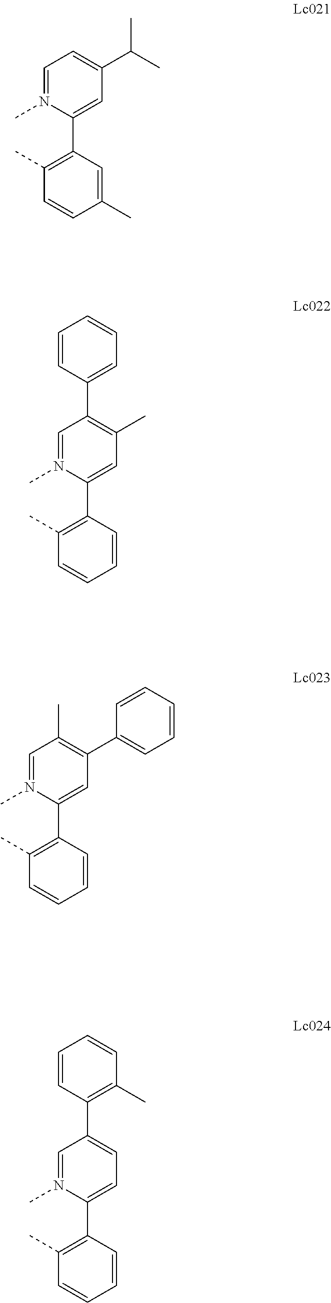

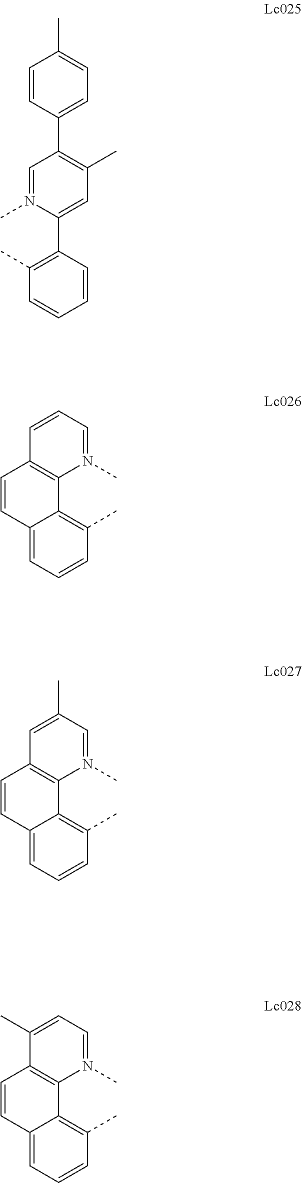

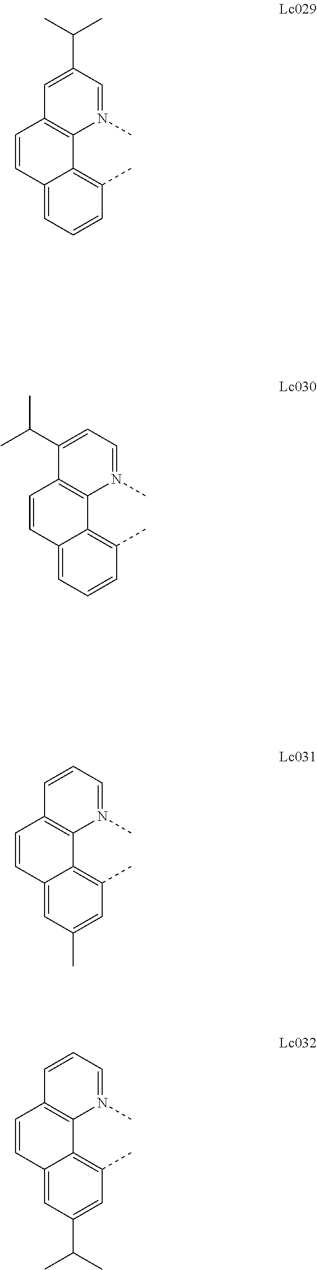

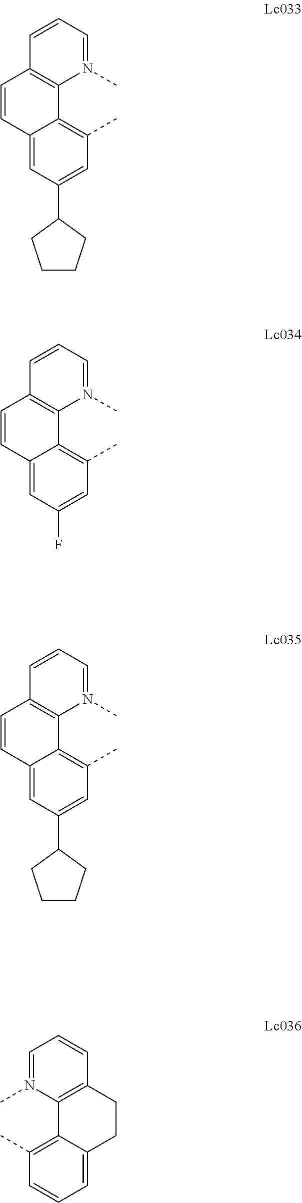

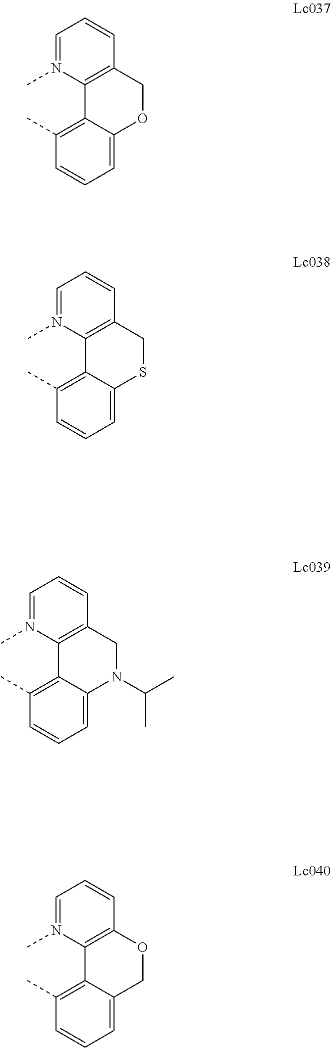

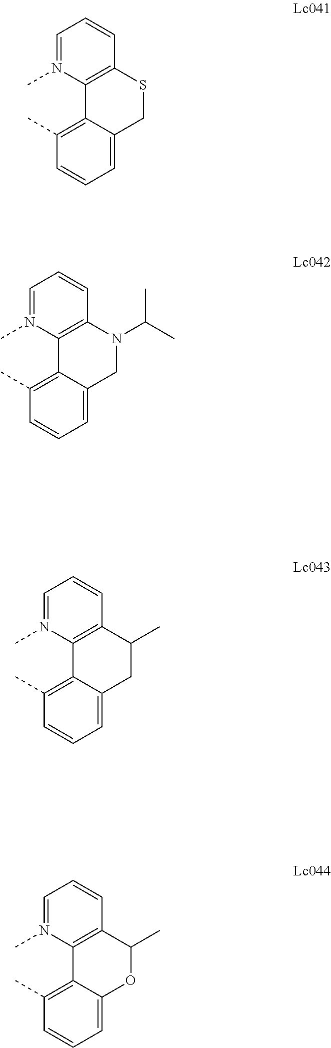

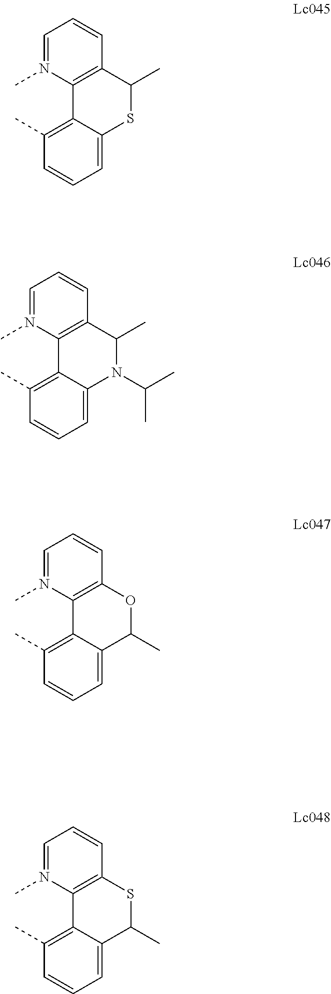

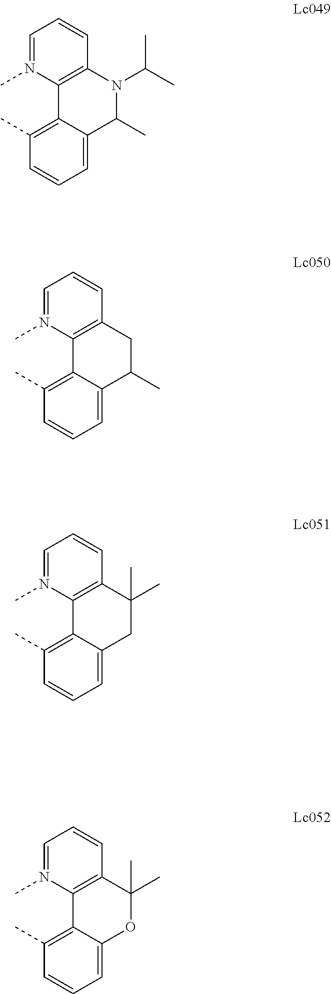

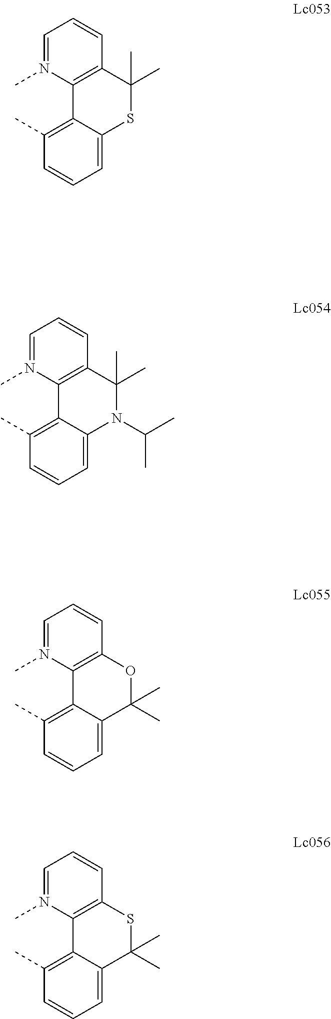

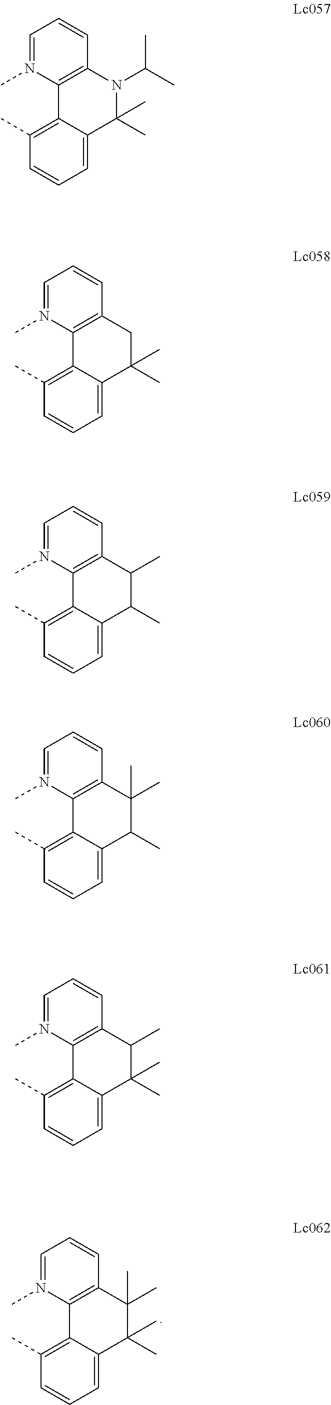

15. Application of the organometallic compound according to any one of claims 1-14 in an organic electroluminescent device.

16. The application according to claim 15, wherein the organometallic compound according to any one of claims 1-14 is used as a green light-emitting doping material for a light-emitting layer in the organic electroluminescent device.
